(19) United States
(12) Patent Application Publication
(10) Pub. No.: US 2015/0137051 A1
(43) Pub. Date: May 21, 2015

(54) NOVEL COMBINATION OF A HOST COMPOUND AND A DOPANT COMPOUND AND AN ORGANIC ELECTROLUMINESCENCE DEVICE COMPRISING THE SAME

(71) Applicant: Rohm and Haas Electronic Materials Korea Ltd., Cheonan (KR)

(72) Inventors: So-Young Jung, Hwaseong (KR); Bong-Ok Kim, Seoul (KR); Chi-Sik Kim, Hwaseong (KR); Hyun Kim, Suwon (KR); Hyuck-Joo Kwon, Seoul (KR); Kyung-Joo Lee, Seoul (KR); Kyoung-Jin Park, Seongnam (KR); So-Mi Park, Osan (KR)

(21) Appl. No.: 14/400,414

(22) PCT Filed: Jun. 26, 2013
(86) PCT No.: PCT/KR2013/005665

§ 371 Date: Nov. 11, 2014

(30) Foreign Application Priority Data
Jun. 26, 2012 (KR) 10-2012-0068543

(51) Int. Cl. H01L 51/00; C09K 11/06

(52) U.S. Cl. CPC H01L 51/0085; H01L 51/0072; H01L 51/0067; H01L 51/0094; H01L 51/0074; C09K 11/06; C09K 2211/185
USPC 252/519.21

(57) ABSTRACT

The present invention relates to a specific combination of a dopant compound and a host compound, and an organic electroluminescent device comprising the same. The organic electroluminescent device of the present invention provides the advantages of excellent luminous characteristics with lower driving voltages, compared to devices using conventional luminescent materials.

### TECHNICAL FIELD

The present invention relates to a novel combination of a host compound and a dopant compound and an organic electroluminescence device comprising the same.

### BACKGROUND ART

An electroluminescent (EL) device is a self-light-emitting device which has advantages in that it provides a wider viewing angle, a greater contrast ratio, and a faster response time compared to LCDs. An organic EL device was first developed by Eastman Kodak, by using small aromatic diamine molecules, and aluminum complexes as materials for forming a light-emitting layer [Appl. Phys. Lett. 51, 913, 1987].

The most important factor determining luminous efficiency in an organic EL device is the light-emitting material. The electroluminescent material includes a host material and a dopant material for purposes of functionality. Typically, a device that has very superior electroluminescent properties is known to have a structure in which a host is doped with a dopant to form an electroluminescent layer. Recently, the development of an organic EL device having high efficiency and long lifespan is being urgently called for. Particularly, taking into consideration the electroluminescent properties required of medium to large OLED panels, the development of materials very superior to conventional electroluminescent materials is urgent. In order to achieve such, a host material which functions as the solvent in a solid phase and plays a role in transferring energy should be of high purity and must have a molecular weight appropriate to enabling vacuum deposition. Also, the glass transition temperature and heat decomposition temperature should be high to ensure thermal stability, and high electrochemical stability is required to attain a long lifespan, and the formation of an amorphous thin film should become simple, and the force of adhesion to materials of other adjacent layers must be good but interlayer migration should not occur.

Until now, fluorescent materials have been widely used as a light-emitting material. However, in view of electroluminescent mechanisms, developing phosphorescent materials is one of the best methods to theoretically enhance luminous efficiency by four (4) times. Iridium(III) complexes have been widely known as dopant compounds of phosphorescent substances, including bis(2-(2′-benzothienyl)-pyridinato-N,C3′)iridium(acetylacetonate) [(acac)Ir(btp)₂], tris(2-phenylpyridine)iridium [Ir(ppy)₃] and bis(4,6-difluorophenylpyridinato-N,C2)picolinato iridium [Firpic] as red, green and blue materials, respectively. Until now, 4,4′-N,N′-dicarbazol-biphenyl (CBP) was the most widely known host material for phosphorescent substances. Further, an organic EL device using bathocuproine (BCP) and aluminum(III)bis(2-methyl-8-quinolinate)(4-phenylphenolate) (BAlq) for a hole blocking layer is also known. However, there were problems in power efficiency, operational life span, and luminous efficiency, when applying a light-emitting layer comprising conventional dopant and host compounds.

Korean Patent Appin. Laying-Open No. KR 2007050438 A discloses iridium complexes introducing an alkyl or an aryl group to an Ir(ppy)₃ structure, which is a conventional dopant compound, as a dopant compound comprised in a light-emitting layer of an organic electroluminescent device. However, the above reference does not disclose a combination with a specific host compound, and still could not solve the problems of luminous efficiency, etc.

The present inventors found that a specific combination of a dopant compound and a host compound is suitable for manufacturing organic EL devices having high color purity, high luminance, and a long lifespan.

### DISCLOSURE OF THE INVENTION

### Problems to be Solved

The objective of the present invention is to provide a novel dopant/host combination and an organic electroluminescent device comprising the same which provides excellent luminous efficiency in lowered operating voltages.

### Solution to Problems

In order to achieve said purposes, the present invention provides a combination of one or more dopant compounds represented by the following formula 1, and one or more host compounds represented by the following formula 2:

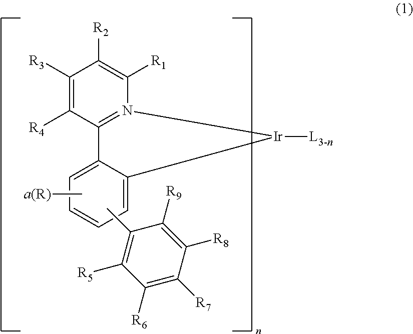

wherein

L is an organic ligand;

R₁ to R₉ each independently represent hydrogen, deuterium, a halogen, a substituted or unsubstituted (C1-C30)alkyl, a substituted or unsubstituted (C3-C30)cycloalkyl, a substituted or unsubstituted (C1-C30)alkoxy, a substituted or unsubstituted (C6-C30)aryl, or a substituted or unsubstituted 3- to 30-membered heteroaryl;

R represents hydrogen, a halogen, a substituted or unsubstituted (C1-C30)alkyl, or a substituted or unsubstituted (C3-C30)cycloalkyl;

a represents an integer of 1 to 3; where a is an integer of 2 or more, each of R may be same or different; and

n represents an integer of 1 to 3;

H-(Cz-L₁)_{b}-L₂-M (2)

wherein

Cz is selected from the following structures:

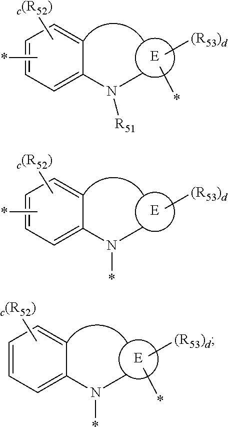

ring E represents a substituted or unsubstituted (C6-C30)cycloalkyl, a substituted or unsubstituted (C6-C30)aryl, or a substituted or unsubstituted 3- to 30-membered heteroaryl;

R₅₁ to R₅₃ each independently represent hydrogen, deuterium, a halogen, a substituted or unsubstituted (C1-C30)alkyl, a substituted or unsubstituted (C6-C30)aryl, a substituted or unsubstituted 3- to 30-membered heteroaryl, a substituted or unsubstituted 5- to 7-membered heterocycloalkyl, a substituted or unsubstituted (C6-C30)aryl fused with at least one substituted or unsubstituted (C3-C30)alicyclic ring, a 5- to 7-membered heterocycloalkyl fused with at least one substituted or unsubstituted (C6-C30)aromatic ring, a substituted or unsubstituted (C3-C30)cycloalkyl, a (C3-C30)cycloalkyl fused with at least one substituted or unsubstituted (C6-C30)aromatic ring, or a substituted or unsubstituted (C6-C30)aryl(C1-C30)alkyl;

L₁ and L₂ each independently represent a single bond, a substituted or unsubstituted (C6-C30)arylene, a substituted or unsubstituted 3- to 30-membered heteroarylene, or a substituted or unsubstituted (C6-C30)cycloalkylene;

M represents a substituted or unsubstituted (C6-C30)aryl, or a substituted or unsubstituted 3- to 30-membered heteroaryl;

b represents 1 or 2; where b is 2, each of Cz, and each of L₁ from each (Cz-L₁) may be same or different;

c and d each independently represent an integer of 0 to 4; where c or d is an integer of 2 or more, each of R₅₂, and each of R₅₃ may be same or different.

### Effects of the Invention

The host-dopant combination according to the present invention improves electron density distribution in the light-emitting layer through efficient energy transfer mechanisms between the host and the dopant, and provides luminous characteristics of high efficiency. In addition, it can overcome problems of lowered initial efficiency and lifespan characteristics, which the conventional luminous materials had, and can provide luminous characteristics of high performance having high efficiency and a long lifespan in each color.

By using the specific combination of a dopant compound and a host compound according to the present invention in an organic EL device, there are advantages of better luminous efficiency at a lower driving voltage, compared to one using conventional luminous materials.

### EMBODIMENTS OF THE INVENTION

Hereinafter, the present invention will be described in detail. However, the following description is intended to explain the invention, and is not meant in any way to restrict the scope of the invention.

The present invention relates to a combination of one or more dopant compounds represented by formula 1, and one or more host compounds represented by formula 2; and a light-emitting layer comprising the same.

The dopant compound represented by formula 1 is preferably represented by formula 3 or 4:

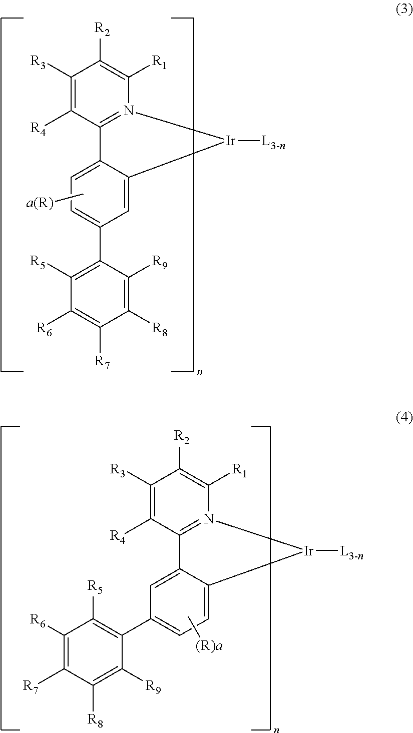

wherein R, R₁ to R₉, L, n, and a are as defined in formula 1.

In formulae 1, 3, and 4, L may be selected from the following structures, but is not limited thereto:

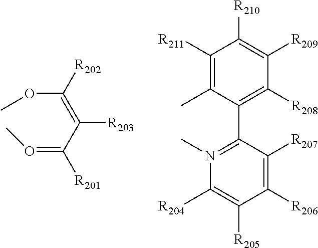

wherein R₂₀₁ to R₂₁₁ each independently represent hydrogen; deuterium; a halogen; a substituted or unsubstituted (C1-C30)alkyl; or a substituted or unsubstituted (C3-C30)cycloalkyl.

In formulae 1, 3, and 4, R₁ to R₉ preferably each independently represent hydrogen, a halogen, a substituted or unsubstituted (C1-C30)alkyl, or a substituted or unsubstituted (C3-C30)cycloalkyl, and more preferably each independently represent hydrogen, a halogen, an unsubstituted (C1-C6)alkyl, a (C1-C6)alkyl substituted with a (C1-C6)alkyl, an unsubstituted (C3-C7)cycloalkyl, or a (C3-C7)cycloalkyl substituted with a (C1-C6)alkyl.

The representative compounds of formula 1 include the following compounds, but are not limited thereto:

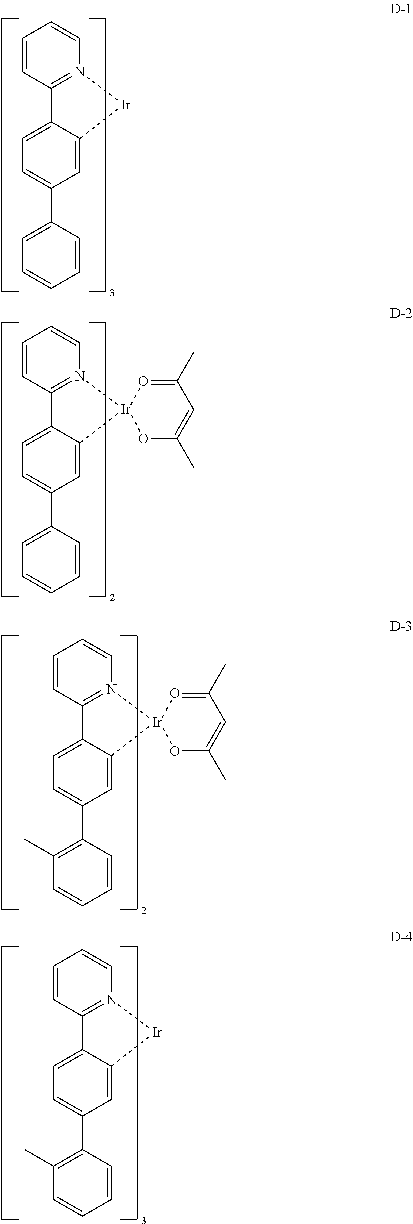

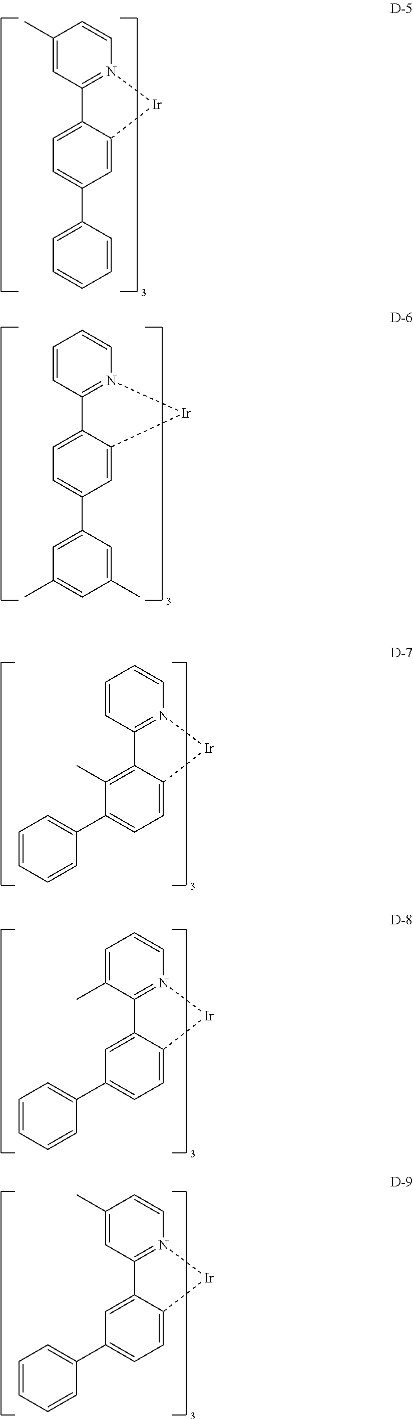

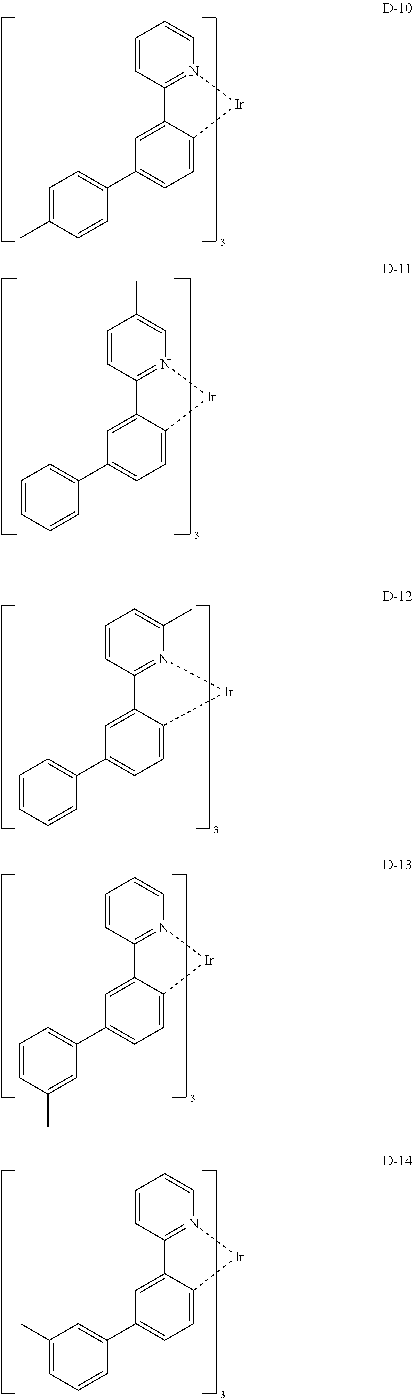

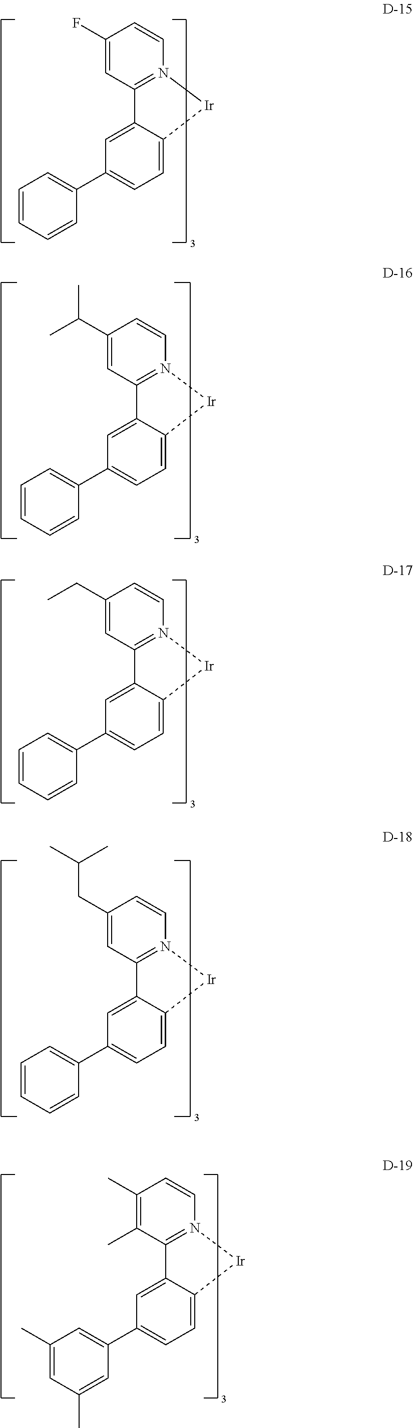

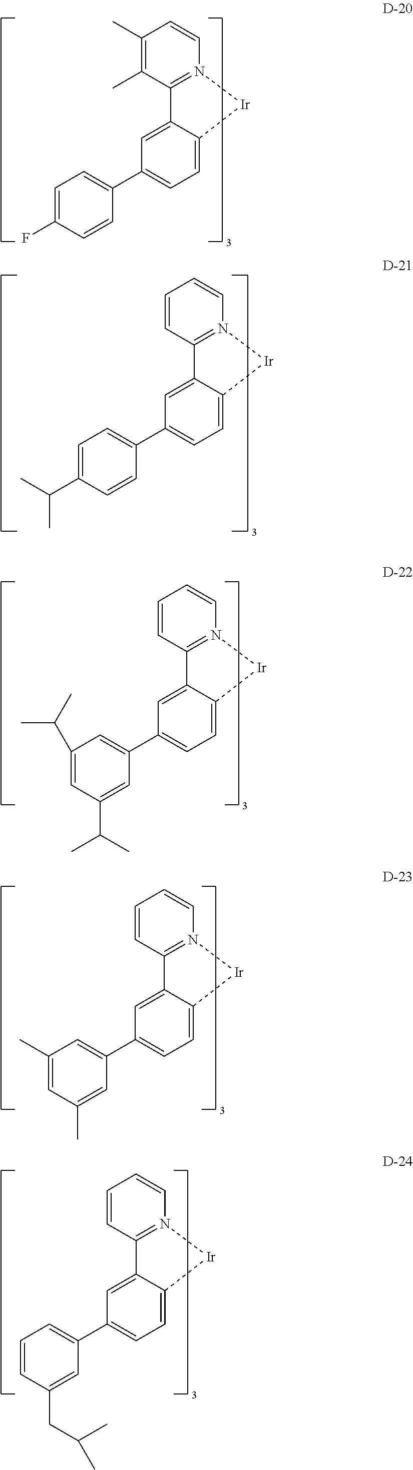

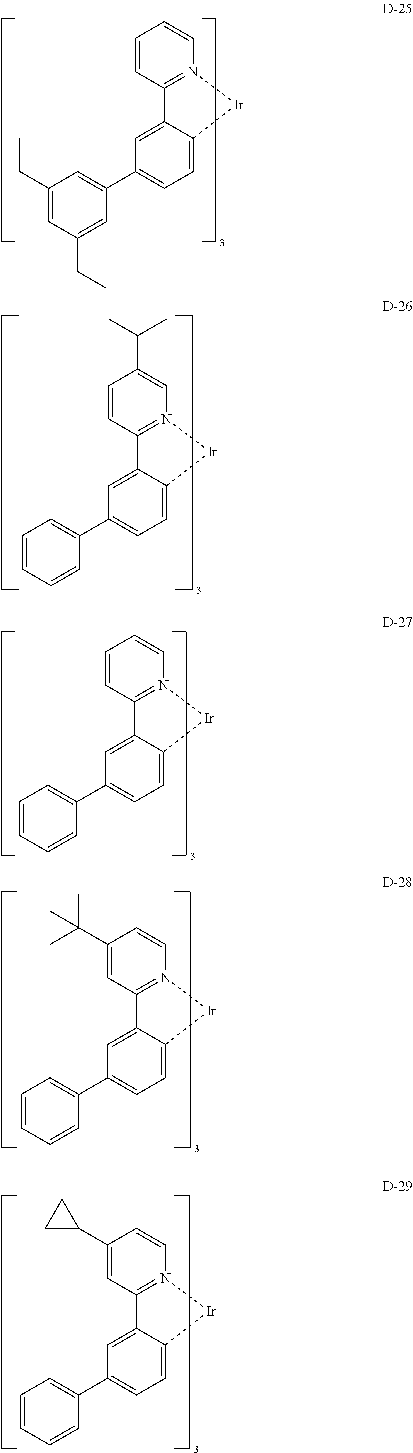

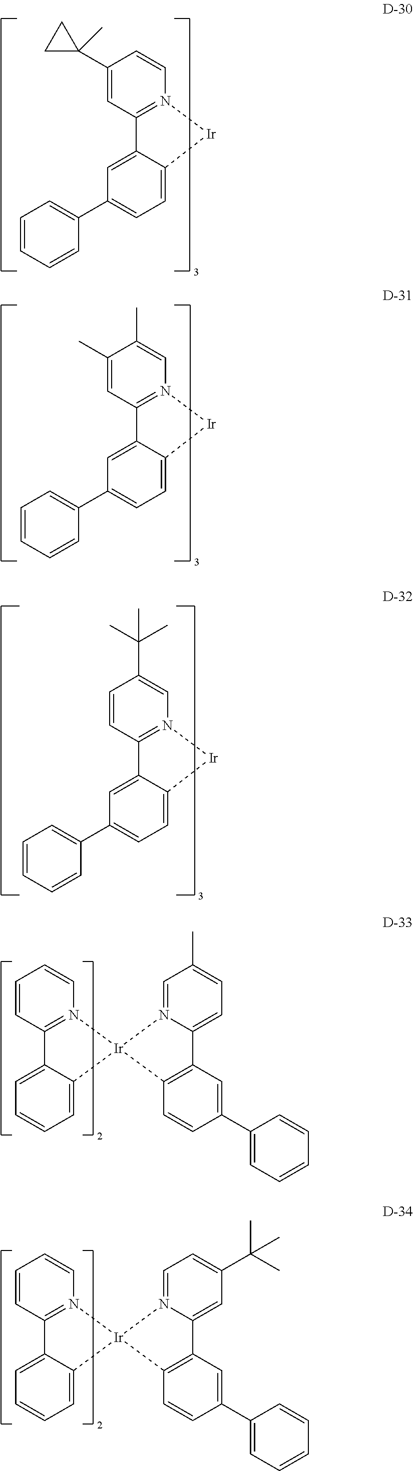

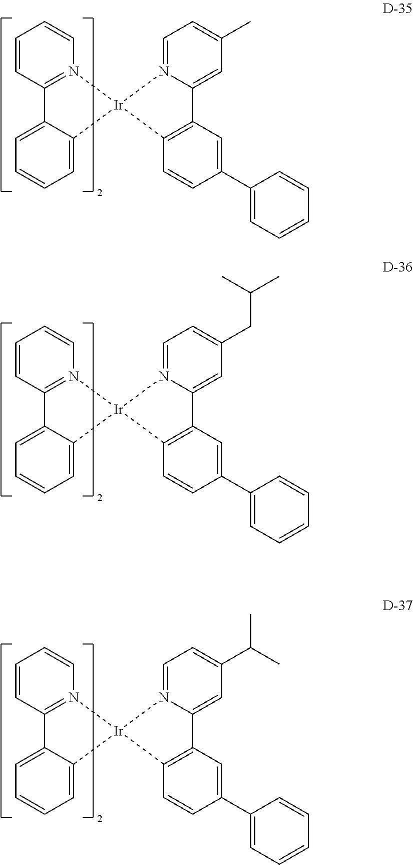

In formulae 2, Cz is preferably selected from the following structures:

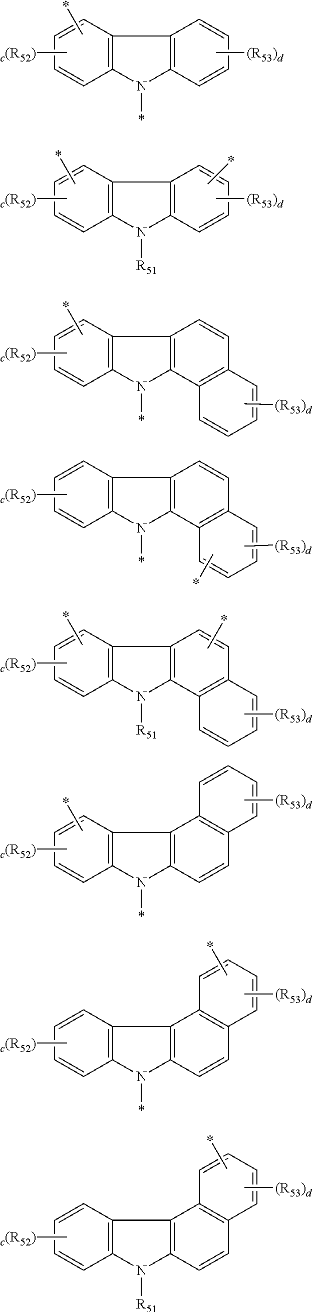

wherein R₅₁, R₅₂, R₅₃, c, and d are as defined in formula 2.

In formula 2, when L₂ is a single bond, formula 2 may be represented by formula 2′, and when L₁ is a single bond, formula 2 may be represented by formula 2″:

H-(Cz-L₁)_{b}-M (2′)

H-(Cz)_{b}-L₂-M (2″)

wherein Cz, L₁, L₂, M, and b are as defined in formula 2.

The compound represented by formula 2 may be represented by formula 5:

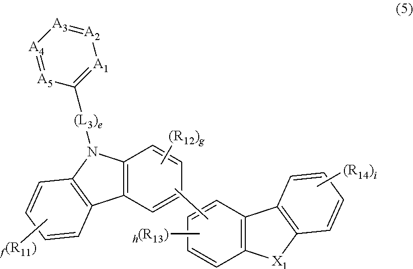

wherein

A₁ to A₅ each independently represent CR₂₃ or N;

X₁ represents —C(R₁₈)(R₁₉)—, —N(R₂₀)—, —S—, —O—, or —Si(R₂₁)(R₂₂)—;

L₃ represents a single bond, a substituted or unsubstituted (C6-C30)arylene, a substituted or unsubstituted 3- to 30-membered heteroarylene, or a substituted or unsubstituted (C6-C30)cycloalkylene;

R₁₁ to R₁₄, and R₁₈ to R₂₂ each independently represent hydrogen, deuterium, a halogen, a substituted or unsubstituted (C1-C30)alkyl, a substituted or unsubstituted (C6-C30)aryl, a substituted or unsubstituted 3- to 30-membered heteroaryl, a substituted or unsubstituted (C3-C30)cycloalkyl, a substituted or unsubstituted 5- to 7-membered heterocycloalkyl, a substituted or unsubstituted (C6-C30)aryl(C1-C30)alkyl, —NR₂₄R₂₅, —SiR₂₆R₂₇1 R₂₈, —SR₂₉, —OR₃₀, a cyano, a nitro, or a hydroxyl;

R₂₄ to R₃₀ each independently represent a substituted or unsubstituted (C1-C30)alkyl, a substituted or unsubstituted (C6-C30)aryl, or a substituted or unsubstituted 3- to 30-membered heteroaryl; or are linked to an adjacent substituent(s) to form a mono- or polycyclic, 5- to 30-membered alicyclic or aromatic ring;

R₂₃ represents hydrogen, deuterium, a halogen, a substituted or unsubstituted (C1-C30)alkyl, a substituted or unsubstituted (C6-C30)aryl, a substituted or unsubstituted (C6-C30)aryl fused with at least one substituted or unsubstituted (C3-C30)alicyclic ring, a substituted or unsubstituted 3- to 30-membered heteroaryl, a substituted or unsubstituted 5- to 7-membered heterocycloalkyl, a 5- to 7-membered heterocycloalkyl fused with at least one substituted or unsubstituted (C6-C30)aromatic ring, a substituted or unsubstituted (C3-C30)cycloalkyl, or a (C3-C30)cycloalkyl fused with at least one substituted or unsubstituted (C6-C30)aromatic ring; or are linked to an adjacent substituent(s) to form a mono- or polycyclic, 5- to 30-membered alicyclic or aromatic ring whose carbon atom(s) may be replaced with at least one hetero atom selected from the group consisting of nitrogen, oxygen and sulfur;

f to i each independently represent an integer of 0 to 4; where at least one of f to i is an integer of 2 or more, each of R₁₁ to R₁₄ may be same or different;

e represents 1 or 2; where e is 2, each of L₃ may be same or different.

The host compound represented by formula 5 is preferably selected from formulae 6 to 8:

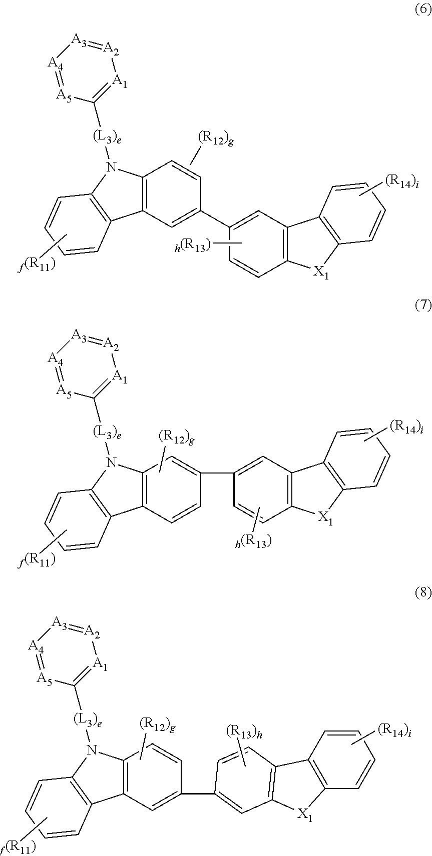

wherein A₁ to A₅, X₁, L₃, R₁₁ to R₁₄, and e to i are as defined in formula 5.

Herein, “(C1-C30)alkyl(ene)” is meant to be a linear or branched alkyl(ene) having 1 to 30 carbon atoms, in which the number of carbon atoms is preferably 1 to 20, more preferably 1 to 10, and includes methyl, ethyl, n-propyl, isopropyl, n-butyl, isobutyl, tert-butyl, etc.; “(C2-C30) alkenyl” is meant to be a linear or branched alkenyl having 2 to 30 carbon atoms, in which the number of carbon atoms is preferably 2 to 20, more preferably 2 to 10, and includes vinyl, 1-propenyl, 2-propenyl, 1-butenyl, 2-butenyl, 3-butenyl, 2-methylbut-2-enyl, etc.; “(C2-C30)alkynyl” is a linear or branched alkynyl having 2 to 30 carbon atoms, in which the number of carbon atoms is preferably 2 to 20, more preferably 2 to 10, and includes ethynyl, 1-propynyl, 2-propynyl, 1-butynyl, 2-butynyl, 3-butynyl, 1-methylpent-2-ynyl, etc.; “(C3-C30)cycloalkyl” is a mono- or polycyclic hydrocarbon having 3 to 30 carbon atoms, in which the number of carbon atoms is preferably 3 to 20, more preferably 3 to 7, and includes cyclopropyl, cyclobutyl, cyclopentyl, cyclohexyl, etc.; “3- to 7-membered heterocycloalkyl” is a cycloalkyl having at least one heteroatom selected from B, N, O, S, P(═O), Si and P, preferably O, S and N, and 3 to 7 ring backbone atoms, and includes tetrahydrofuran, pyrrolidine, thiolan, tetrahydropyran, etc.; “(C6-C30)aryl(ene)” is a monocyclic or fused ring derived from an aromatic hydrocarbon having 6 to 30 carbon atoms, in which the number of carbon atoms is preferably 6 to 20, more preferably 6 to 12, and includes phenyl, biphenyl, terphenyl, naphthyl, fluorenyl, phenanthrenyl, anthracenyl, indenyl, triphenylenyl, pyrenyl, tetracenyl, perylenyl, chrysenyl, naphthacenyl, fluoranthenyl, etc.; “3- to 30-membered heteroaryl(ene)” is an aryl group having at least one, preferably 1 to 4 heteroatom selected from the group consisting of B, N, O, S, P(═O), Si and P, and 3 to 30 ring backbone atoms; is a monocyclic ring, or a fused ring condensed with at least one benzene ring; has preferably 5 to 20, more preferably 5 to 15 ring backbone atoms; may be partially saturated; may be one formed by linking at least one heteroaryl or aryl group to a heteroaryl group via a single bond(s); and includes a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “halogen” includes F, Cl, Br and I.

Herein, “substituted” in the expression “substituted or unsubstituted” means that a hydrogen atom in a certain functional group is replaced with another atom or group, i.e., a substituent.

The substituents of the substituted alkyl(ene), the substituted aryl(ene), the substituted heteroaryl(ene), the substituted cycloalkyl, and the substituted heterocycloalkyl in the above formulae each independently are preferably at least one selected from the group consisting of deuterium; a halogen; a (C1-C30)alkyl unsubstituted or substituted with a halogen; a (C6-C30)aryl; a 3- to 30-membered heteroaryl unsubstituted or substituted with a (C6-C30)aryl; a 5- to 7-membered heterocycloalkyl; a 5- to 7-membered heterocycloalkyl fused with at least one (C6-C30)aromatic ring; a (C3-C30)cycloalkyl; a (C6-C30)cycloalkyl fused with at least one (C6-C30)aromatic ring; RⱼRₖRₗSi—; a (C2-C30)alkenyl; a (C2-C30)alkynyl; a cyano; a carbazolyl; —NRₘRₒ; —BRₚR_{q}; —PRᵣRₛ; —P(═O)RₜRᵤ; a (C6-C30)aryl(C1-C30)alkyl; a (C1-C30)alkyl(C6-C30)aryl; RᵥZ—; R_{w}C(═O)—; R_{w}C(═O)O—; a carboxyl; a nitro; and a hydroxyl, wherein Rⱼ to Rₘ, and Rₒ to Rᵥ each independently represent a (C1-C30)alkyl, a (C6-C30)aryl, or a 3- to 30-membered heteroaryl; or are linked to an adjacent substituent(s) to form a mono- or polycyclic, 5- to 30-membered alicyclic or aromatic ring whose carbon atom(s) may be replaced with at least one hetero atom selected from the group consisting of nitrogen, oxygen and sulfur; Z represents S or O; and R_{w} represents a (C1-C30)alkyl, a (C1-C30)alkoxy, a (C6-C30)aryl, or a (C6-C30)aryloxy.

The representative compounds of formula 2 include the following compounds, but are not limited thereto:

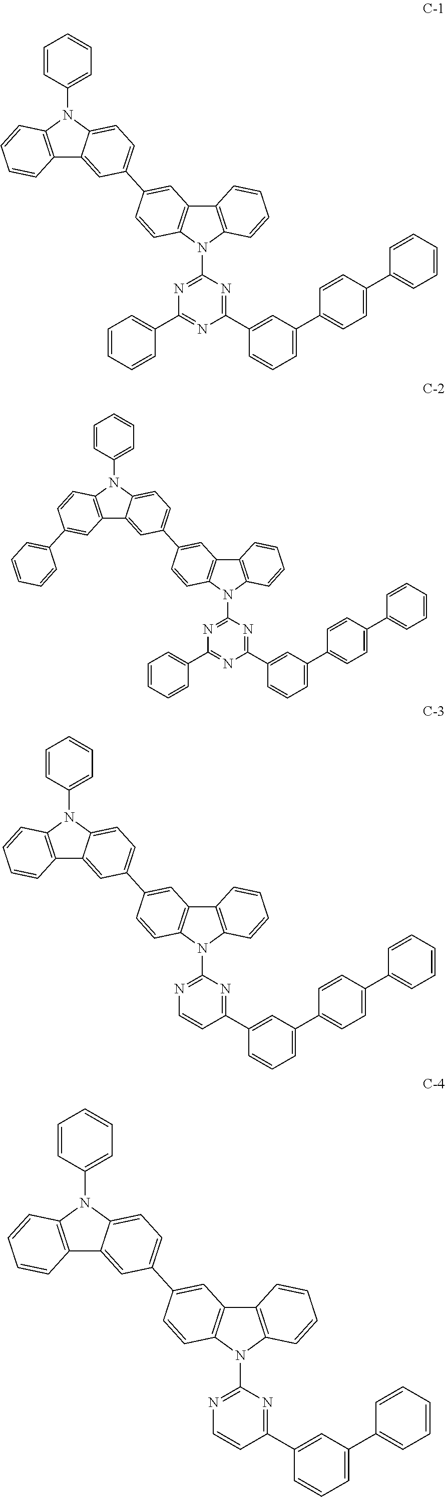 [SMILES: c1ccc(-c2ccc(-c3cccc(-c4nc(-c5ccccc5)nc(-n5c6ccccc6c6cc(-c7ccc8c(c7)c7ccccc7n8-c7ccccc7)ccc65)n4)c3)cc2)cc1 ; c1ccc(-c2ccc(-c3cccc(-c4nc(-c5ccccc5)nc(-n5c6ccccc6c6cc(-c7ccc8c(c7)c7cc(-c9ccccc9)ccc7n8-c7ccccc7)ccc65)n4)c3)cc2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1 ; c1ccc(-c2cccc(-c3ccnc(-n4c5ccccc5c5cc(-c6ccc7c(c6)c6ccccc6n7-c6ccccc6)ccc54)n3)c2)cc1]

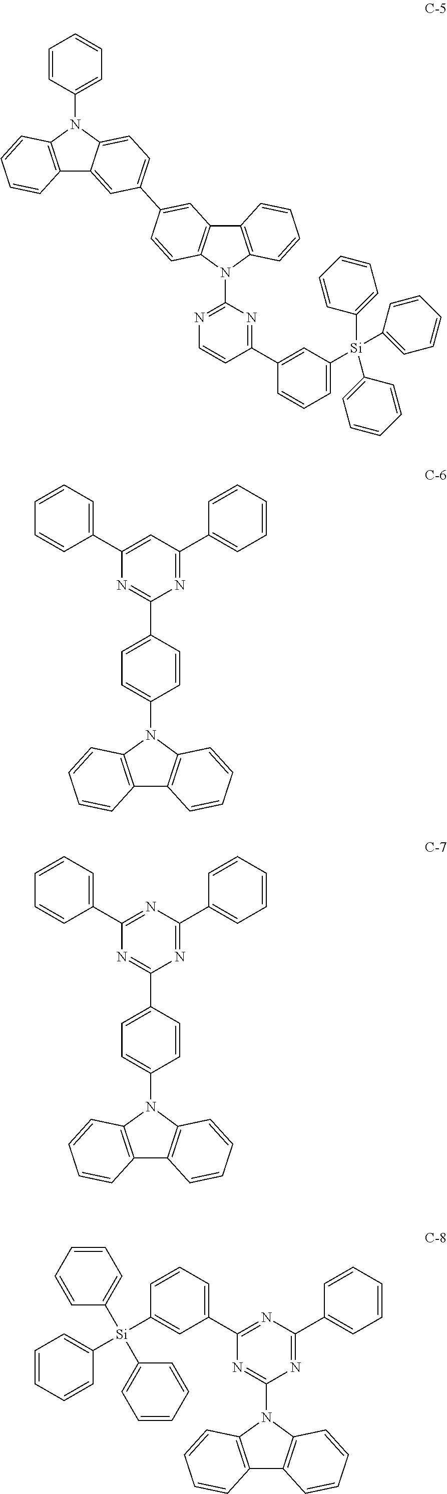 [SMILES: c1ccc(-n2c3ccccc3c3cc(-c4ccc5c(c4)c4ccccc4n5-c4nccc(-c5cccc([Si](c6ccccc6)(c6ccccc6)c6ccccc6)c5)n4)ccc32)cc1 ; c1ccc(-c2cc(-c3ccccc3)nc(-c3ccc(-n4c5ccccc5c5ccccc54)cc3)n2)cc1 ; c1ccc(-c2nc(-c3ccccc3)nc(-c3ccc(-n4c5ccccc5c5ccccc54)cc3)n2)cc1 ; c1ccc(-c2nc(-c3cccc([Si](c4ccccc4)(c4ccccc4)c4ccccc4)c3)nc(-n3c4ccccc4c4ccccc43)n2)cc1]

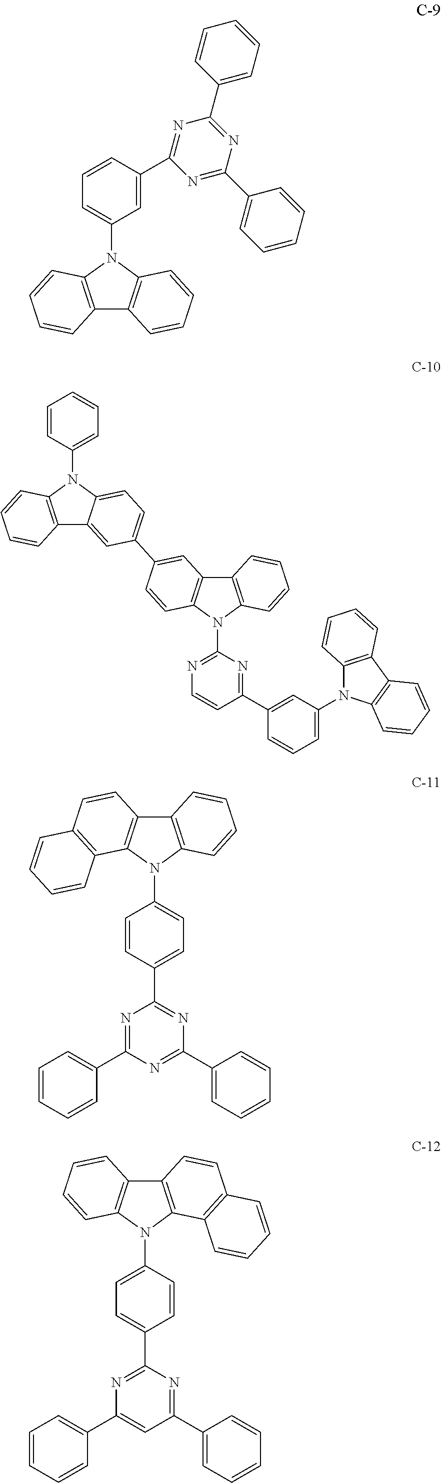

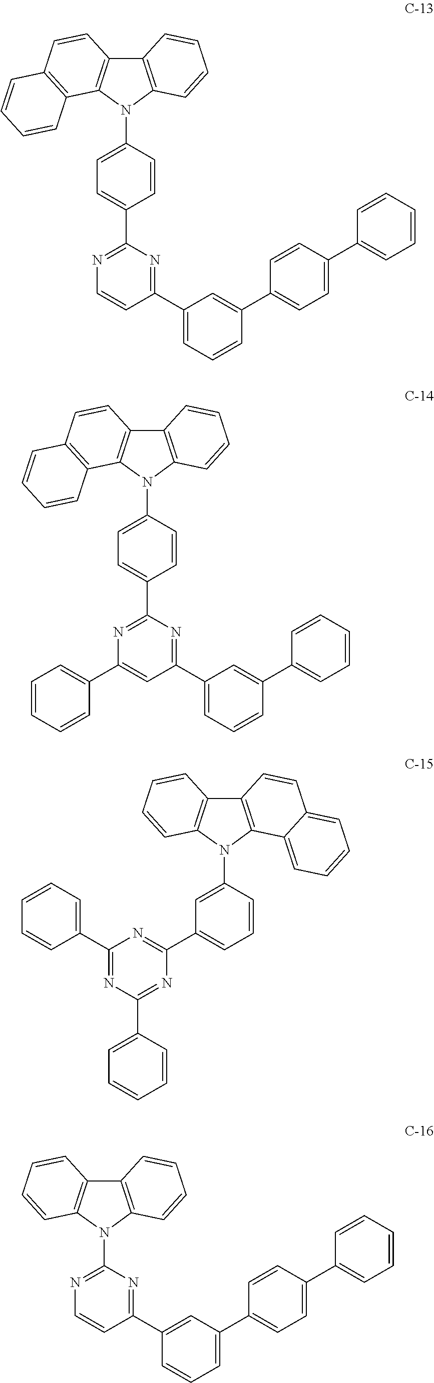 [SMILES: c1ccc(-c2ccc(-c3cccc(-c4ccnc(-c5ccc(-n6c7ccccc7c7ccc8ccccc8c76)cc5)n4)c3)cc2)cc1 ; c1ccc(-c2cccc(-c3cc(-c4ccccc4)nc(-c4ccc(-n5c6ccccc6c6ccc7ccccc7c65)cc4)n3)c2)cc1 ; c1ccc(-c2nc(-c3ccccc3)nc(-c3cccc(-n4c5ccccc5c5ccc6ccccc6c54)c3)n2)cc1 ; c1ccc(-c2ccc(-c3cccc(-c4ccnc(-n5c6ccccc6c6ccccc65)n4)c3)cc2)cc1]

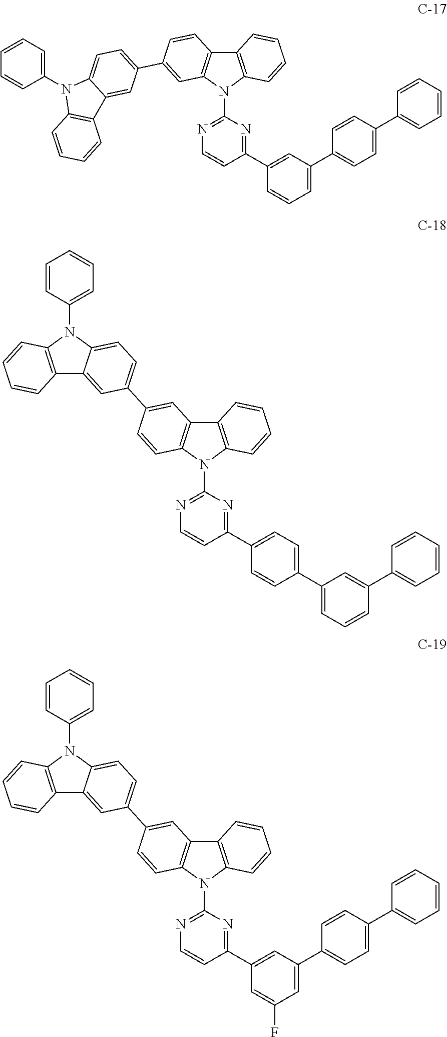 [SMILES: c1ccc(-c2ccc(-c3cccc(-c4ccnc(-n5c6ccccc6c6ccc(-c7ccc8c(c7)c7ccccc7n8-c7ccccc7)cc65)n4)c3)cc2)cc1 ; c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1 ; Fc1cc(-c2ccc(-c3ccccc3)cc2)cc(-c2ccnc(-n3c4ccccc4c4cc(-c5ccc6c(c5)c5ccccc5n6-c5ccccc5)ccc43)n2)c1]

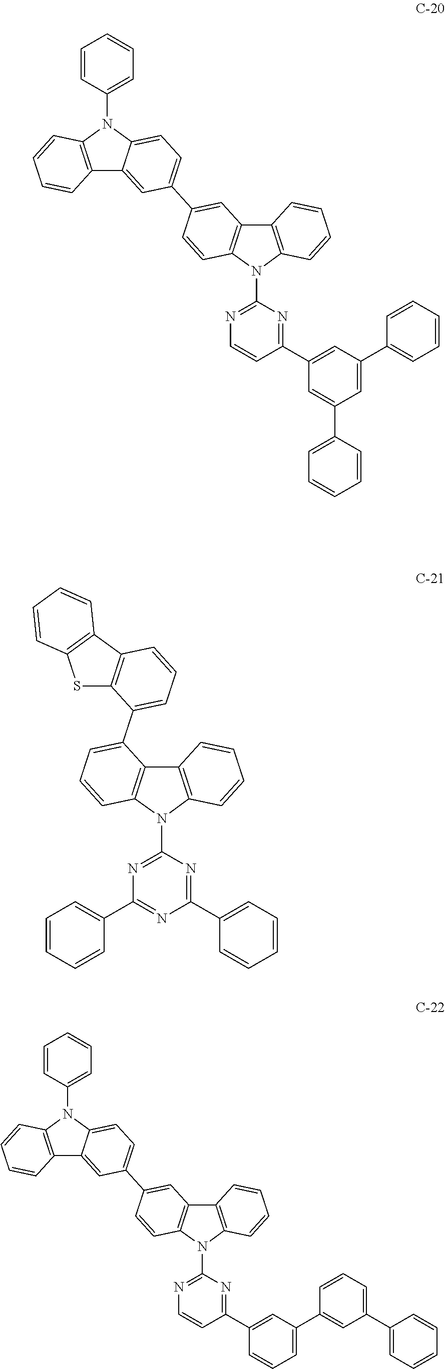 [SMILES: c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1 ; c1ccc(-c2nc(-c3ccccc3)nc(-n3c4ccccc4c4c(-c5cccc6c5sc5ccccc56)cccc43)n2)cc1 ; c1ccc(-c2cccc(-c3cccc(-c4ccnc(-n5c6ccccc6c6cc(-c7ccc8c(c7)c7ccccc7n8-c7ccccc7)ccc65)n4)c3)c2)cc1]

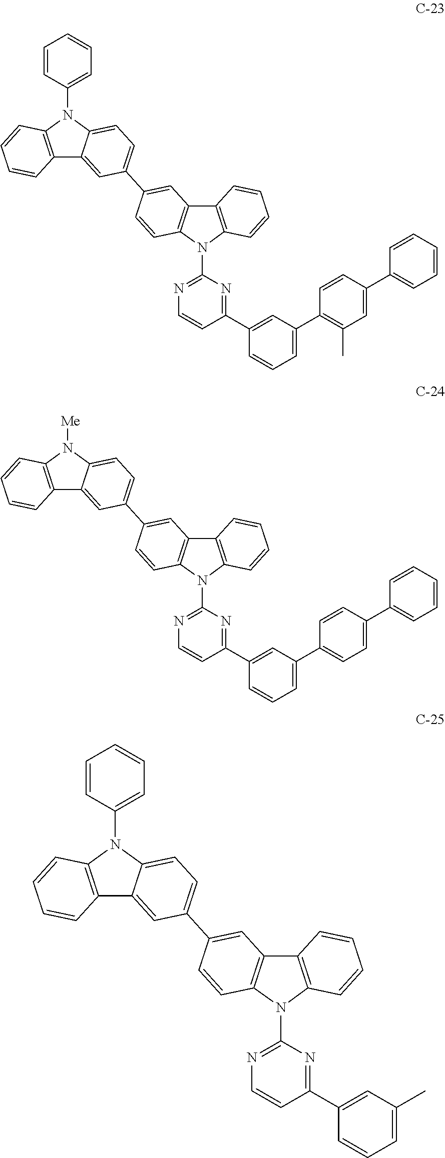 [SMILES: Cc1cc(-c2ccccc2)ccc1-c1cccc(-c2ccnc(-n3c4ccccc4c4cc(-c5ccc6c(c5)c5ccccc5n6-c5ccccc5)ccc43)n2)c1 ; Cn1c2ccccc2c2cc(-c3ccc4c(c3)c3ccccc3n4-c3nccc(-c4cccc(-c5ccc(-c6ccccc6)cc5)c4)n3)ccc21 ; Cc1cccc(-c2ccnc(-n3c4ccccc4c4cc(-c5ccc6c(c5)c5ccccc5n6-c5ccccc5)ccc43)n2)c1]

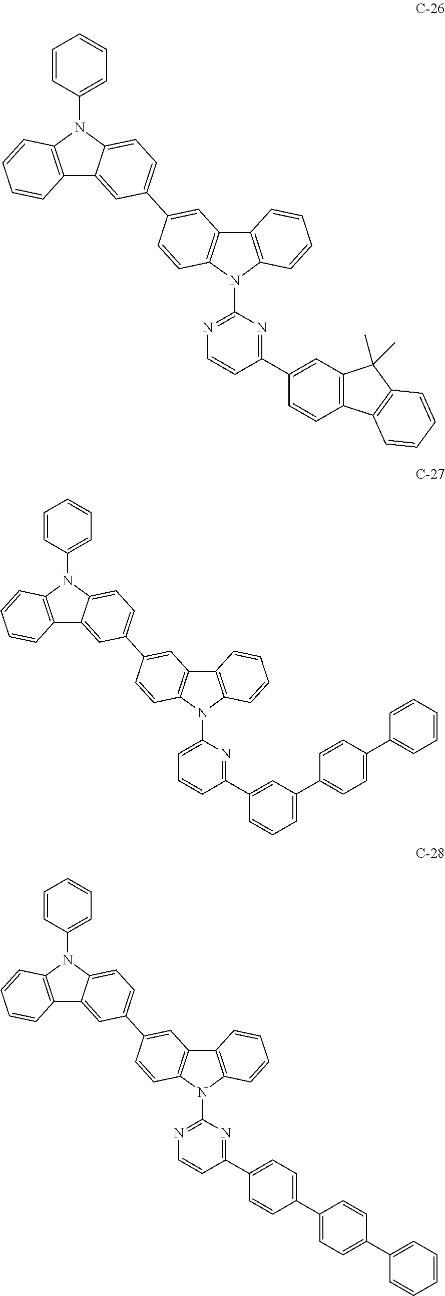 [SMILES: CC1(C)c2ccccc2-c2ccc(-c3ccnc(-n4c5ccccc5c5cc(-c6ccc7c(c6)c6ccccc6n7-c6ccccc6)ccc54)n3)cc21 ; c1ccc(-c2ccc(-c3cccc(-c4cccc(-n5c6ccccc6c6cc(-c7ccc8c(c7)c7ccccc7n8-c7ccccc7)ccc65)n4)c3)cc2)cc1 ; c1ccc(-c2ccc(-c3ccc(-c4ccnc(-n5c6ccccc6c6cc(-c7ccc8c(c7)c7ccccc7n8-c7ccccc7)ccc65)n4)cc3)cc2)cc1]

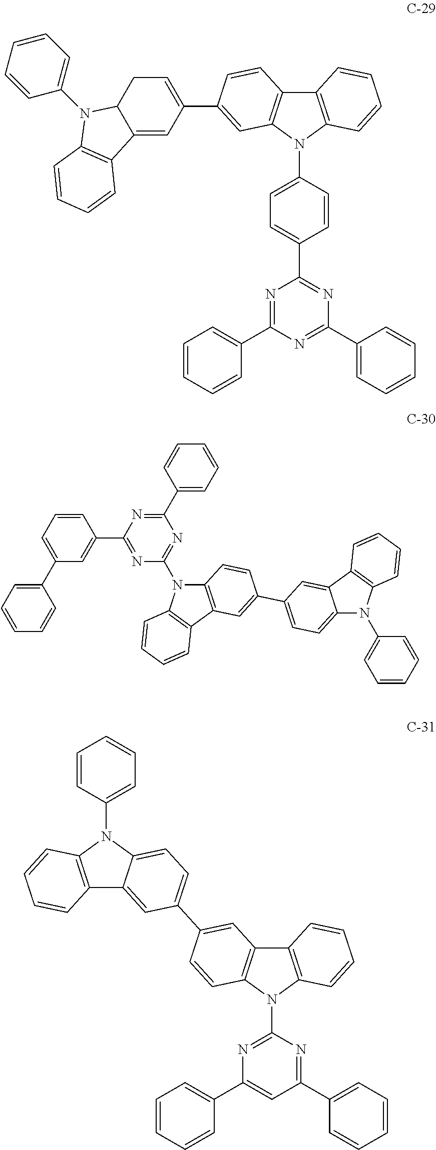 [SMILES: C1=C(c2ccc3c4ccccc4n(-c4ccc(-c5nc(-c6ccccc6)nc(-c6ccccc6)n5)cc4)c3c2)C=C2c3ccccc3N(c3ccccc3)C2C1 ; c1ccc(-c2cccc(-c3nc(-c4ccccc4)nc(-n4c5ccccc5c5cc(-c6ccc7c(c6)c6ccccc6n7-c6ccccc6)ccc54)n3)c2)cc1 ; c1ccc(-c2cc(-c3ccccc3)nc(-n3c4ccccc4c4cc(-c5ccc6c(c5)c5ccccc5n6-c5ccccc5)ccc43)n2)cc1]

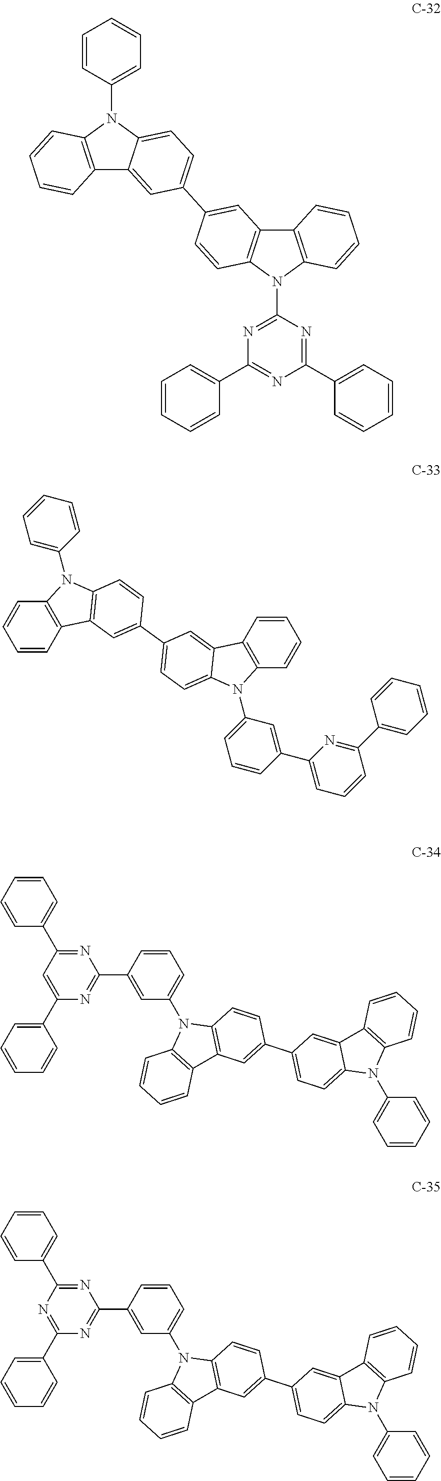 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-c3cccc(-n4c5ccccc5c5cc(-c6ccc7c(c6)c6ccccc6n7-c6ccccc6)ccc54)c3)n2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

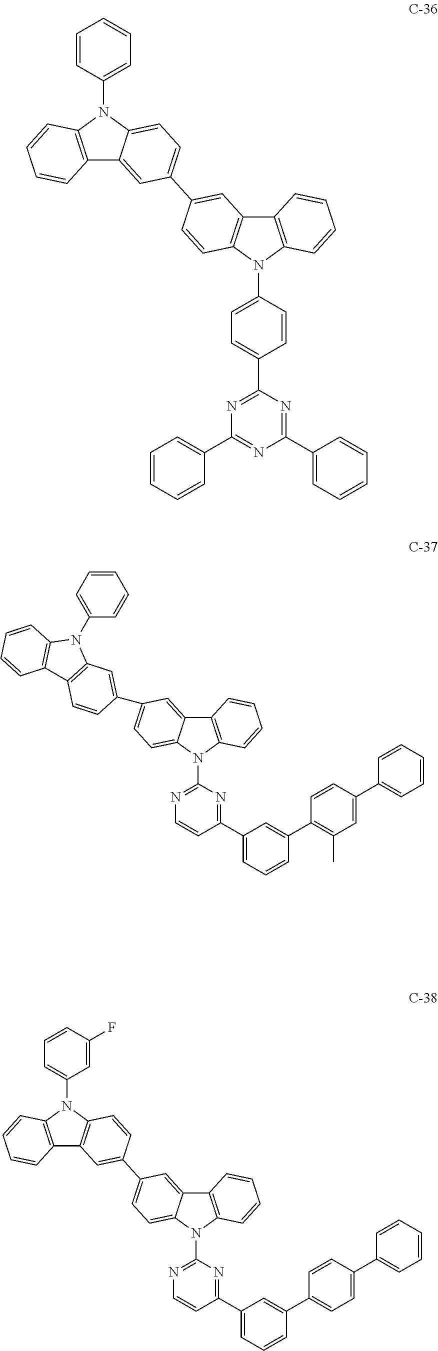 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; Cc1cc(-c2ccccc2)ccc1-c1cccc(-c2ccnc(-n3c4ccccc4c4cc(-c5ccc6c7ccccc7n(-c7ccccc7)c6c5)ccc43)n2)c1 ; Fc1cccc(-n2c3ccccc3c3cc(-c4ccc5c(c4)c4ccccc4n5-c4nccc(-c5cccc(-c6ccc(-c7ccccc7)cc6)c5)n4)ccc32)c1]

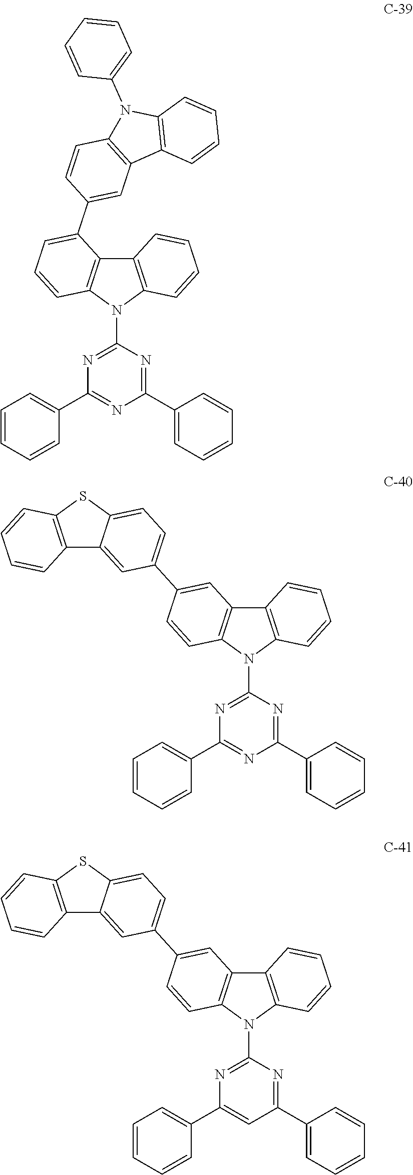 [SMILES: c1ccc(-c2nc(-c3ccccc3)nc(-n3c4ccccc4c4c(-c5ccc6c(c5)c5ccccc5n6-c5ccccc5)cccc43)n2)cc1 ; c1ccc(-c2nc(-c3ccccc3)nc(-n3c4ccccc4c4cc(-c5ccc6sc7ccccc7c6c5)ccc43)n2)cc1 ; c1ccc(-c2cc(-c3ccccc3)nc(-n3c4ccccc4c4cc(-c5ccc6sc7ccccc7c6c5)ccc43)n2)cc1]

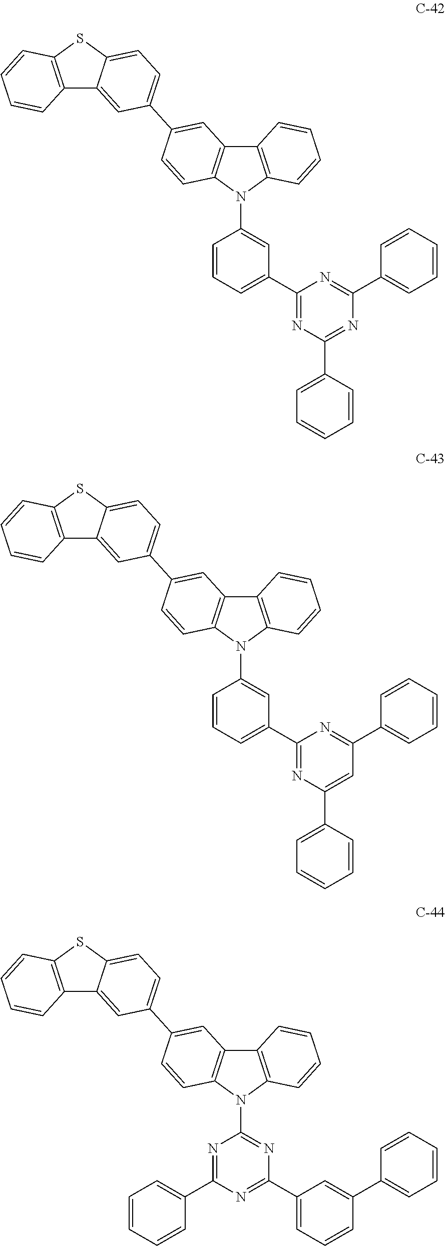 [SMILES: c1ccc(-c2nc(-c3ccccc3)nc(-c3cccc(-n4c5ccccc5c5cc(-c6ccc7sc8ccccc8c7c6)ccc54)c3)n2)cc1 ; c1ccc(-c2cc(-c3ccccc3)nc(-c3cccc(-n4c5ccccc5c5cc(-c6ccc7sc8ccccc8c7c6)ccc54)c3)n2)cc1 ; c1ccc(-c2cccc(-c3nc(-c4ccccc4)nc(-n4c5ccccc5c5cc(-c6ccc7sc8ccccc8c7c6)ccc54)n3)c2)cc1]

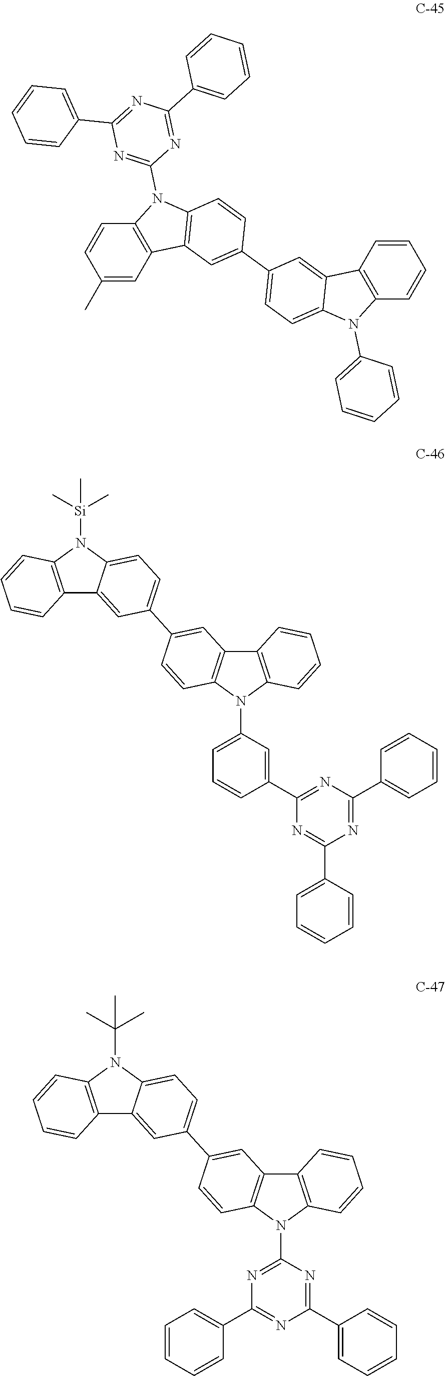 [SMILES: Cc1ccc2c(c1)c1cc(-c3ccc4c(c3)c3ccccc3n4-c3ccccc3)ccc1n2-c1nc(-c2ccccc2)nc(-c2ccccc2)n1 ; C[Si](C)(C)n1c2ccccc2c2cc(-c3ccc4c(c3)c3ccccc3n4-c3cccc(-c4nc(-c5ccccc5)nc(-c5ccccc5)n4)c3)ccc21 ; CC(C)(C)n1c2ccccc2c2cc(-c3ccc4c(c3)c3ccccc3n4-c3nc(-c4ccccc4)nc(-c4ccccc4)n3)ccc21]

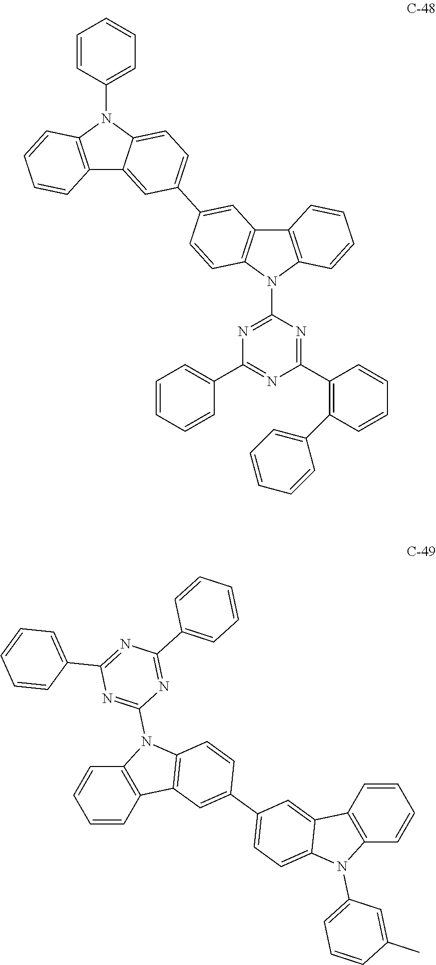 [SMILES: c1ccc(-c2nc(-c3ccccc3-c3ccccc3)nc(-n3c4ccccc4c4cc(-c5ccc6c(c5)c5ccccc5n6-c5ccccc5)ccc43)n2)cc1 ; Cc1cccc(-n2c3ccccc3c3cc(-c4ccc5c(c4)c4ccccc4n5-c4nc(-c5ccccc5)nc(-c5ccccc5)n4)ccc32)c1]

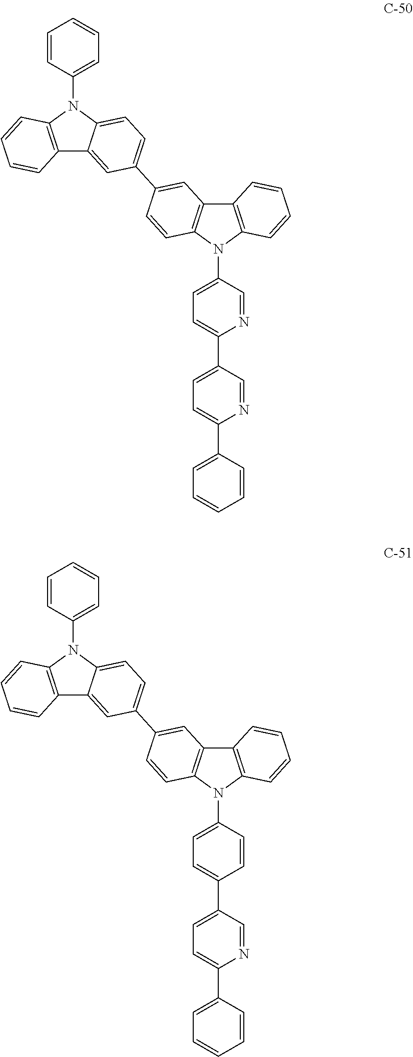 [SMILES: c1ccc(-c2ccc(-c3ccc(-n4c5ccccc5c5cc(-c6ccc7c(c6)c6ccccc6n7-c6ccccc6)ccc54)cn3)cn2)cc1 ; c1ccc(-c2ccc(-c3ccc(-n4c5ccccc5c5cc(-c6ccc7c(c6)c6ccccc6n7-c6ccccc6)ccc54)cc3)cn2)cc1]

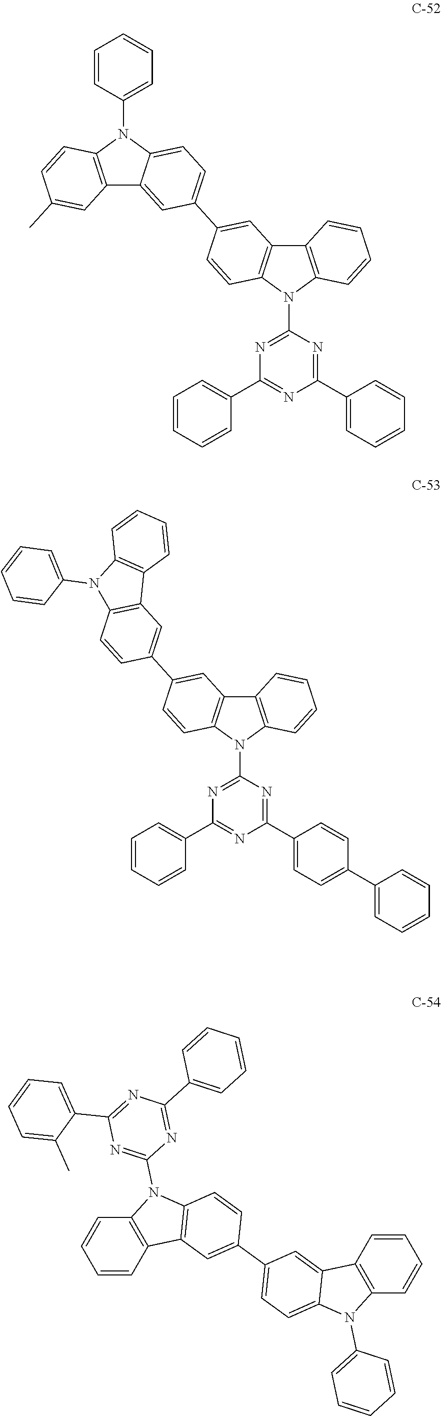 [SMILES: Cc1ccc2c(c1)c1cc(-c3ccc4c(c3)c3ccccc3n4-c3nc(-c4ccccc4)nc(-c4ccccc4)n3)ccc1n2-c1ccccc1 ; c1ccc(-c2ccc(-c3nc(-c4ccccc4)nc(-n4c5ccccc5c5cc(-c6ccc7c(c6)c6ccccc6n7-c6ccccc6)ccc54)n3)cc2)cc1 ; Cc1ccccc1-c1nc(-c2ccccc2)nc(-n2c3ccccc3c3cc(-c4ccc5c(c4)c4ccccc4n5-c4ccccc4)ccc32)n1]

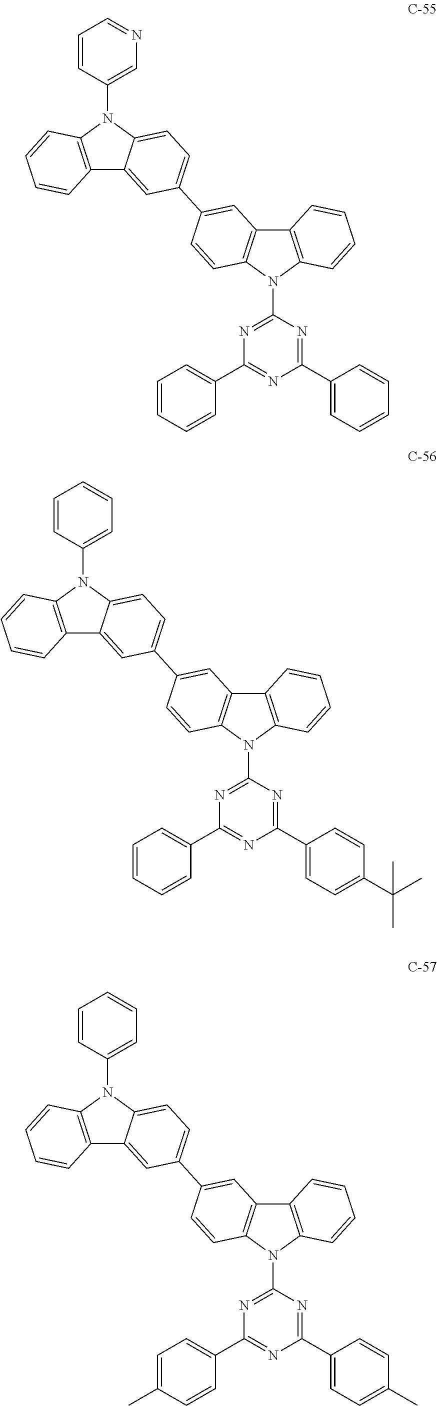 [SMILES: c1ccc(-c2nc(-c3ccccc3)nc(-n3c4ccccc4c4cc(-c5ccc6c(c5)c5ccccc5n6-c5cccnc5)ccc43)n2)cc1 ; CC(C)(C)c1ccc(-c2nc(-c3ccccc3)nc(-n3c4ccccc4c4cc(-c5ccc6c(c5)c5ccccc5n6-c5ccccc5)ccc43)n2)cc1 ; Cc1ccc(-c2nc(-c3ccc(C)cc3)nc(-n3c4ccccc4c4cc(-c5ccc6c(c5)c5ccccc5n6-c5ccccc5)ccc43)n2)cc1]

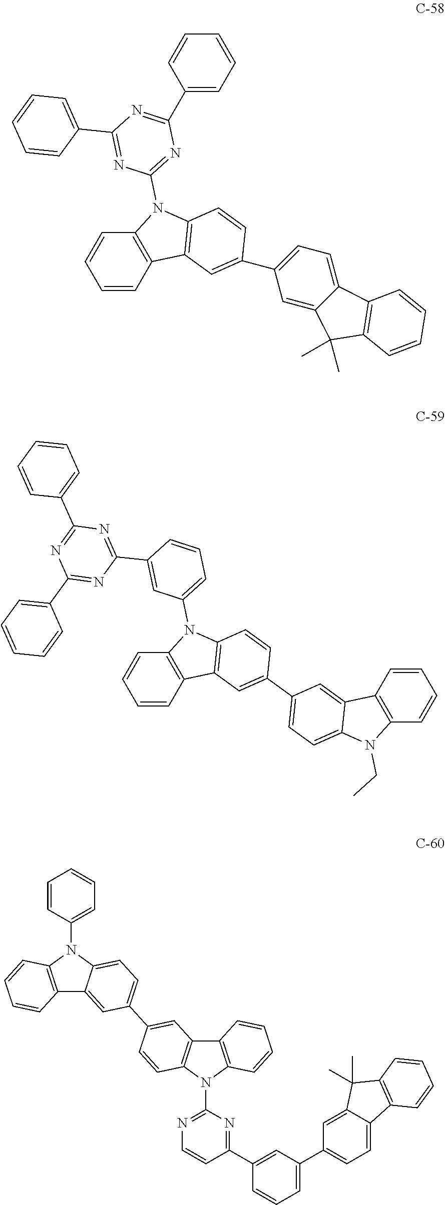 [SMILES: CC1(C)c2ccccc2-c2ccc(-c3ccc4c(c3)c3ccccc3n4-c3nc(-c4ccccc4)nc(-c4ccccc4)n3)cc21 ; CCn1c2ccccc2c2cc(-c3ccc4c(c3)c3ccccc3n4-c3cccc(-c4nc(-c5ccccc5)nc(-c5ccccc5)n4)c3)ccc21 ; CC1(C)c2ccccc2-c2ccc(-c3cccc(-c4ccnc(-n5c6ccccc6c6cc(-c7ccc8c(c7)c7ccccc7n8-c7ccccc7)ccc65)n4)c3)cc21]

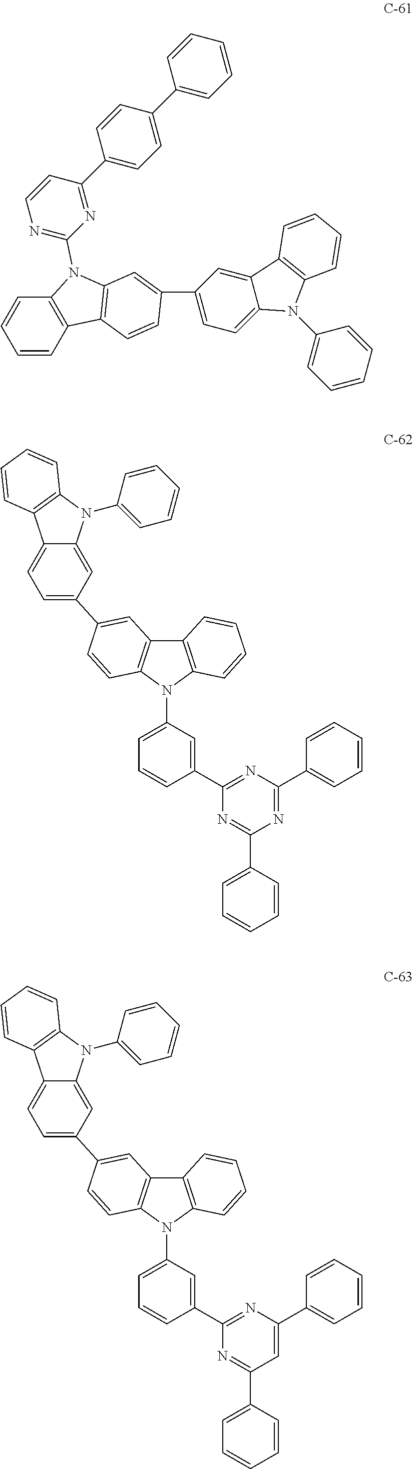 [SMILES: c1ccc(-c2ccc(-c3ccnc(-n4c5ccccc5c5ccc(-c6ccc7c(c6)c6ccccc6n7-c6ccccc6)cc54)n3)cc2)cc1 ; c1ccc(-c2nc(-c3ccccc3)nc(-c3cccc(-n4c5ccccc5c5cc(-c6ccc7c8ccccc8n(-c8ccccc8)c7c6)ccc54)c3)n2)cc1 ; c1ccc(-c2cc(-c3ccccc3)nc(-c3cccc(-n4c5ccccc5c5cc(-c6ccc7c8ccccc8n(-c8ccccc8)c7c6)ccc54)c3)n2)cc1]

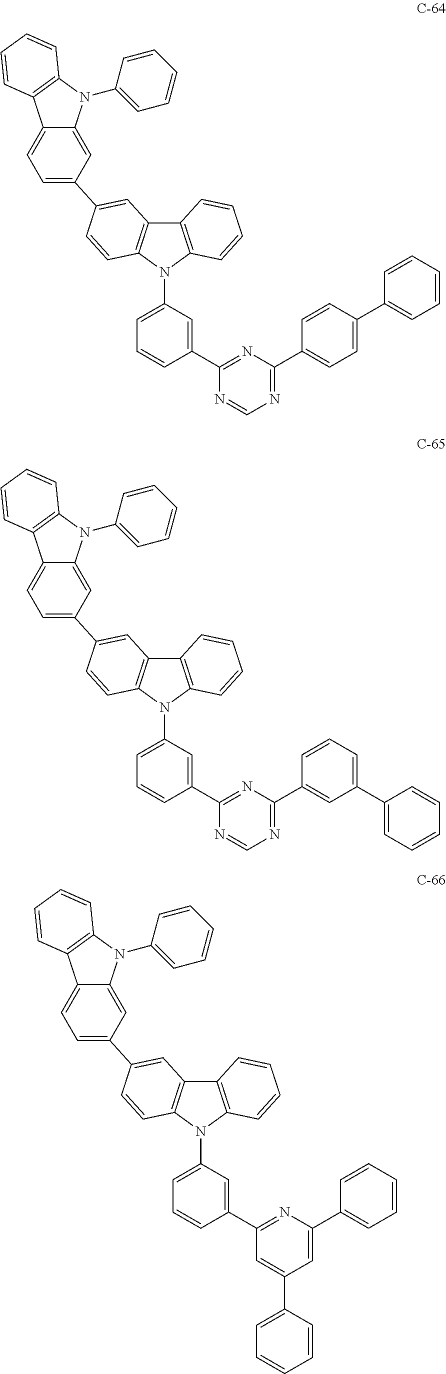 [SMILES: c1ccc(-c2ccc(-c3ncnc(-c4cccc(-n5c6ccccc6c6cc(-c7ccc8c9ccccc9n(-c9ccccc9)c8c7)ccc65)c4)n3)cc2)cc1 ; c1ccc(-c2cccc(-c3ncnc(-c4cccc(-n5c6ccccc6c6cc(-c7ccc8c9ccccc9n(-c9ccccc9)c8c7)ccc65)c4)n3)c2)cc1 ; c1ccc(-c2cc(-c3ccccc3)nc(-c3cccc(-n4c5ccccc5c5cc(-c6ccc7c8ccccc8n(-c8ccccc8)c7c6)ccc54)c3)c2)cc1]

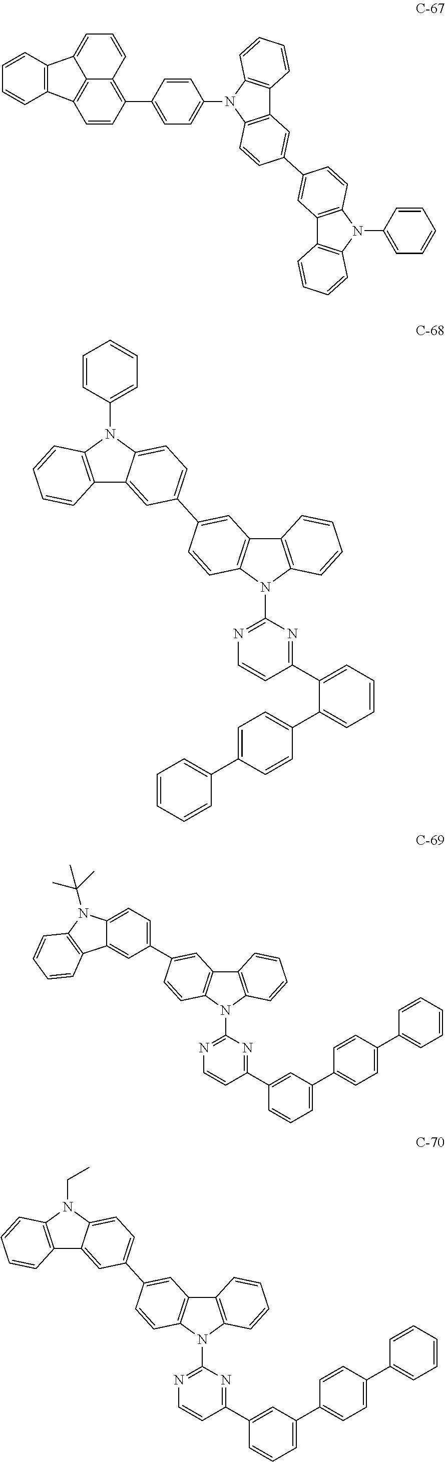 [SMILES: c1ccc(-n2c3ccccc3c3cc(-c4ccc5c(c4)c4ccccc4n5-c4ccc(-c5ccc6c7c(cccc57)-c5ccccc5-6)cc4)ccc32)cc1 ; c1ccc(-c2ccc(-c3ccccc3-c3ccnc(-n4c5ccccc5c5cc(-c6ccc7c(c6)c6ccccc6n7-c6ccccc6)ccc54)n3)cc2)cc1 ; CC(C)(C)n1c2ccccc2c2cc(-c3ccc4c(c3)c3ccccc3n4-c3nccc(-c4cccc(-c5ccc(-c6ccccc6)cc5)c4)n3)ccc21 ; CCn1c2ccccc2c2cc(-c3ccc4c(c3)c3ccccc3n4-c3nccc(-c4cccc(-c5ccc(-c6ccccc6)cc5)c4)n3)ccc21]

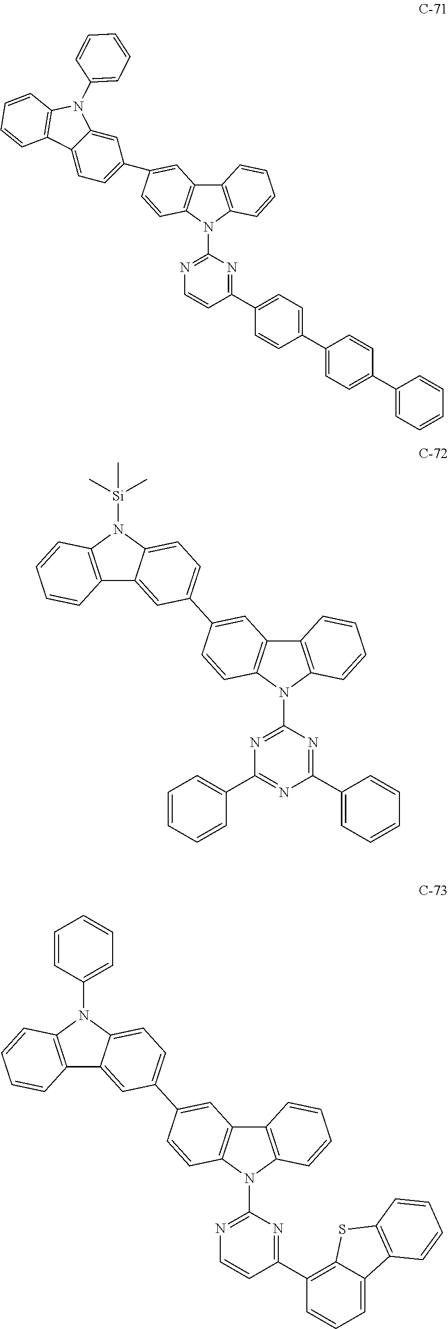 [SMILES: c1ccc(-c2ccc(-c3ccc(-c4ccnc(-n5c6ccccc6c6cc(-c7ccc8c9ccccc9n(-c9ccccc9)c8c7)ccc65)n4)cc3)cc2)cc1 ; C[Si](C)(C)n1c2ccccc2c2cc(-c3ccc4c(c3)c3ccccc3n4-c3nc(-c4ccccc4)nc(-c4ccccc4)n3)ccc21 ; c1ccc(-n2c3ccccc3c3cc(-c4ccc5c(c4)c4ccccc4n5-c4nccc(-c5cccc6c5sc5ccccc56)n4)ccc32)cc1]

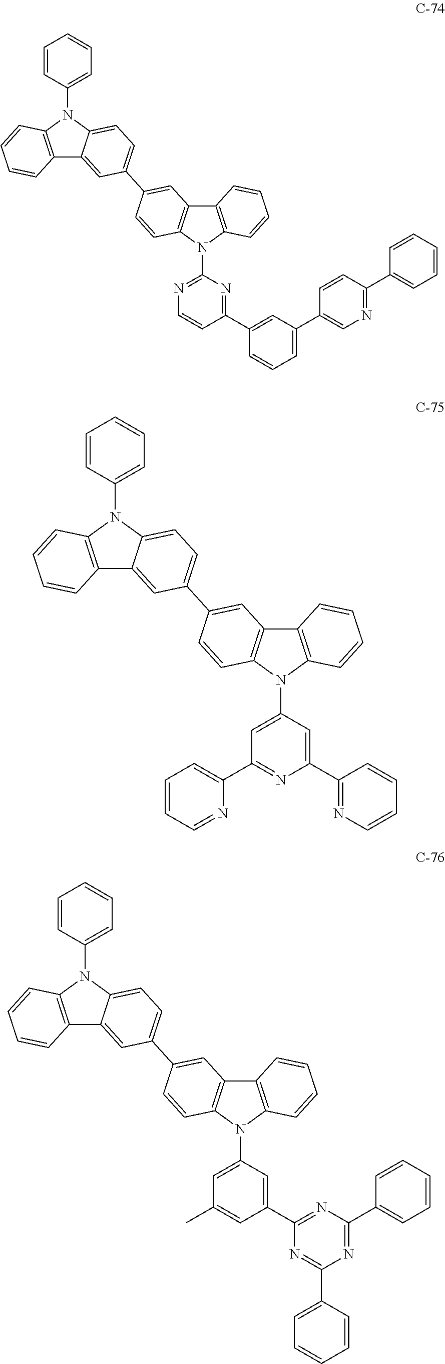 [SMILES: c1ccc(-c2ccc(-c3cccc(-c4ccnc(-n5c6ccccc6c6cc(-c7ccc8c(c7)c7ccccc7n8-c7ccccc7)ccc65)n4)c3)cn2)cc1 ; c1ccc(-n2c3ccccc3c3cc(-c4ccc5c(c4)c4ccccc4n5-c4cc(-c5ccccn5)nc(-c5ccccn5)c4)ccc32)cc1 ; Cc1cc(-c2nc(-c3ccccc3)nc(-c3ccccc3)n2)cc(-n2c3ccccc3c3cc(-c4ccc5c(c4)c4ccccc4n5-c4ccccc4)ccc32)c1]

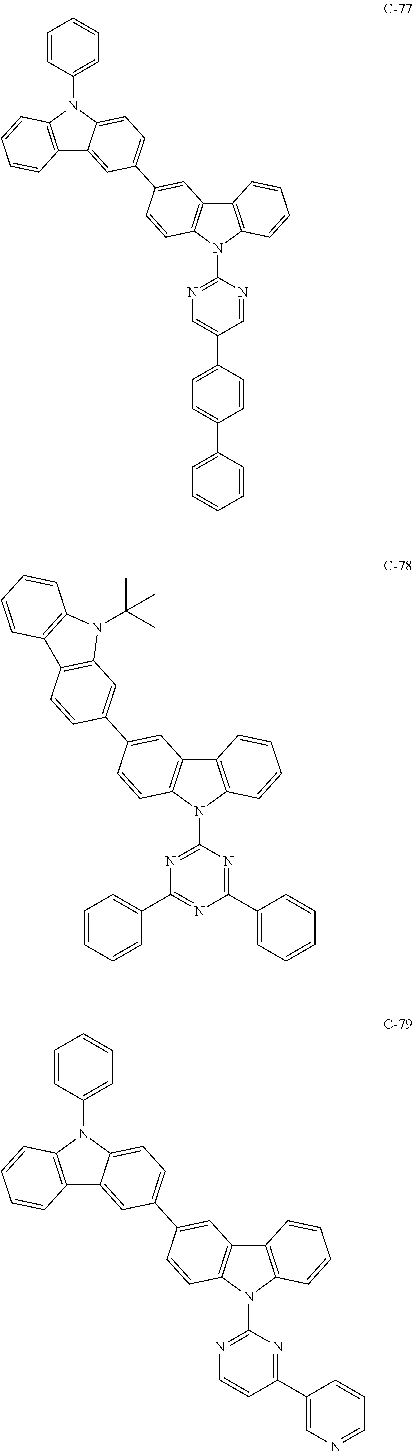 [SMILES: c1ccc(-c2ccc(-c3cnc(-n4c5ccccc5c5cc(-c6ccc7c(c6)c6ccccc6n7-c6ccccc6)ccc54)nc3)cc2)cc1 ; CC(C)(C)n1c2ccccc2c2ccc(-c3ccc4c(c3)c3ccccc3n4-c3nc(-c4ccccc4)nc(-c4ccccc4)n3)cc21 ; c1ccc(-n2c3ccccc3c3cc(-c4ccc5c(c4)c4ccccc4n5-c4nccc(-c5cccnc5)n4)ccc32)cc1]

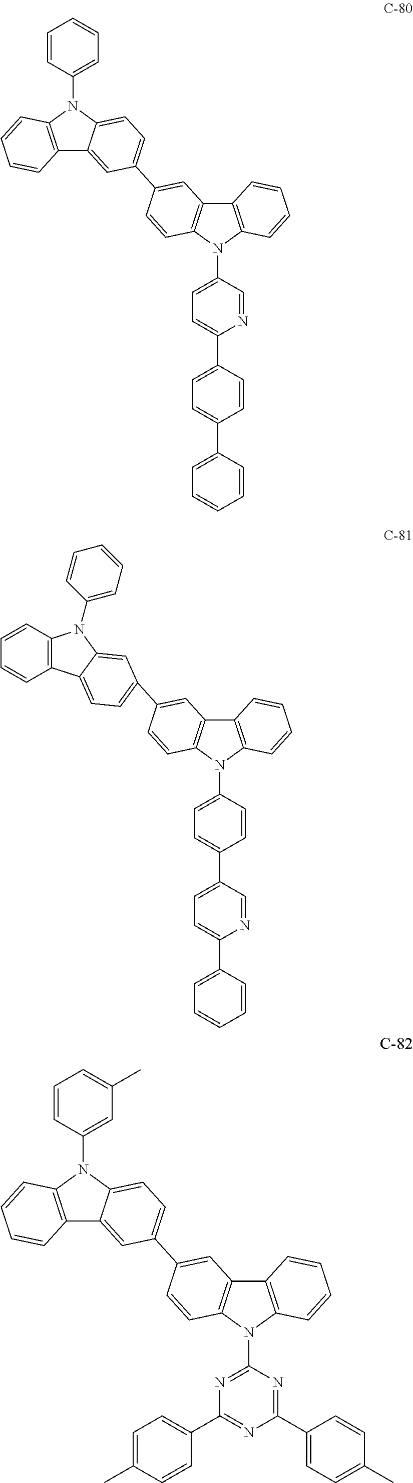 [SMILES: c1ccc(-c2ccc(-c3ccc(-n4c5ccccc5c5cc(-c6ccc7c(c6)c6ccccc6n7-c6ccccc6)ccc54)cn3)cc2)cc1 ; c1ccc(-c2ccc(-c3ccc(-n4c5ccccc5c5cc(-c6ccc7c8ccccc8n(-c8ccccc8)c7c6)ccc54)cc3)cn2)cc1 ; Cc1ccc(-c2nc(-c3ccc(C)cc3)nc(-n3c4ccccc4c4cc(-c5ccc6c(c5)c5ccccc5n6-c5cccc(C)c5)ccc43)n2)cc1]

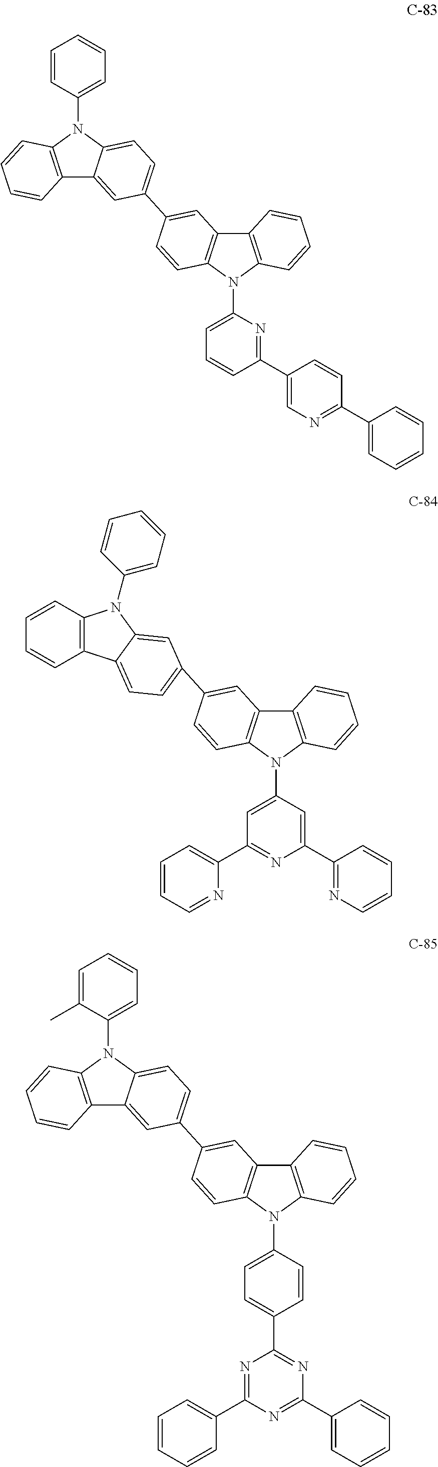 [SMILES: c1ccc(-c2ccc(-c3cccc(-n4c5ccccc5c5cc(-c6ccc7c(c6)c6ccccc6n7-c6ccccc6)ccc54)n3)cn2)cc1 ; c1ccc(-n2c3ccccc3c3ccc(-c4ccc5c(c4)c4ccccc4n5-c4cc(-c5ccccn5)nc(-c5ccccn5)c4)cc32)cc1 ; Cc1ccccc1-n1c2ccccc2c2cc(-c3ccc4c(c3)c3ccccc3n4-c3ccc(-c4nc(-c5ccccc5)nc(-c5ccccc5)n4)cc3)ccc21]

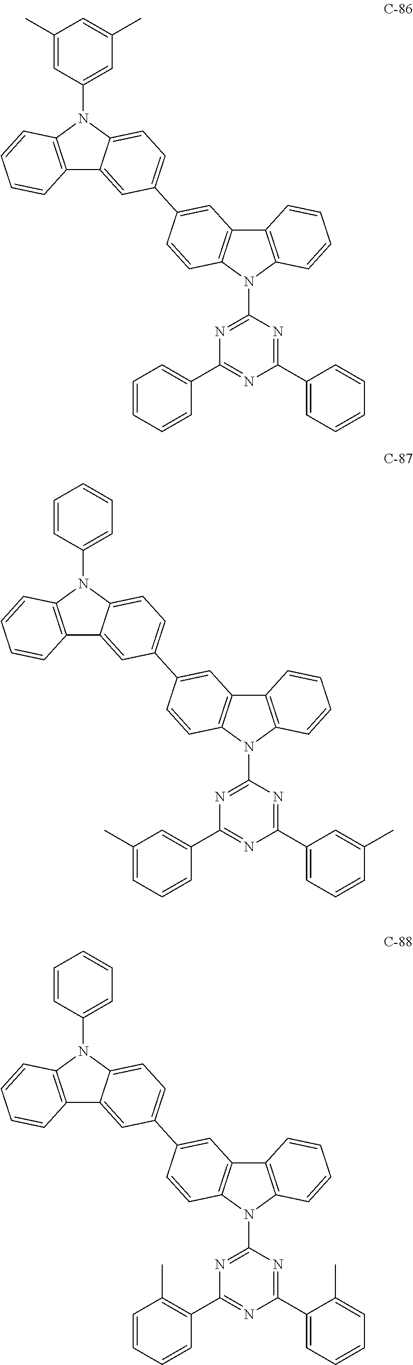 [SMILES: Cc1cc(C)cc(-n2c3ccccc3c3cc(-c4ccc5c(c4)c4ccccc4n5-c4nc(-c5ccccc5)nc(-c5ccccc5)n4)ccc32)c1 ; Cc1cccc(-c2nc(-c3cccc(C)c3)nc(-n3c4ccccc4c4cc(-c5ccc6c(c5)c5ccccc5n6-c5ccccc5)ccc43)n2)c1 ; Cc1ccccc1-c1nc(-c2ccccc2C)nc(-n2c3ccccc3c3cc(-c4ccc5c(c4)c4ccccc4n5-c4ccccc4)ccc32)n1]

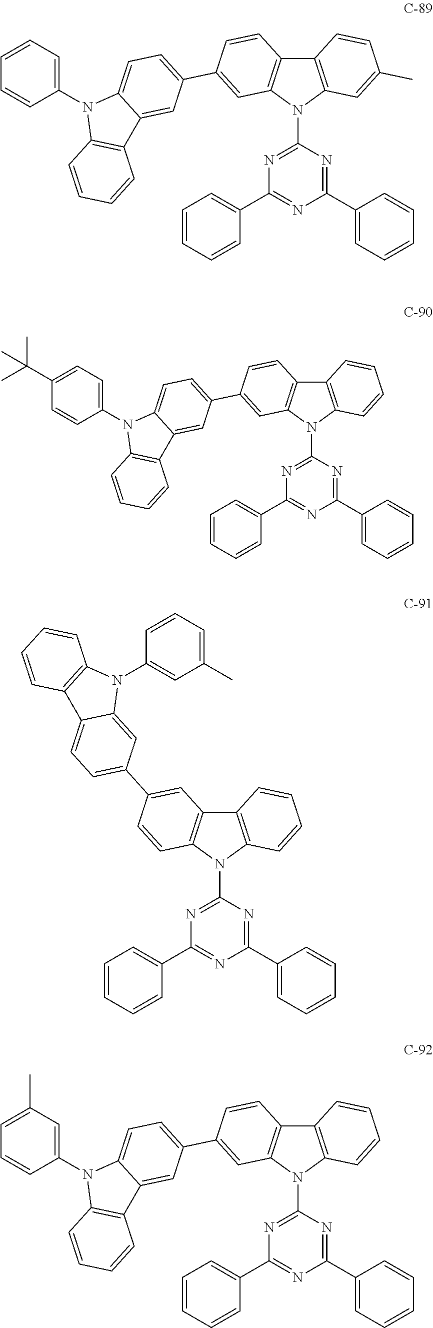 [SMILES: Cc1ccc2c3ccc(-c4ccc5c(c4)c4ccccc4n5-c4ccccc4)cc3n(-c3nc(-c4ccccc4)nc(-c4ccccc4)n3)c2c1 ; CC(C)(C)c1ccc(-n2c3ccccc3c3cc(-c4ccc5c6ccccc6n(-c6nc(-c7ccccc7)nc(-c7ccccc7)n6)c5c4)ccc32)cc1 ; Cc1cccc(-n2c3ccccc3c3ccc(-c4ccc5c(c4)c4ccccc4n5-c4nc(-c5ccccc5)nc(-c5ccccc5)n4)cc32)c1 ; Cc1cccc(-n2c3ccccc3c3cc(-c4ccc5c6ccccc6n(-c6nc(-c7ccccc7)nc(-c7ccccc7)n6)c5c4)ccc32)c1]

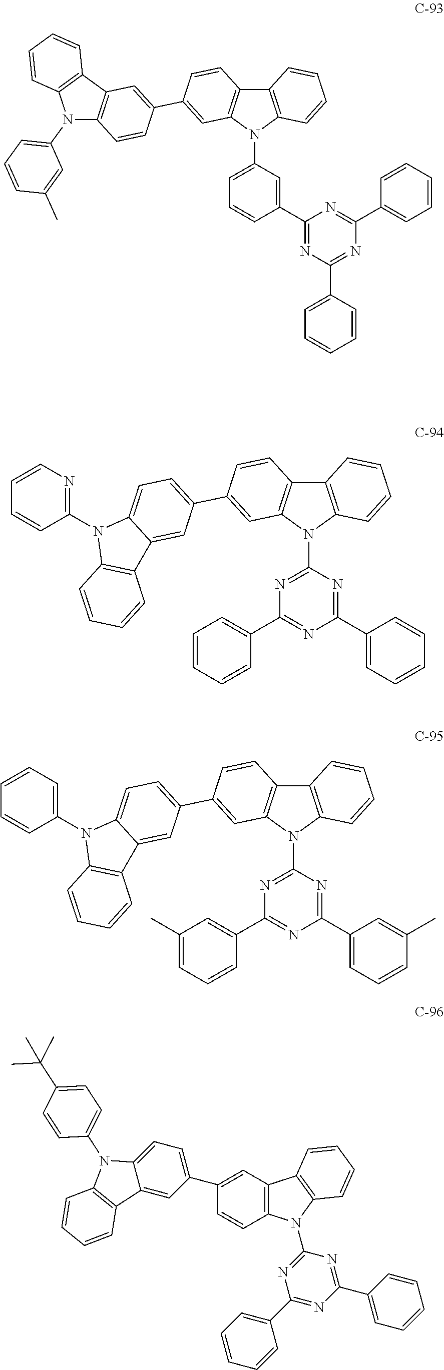

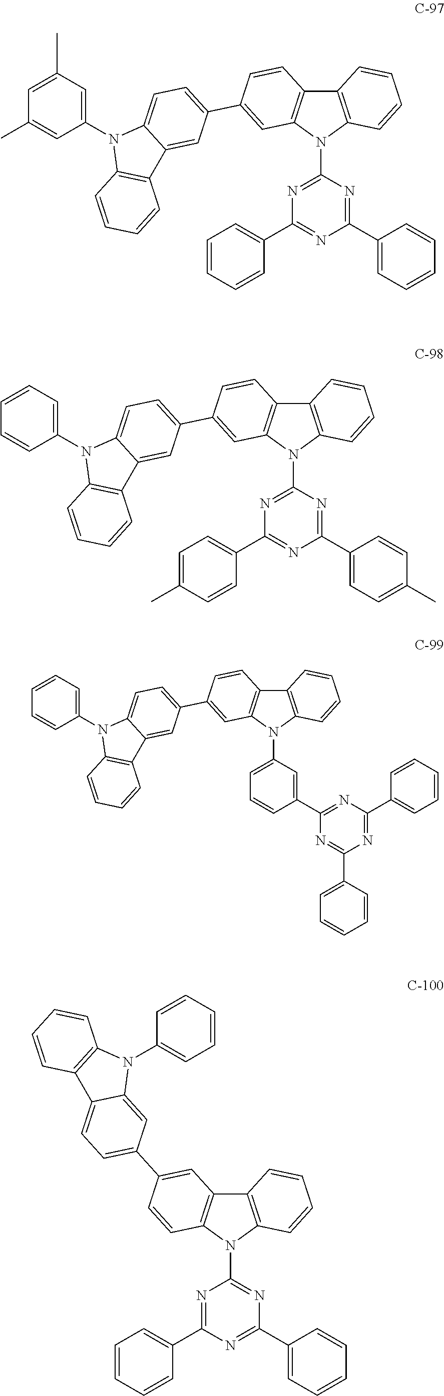 [SMILES: Cc1cc(C)cc(-n2c3ccccc3c3cc(-c4ccc5c6ccccc6n(-c6nc(-c7ccccc7)nc(-c7ccccc7)n6)c5c4)ccc32)c1 ; Cc1ccc(-c2nc(-c3ccc(C)cc3)nc(-n3c4ccccc4c4ccc(-c5ccc6c(c5)c5ccccc5n6-c5ccccc5)cc43)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-c2nc(-c3ccccc3)nc(-n3c4ccccc4c4cc(-c5ccc6c7ccccc7n(-c7ccccc7)c6c5)ccc43)n2)cc1]

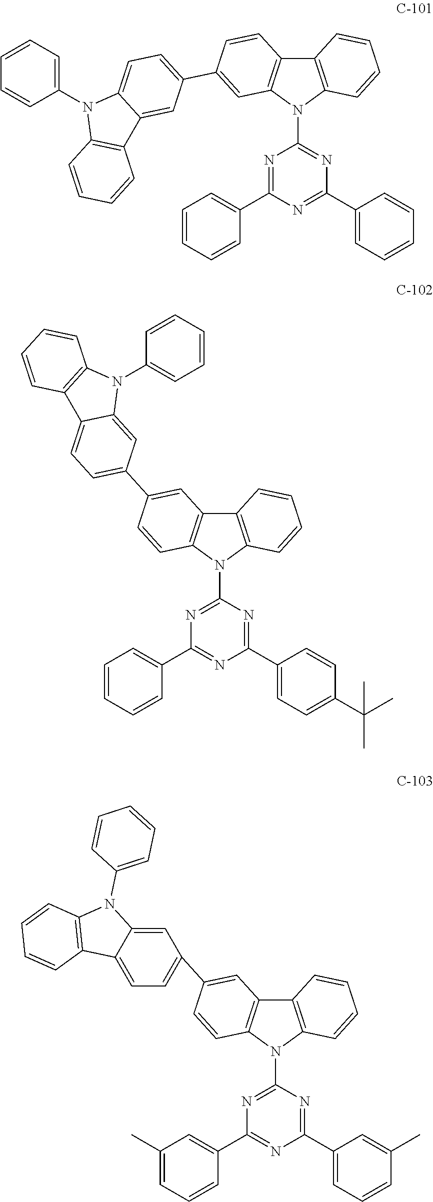 [SMILES: c1ccc(-c2nc(-c3ccccc3)nc(-n3c4ccccc4c4ccc(-c5ccc6c(c5)c5ccccc5n6-c5ccccc5)cc43)n2)cc1 ; CC(C)(C)c1ccc(-c2nc(-c3ccccc3)nc(-n3c4ccccc4c4cc(-c5ccc6c7ccccc7n(-c7ccccc7)c6c5)ccc43)n2)cc1 ; Cc1cccc(-c2nc(-c3cccc(C)c3)nc(-n3c4ccccc4c4cc(-c5ccc6c7ccccc7n(-c7ccccc7)c6c5)ccc43)n2)c1]

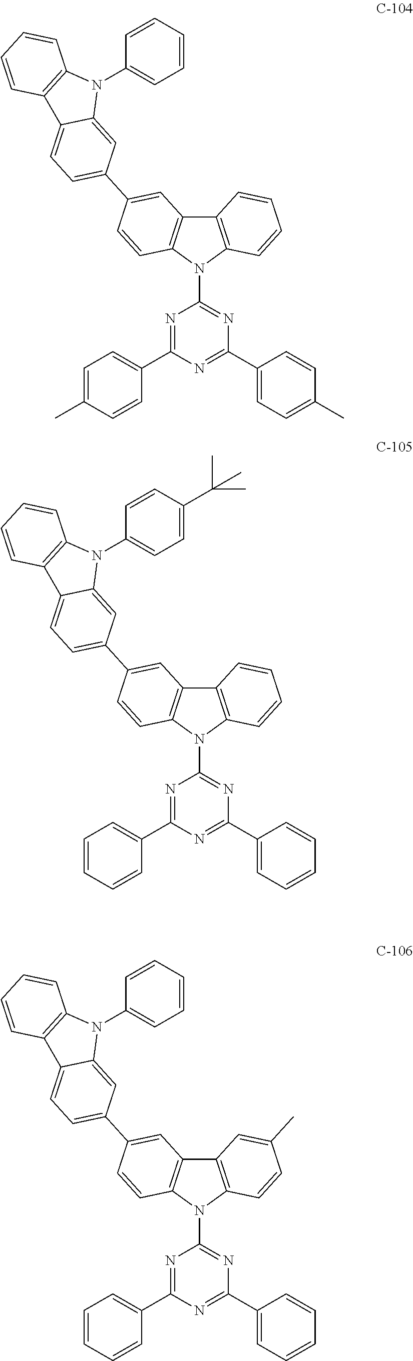 [SMILES: Cc1ccc(-c2nc(-c3ccc(C)cc3)nc(-n3c4ccccc4c4cc(-c5ccc6c7ccccc7n(-c7ccccc7)c6c5)ccc43)n2)cc1 ; CC(C)(C)c1ccc(-n2c3ccccc3c3ccc(-c4ccc5c(c4)c4ccccc4n5-c4nc(-c5ccccc5)nc(-c5ccccc5)n4)cc32)cc1 ; Cc1ccc2c(c1)c1cc(-c3ccc4c5ccccc5n(-c5ccccc5)c4c3)ccc1n2-c1nc(-c2ccccc2)nc(-c2ccccc2)n1]

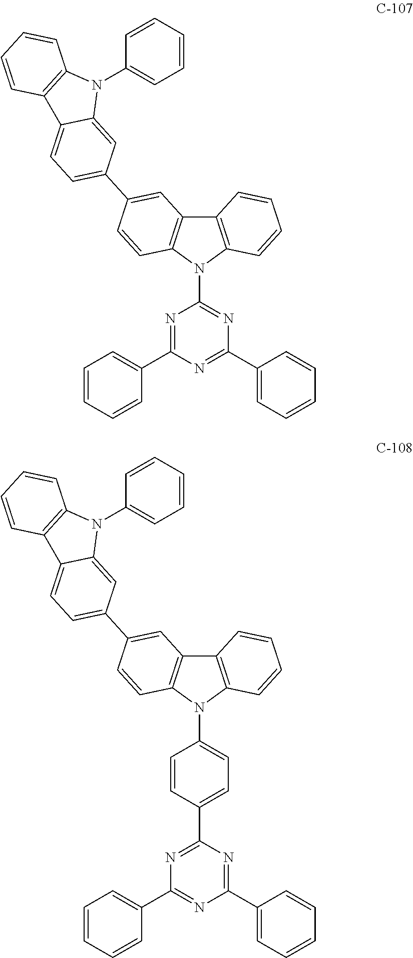 [SMILES: c1ccc(-c2nc(-c3ccccc3)nc(-n3c4ccccc4c4cc(-c5ccc6c7ccccc7n(-c7ccccc7)c6c5)ccc43)n2)cc1 ; c1ccc(-c2nc(-c3ccccc3)nc(-c3ccc(-n4c5ccccc5c5cc(-c6ccc7c8ccccc8n(-c8ccccc8)c7c6)ccc54)cc3)n2)cc1]

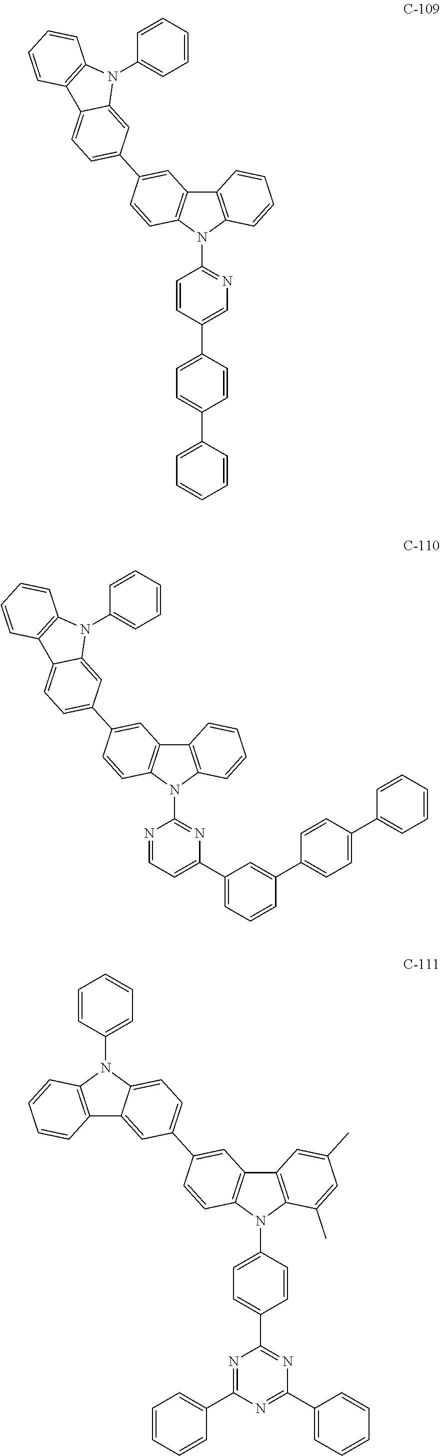 [SMILES: c1ccc(-c2ccc(-c3ccc(-n4c5ccccc5c5cc(-c6ccc7c8ccccc8n(-c8ccccc8)c7c6)ccc54)nc3)cc2)cc1 ; c1ccc(-c2ccc(-c3cccc(-c4ccnc(-n5c6ccccc6c6cc(-c7ccc8c9ccccc9n(-c9ccccc9)c8c7)ccc65)n4)c3)cc2)cc1 ; Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1]

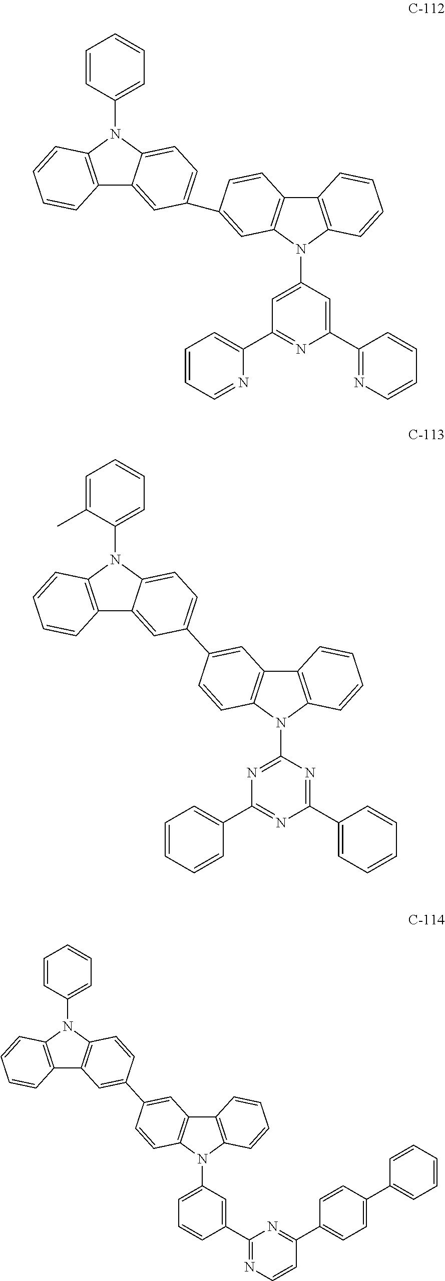 [SMILES: c1ccc(-n2c3ccccc3c3cc(-c4ccc5c6ccccc6n(-c6cc(-c7ccccn7)nc(-c7ccccn7)c6)c5c4)ccc32)cc1 ; Cc1ccccc1-n1c2ccccc2c2cc(-c3ccc4c(c3)c3ccccc3n4-c3nc(-c4ccccc4)nc(-c4ccccc4)n3)ccc21 ; c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1]

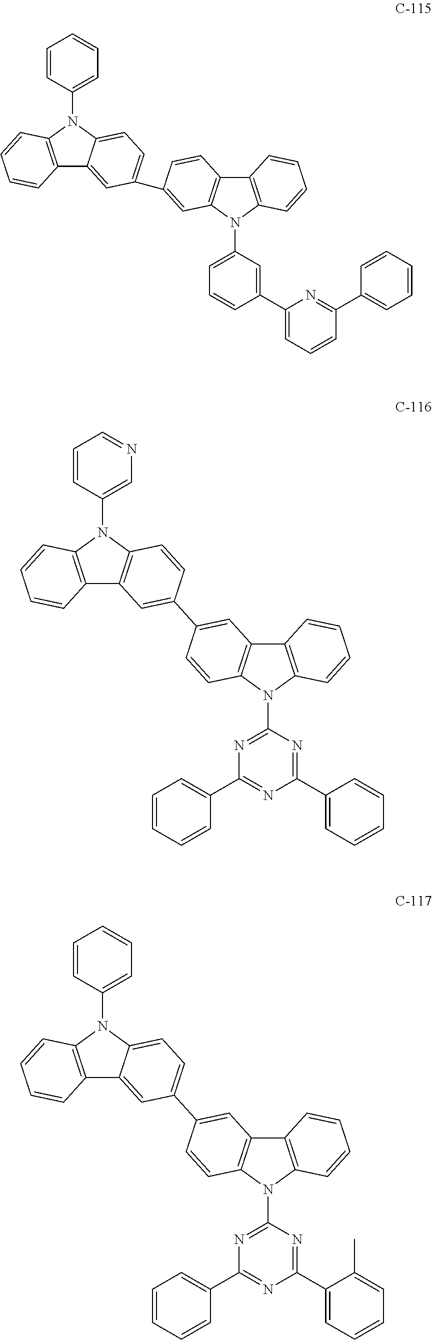 [SMILES: c1ccc(-c2cccc(-c3cccc(-n4c5ccccc5c5ccc(-c6ccc7c(c6)c6ccccc6n7-c6ccccc6)cc54)c3)n2)cc1 ; c1ccc(-c2nc(-c3ccccc3)nc(-n3c4ccccc4c4cc(-c5ccc6c(c5)c5ccccc5n6-c5cccnc5)ccc43)n2)cc1 ; Cc1ccccc1-c1nc(-c2ccccc2)nc(-n2c3ccccc3c3cc(-c4ccc5c(c4)c4ccccc4n5-c4ccccc4)ccc32)n1]

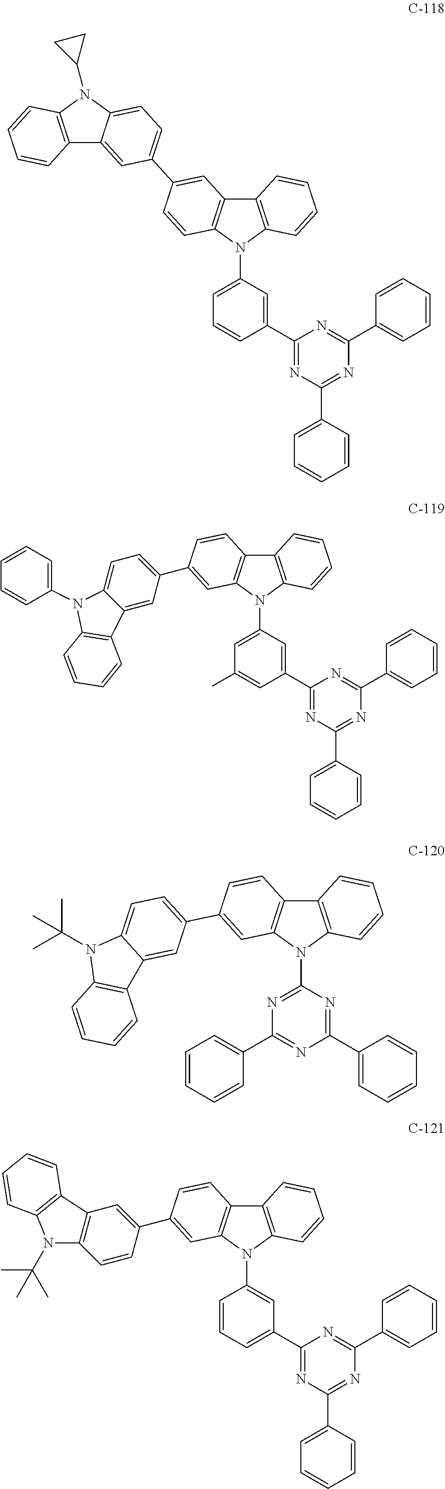 [SMILES: c1ccc(-c2nc(-c3ccccc3)nc(-c3cccc(-n4c5ccccc5c5cc(-c6ccc7c(c6)c6ccccc6n7C6CC6)ccc54)c3)n2)cc1 ; Cc1cc(-c2nc(-c3ccccc3)nc(-c3ccccc3)n2)cc(-n2c3ccccc3c3ccc(-c4ccc5c(c4)c4ccccc4n5-c4ccccc4)cc32)c1 ; CC(C)(C)n1c2ccccc2c2cc(-c3ccc4c5ccccc5n(-c5nc(-c6ccccc6)nc(-c6ccccc6)n5)c4c3)ccc21 ; CC(C)(C)n1c2ccccc2c2cc(-c3ccc4c5ccccc5n(-c5cccc(-c6nc(-c7ccccc7)nc(-c7ccccc7)n6)c5)c4c3)ccc21]

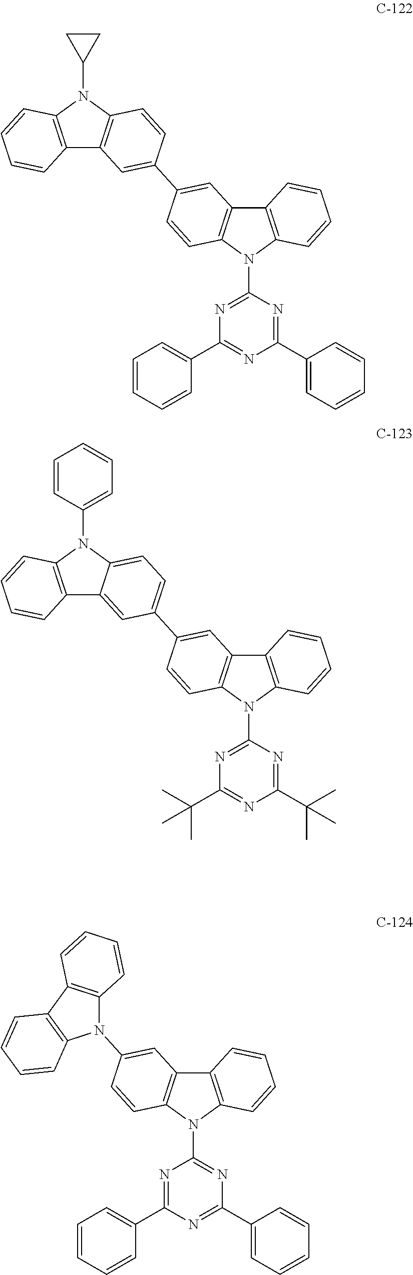 [SMILES: c1ccc(-c2nc(-c3ccccc3)nc(-n3c4ccccc4c4cc(-c5ccc6c(c5)c5ccccc5n6C5CC5)ccc43)n2)cc1 ; CC(C)(C)c1nc(-n2c3ccccc3c3cc(-c4ccc5c(c4)c4ccccc4n5-c4ccccc4)ccc32)nc(C(C)(C)C)n1 ; c1ccc(-c2nc(-c3ccccc3)nc(-n3c4ccccc4c4cc(-n5c6ccccc6c6ccccc65)ccc43)n2)cc1]

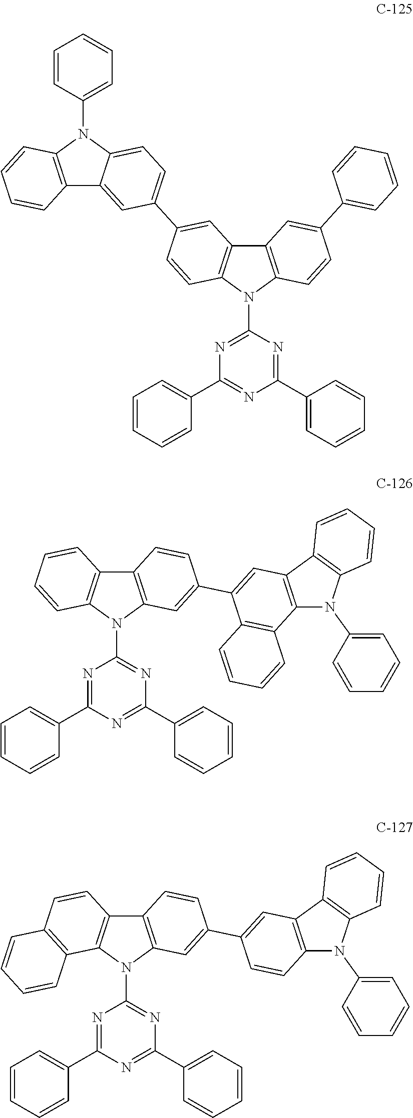 [SMILES: c1ccc(-c2ccc3c(c2)c2cc(-c4ccc5c(c4)c4ccccc4n5-c4ccccc4)ccc2n3-c2nc(-c3ccccc3)nc(-c3ccccc3)n2)cc1 ; c1ccc(-c2nc(-c3ccccc3)nc(-n3c4ccccc4c4ccc(-c5cc6c7ccccc7n(-c7ccccc7)c6c6ccccc56)cc43)n2)cc1 ; c1ccc(-c2nc(-c3ccccc3)nc(-n3c4cc(-c5ccc6c(c5)c5ccccc5n6-c5ccccc5)ccc4c4ccc5ccccc5c43)n2)cc1]

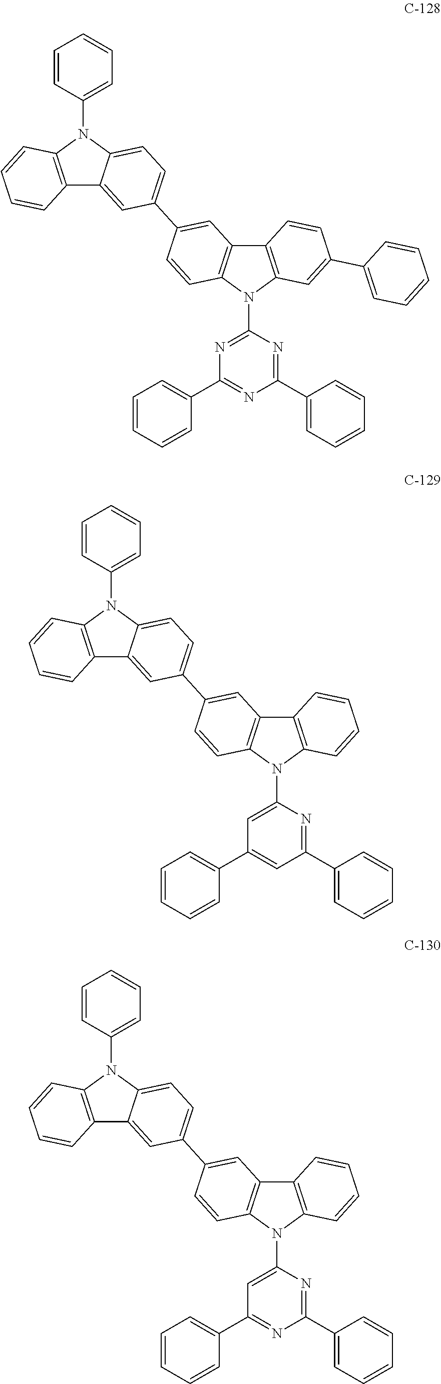 [SMILES: c1ccc(-c2ccc3c4cc(-c5ccc6c(c5)c5ccccc5n6-c5ccccc5)ccc4n(-c4nc(-c5ccccc5)nc(-c5ccccc5)n4)c3c2)cc1 ; c1ccc(-c2cc(-c3ccccc3)nc(-n3c4ccccc4c4cc(-c5ccc6c(c5)c5ccccc5n6-c5ccccc5)ccc43)c2)cc1 ; c1ccc(-c2cc(-n3c4ccccc4c4cc(-c5ccc6c(c5)c5ccccc5n6-c5ccccc5)ccc43)nc(-c3ccccc3)n2)cc1]

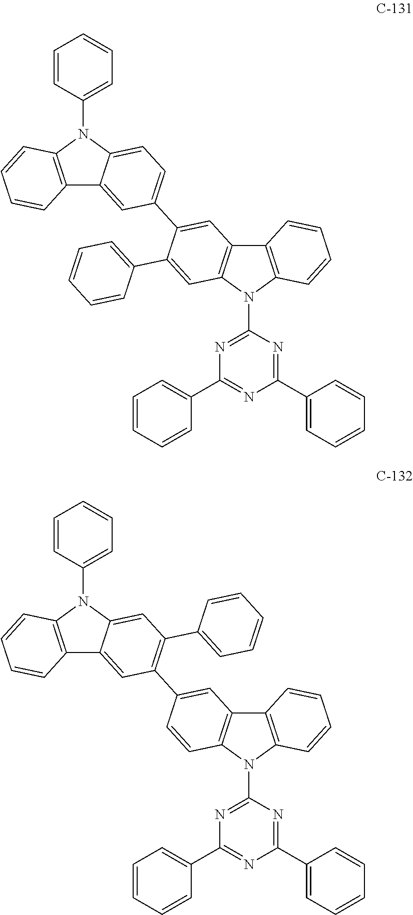 [SMILES: c1ccc(-c2nc(-c3ccccc3)nc(-n3c4ccccc4c4cc(-c5ccc6c(c5)c5ccccc5n6-c5ccccc5)c(-c5ccccc5)cc43)n2)cc1 ; c1ccc(-c2nc(-c3ccccc3)nc(-n3c4ccccc4c4cc(-c5cc6c7ccccc7n(-c7ccccc7)c6cc5-c5ccccc5)ccc43)n2)cc1]

The compounds represented by formula 1 can be prepared according to the following reaction scheme 1, but not limited thereto. In addition, modifying the synthetic method is obvious to a person skilled in the art.

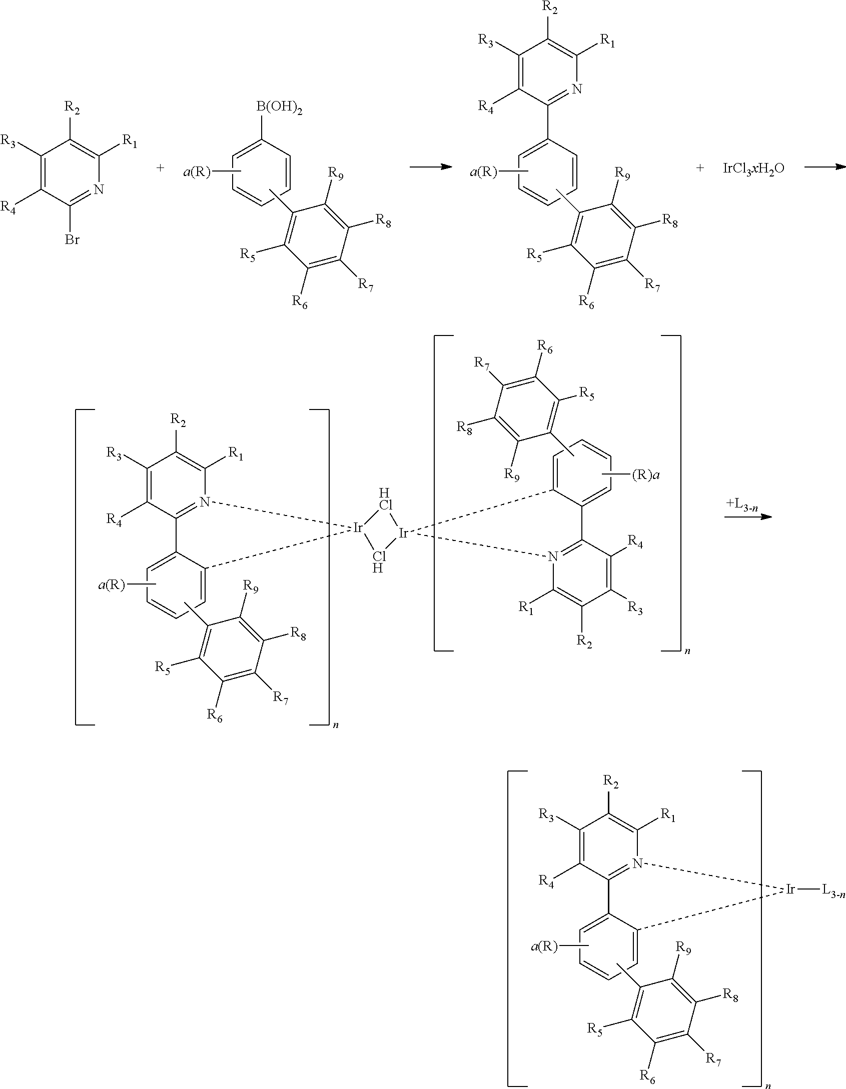

wherein L, R, R₁ to R₉, n, and a are as defined in formula 1 above.

Specifically, said organic electroluminescent device comprises a first electrode; a second electrode; and at least one organic layer between said first and second electrodes. Said organic layer comprises a light-emitting layer, and said light-emitting layer comprises a combination of one or more dopant compounds represented by formula 1, and one or more host compounds represented by formula 2.

Said light-emitting layer is a layer which emits light, and it may be a single layer, or it may be a multi layer of which two or more layers are laminated. The light-emitting layer can also inject/transfer electrons/holes, besides emitting light.

The doping concentration, the proportion of the dopant compound to the host compound may be preferably less than 20 wt %.

Another embodiment of the present invention provides a host/dopant combination of a dopant compound represented by formula 1, and one or more host compounds represented by formula 2, and an organic EL device comprising the host/dopant combination.

In the organic electroluminescent device according to the present invention, a mixed region of an electron transport compound and an reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge generating layer to prepare an electroluminescent device having two or more electroluminescent layers and emitting white light.

In order to form each layer of the organic electroluminescent device according to the present invention, dry film-forming methods such as vacuum evaporation, sputtering, plasma and ion plating methods, or wet film-forming methods such as spin coating, dip coating, flow coating methods can be used.

When using a wet film-forming method, a thin film can be formed by dissolving or diffusing materials forming each layer into any suitable solvent such as ethanol, chloroform, tetrahydrofuran, dioxane, etc. The solvent can be any solvent where the materials forming each layer can be dissolved or diffused, and where there are no problems in film-formation capability.

Hereinafter, the compound, the preparation method of the compound, and the luminescent properties of the device will be explained in detail with reference to the following examples. However, these are just for exemplifying the embodiment of the present invention, so the scope of the present invention cannot be limited thereto.

### EXAMPLE 1

### Preparation of Compound D-5

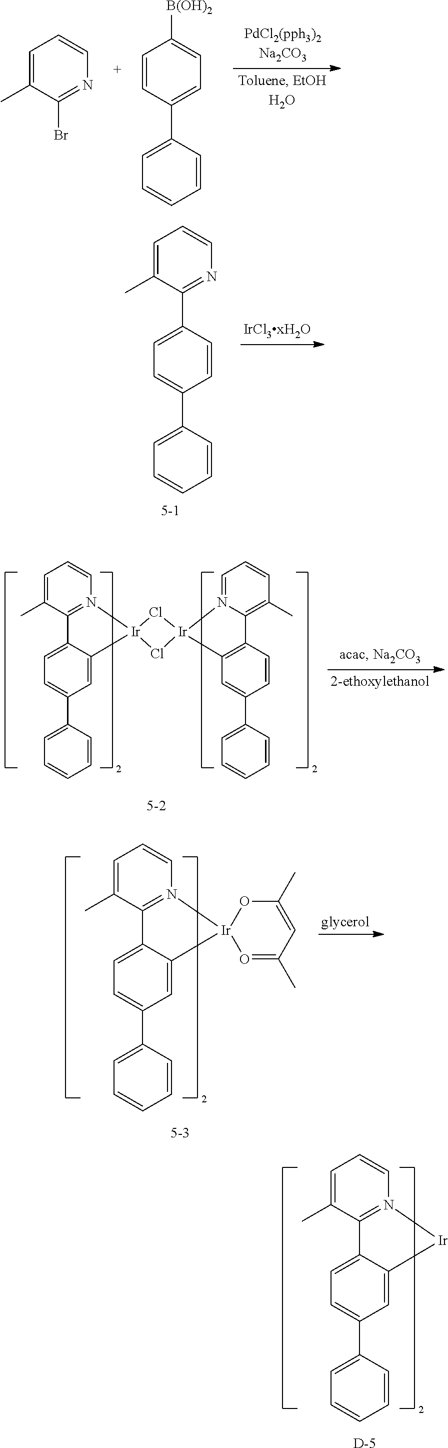

Preparation of Compound 5-1

After adding 4-biphenyl boronic acid 12 g (64 mmol), 2-bromo-3-methylpyridine 10 g (58 mmol), PdCl₂(PPh₃)₂ 1.2 g (1.7 mmol), and Na₂CO₃ 10 g (94 mmol) to a mixture solvent of toluene 100 mL, ethanol 50 mL, and H₂O 50 mL, the mixture was stirred at 120° C. for 4 hours. The reaction mixture was worked up with ethyl acetate (EA)/H₂O, the moisture was removed with MgSO₄, and the remaining product was distilled under reduced pressure. Then, the product was purified by column chromatography with methylene chloride (MC):hexane (Hex) to obtain 14 g (70%) of white solid compound 5-1.

Preparation of Compound 5-2

After adding compound 5-1 10 g (41 mmol), and IrCl₃.xH₂O 5 g (17 mmol) to a mixture solvent of 2-ethoxyethanol 120 mL, and H₂O 40 mL, the mixture was stirred at 120° C. for 24 hours under reflux. After completing the reaction, the mixture was washed using H₂O/MeOH/Hex, and dried to obtain compound 5-2 10 g (75%).

Preparation of Compound 5-3

After adding compound 5-2 10 g (7.0 mmol), 2,4-pentanedion 14 g (14 mmol), and Na₂CO₃ 3.7 g (34.7 mmol) to 2-ethoxyethanol 120 mL, the mixture was stirred at 110° C. for 12 hours. After completing the reaction, the produced solid was washed using H₂O/MeOH/Hex. After drying sufficiently, the product was dissolved with CHCl₃, and purified by column chromatography with MC/Hex to obtain compound 5-3 7.5 g (68%).

Preparation of Compound D-5

After adding glycerol to a mixture of compound 5-3 5 g (6.25 mmol), and compound 5-1 3.1 g (12.4 mmol), the mixture was stirred for 16 hours under reflux. After the reaction, the produced solid was filtered, washed with H₂O/MeOH/Hex, and dried. After drying sufficiently, the product was dissolved with CHCl₃, and purified by column chromatography with MC:Hex to obtain compound D-5 3.8 g (64%).

### EXAMPLE 2

### Preparation of Compound D-9

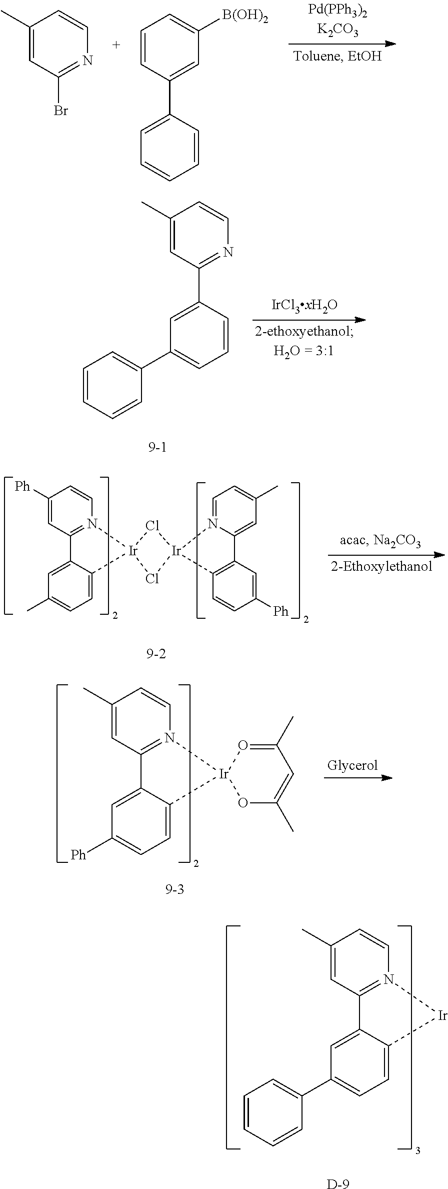

Preparation of Compound 9-1

After adding 3-biphenyl boronic acid 35 g (174 mmol), 2-bromo-4-methylpyridine 20 g (116 mmol), Pd(PPh₃)₄ 4 g (3.5 mmol), and 2 M K₂CO₃ 200 mL (400 mmol) to a mixture solvent of toluene 400 mL, and ethanol 400 mL, the mixture was stirred at 100° C. for 3 hours. The reaction mixture was worked up with EA/H₂O, the moisture was removed with MgSO₄, and the remaining product was distilled under reduced pressure. Then, the product was purified by column chromatography with MC:Hex to obtain a white solid compound 9-1 18 g (63%).

Preparation of Compound 9-2

After adding compound 9-1 7.6 g (31 mmol), and IrCl₃.xH₂O 4.2 g (14 mmol) to a mixture solvent of 2-ethoxyethanol 110 mL, and H₂O 37 mL, the mixture was stirred at 130° C. for 24 hours. After the reaction, the mixture was cooled to room temperature, washed with water and MeOH, and dried to obtain compound 9-2 8 g (80%).

Preparation of Compound 9-3

After adding compound 9-2 7 g (5 mmol), 2,4-pentanedion 1.5 g (15 mmol), and Na₂CO₃ 1.6 g (15 mmol) to 2-ethoxyethanol 80 mL, the reaction was held at 110° C. for 3 hours. After completing the reaction, the produced solid was purified by column chromatography to obtain compound 9-3 5 g (70%).

Preparation of Compound D-9

After adding glycerol to a mixture of compound 9-3 4 g (5 mmol), and compound 9-1 2.5 g (10 mmol), the mixture was stirred at 220° C. for 24 hours under reflux. After completing the reaction, the produced solid was purified by column chromatography to obtain compound D-9 4 g (80%).

### EXAMPLE 3

### Preparation of Compound D-28

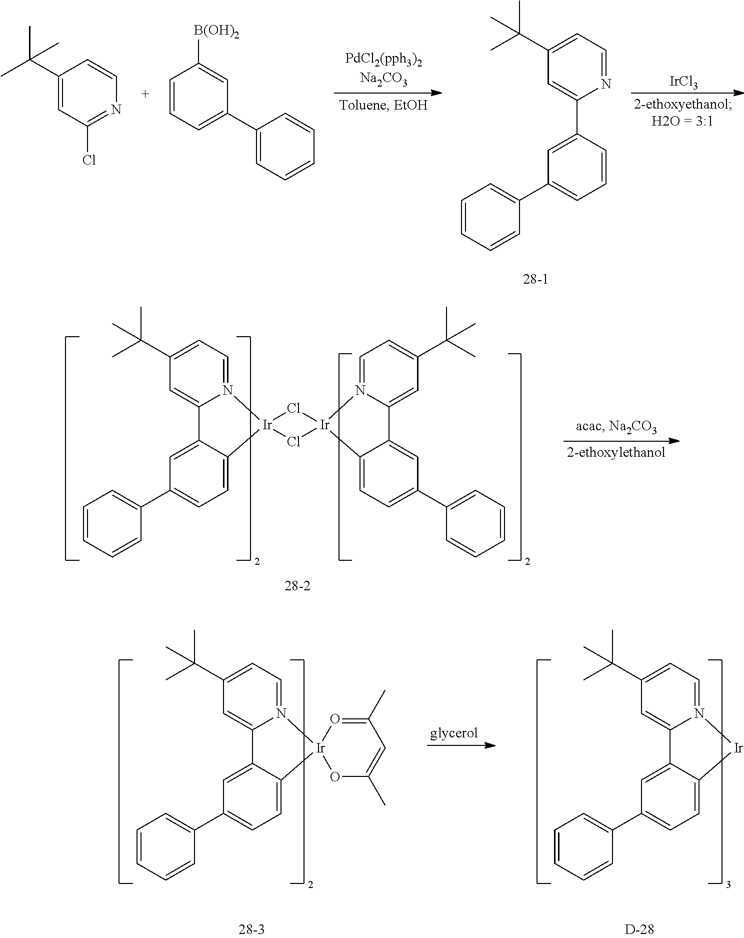

Compounds 28-1 to 28-3 were prepared using the same synthetic methods of compounds 9-1 to 9-3 for preparing compound D-9.

Preparation of Compound D-28

After adding glycerol to a mixture of compound 28-3 4.5 g (5.2 mmol), and compound 28-1 3.0 g (10.4 mmol), the mixture was stirred for 16 hours under reflux. After the reaction, the produced solid was filtered, washed with H₂O/MeOH/Hex, and dried. After drying sufficiently, the product was dissolved with CHCl₃, and purified by column chromatography with MC:Hex to obtain compound D-28 1.8 g (33%).

The detailed data of the compounds prepared in Example 1 to 3 (compounds D-5, D-9, and D-28), and the compounds that can be prepared using similar methods as in the above Examples (compounds D-2, D-10, D-14, and D-18) are shown in table 1 below.

TABLE 1

| | Yield | UV | | |
|---|---|---|---|---|
| Compound | (%) | Spectrum (nm) | PL spectrum (nm) | MP (° C.) |
| D-2 | 63 | 322 | 540 | 310 |
| D-5 | 64 | 326 | 534 | 400 or higher |
| D-9 | 80 | 286 | 513 | 400 or higher |
| D-10 | 56 | 269 | 517 | 389 |
| D-14 | 23 | 324 | 510 | 335 |
| D-18 | 68 | 294 | 515 | 350 |
| D-28 | 27 | 296 | 511.94 | 400 or higher |

### EXAMPLE 4

### Preparation of Compound C-3

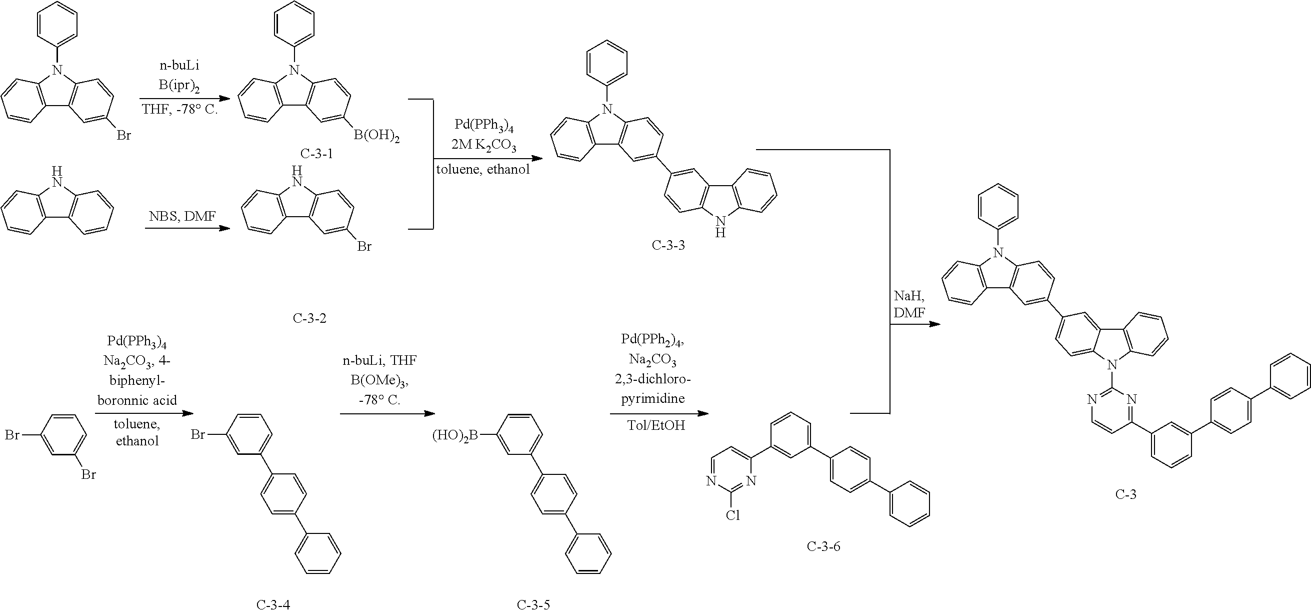

Preparation of Compound C-3-1

After dissolving 3-bromo-N-phenylcarbazole 20 g (62.07 mmol) in tetrahydrofuran (THF) 200 mL, n-buLi 29 mL (74.48 mmol, 2.5 M in hexane) was slowly added to the mixture at −78° C. After an hour, triisopropyl borate 19.9 mL (86.90 mmol) was added to the mixture. After stirring the mixture for 12 hours at room temperature, distilled water was added to the mixture. Then, the mixture was extracted with EA, dried with magnesium sulfate, and distilled under reduced pressure. Then, the remaining product was recrystallized with EA and hexane to obtain compound C-3-1 12 g (67.33° A)).

Preparation of Compound C-3-2

After dissolving carbazole 20 g (119.6 mmol) in dimethylformamide (DMF) 200 mL, N-bromosuccineimide (NBS) 21.2 g (119.6 mmol) was added to the mixture at 0° C. After stirring the mixture for 12 hours, distilled water was added to the mixture, and the produced solid was filtered under reduced pressure. The obtained solid was added to methanol, and the mixture was stirred, and filtered under reduced pressure. Then, the obtained solid was added to a mixture of EA, and methanol, the mixture was stirred, and filtered under reduced pressure to obtain compound C-3-2 17 g (58.04° A)).

Preparation of Compound C-3-3

After adding compound C-3-1 12 g (41.79 mmol), compound C-3-2 11.3 g (45.97 mmol), Pd(PPh₃)₄ 1.4 g (1.25 mmol), and 2 M K₂CO₃ 52 mL to a mixture solvent of toluene 150 mL, and ethanol 30 mL, the mixture was stirred under reflux. After 5 hours, the mixture was cooled to room temperature, and distilled water was added to the mixture. Then, the mixture was extracted with EA, dried with magnesium sulfate, distilled under reduced pressure, and recrystallized with EA and methanol to obtain compound C-3-3 10 g (58.57%).

Preparation of Compound C-3-4

After adding 1,3-dibromobenzene 36.5 mL (302.98 mmol), 4-biphenyl boronic acid 40 g (201.98 mmol), Pd(PPh₃)₄ 4.25 g (6.05 mmol), and 2 M Na₂CO₃ 250 mL to a mixture solvent of toluene 400 mL, and ethanol 100 mL, the mixture was stirred under reflux. After 12 hours, the mixture was cooled to room temperature, and distilled water was added to the mixture. Then, the mixture was extracted with EA, dried with magnesium sulfate, distilled under reduced pressure, and separated with a column to obtain compound C-3-4 25 g (40.12%).

Preparation of Compound C-3-5

After dissolving compound C-3-4 25 g (80.85 mmol) in THF, n-buLi 42 mL (105.10 mmol, 2.5 M in hexane) was slowly added to the mixture at −78° C. After an hour, trimethyl borate 14.42 mL (129.3 mmol) was added to the mixture. After stirring the mixture for 12 hours at room temperature, distilled water was added to the mixture. Then, the mixture was extracted with EA, dried with magnesium sulfate, and distilled under reduced pressure. Then, the remaining product was recrystallized with MC and hexane to obtain compound C-3-5 20 g (90.24° A)).

Preparation of Compound C-3-6

After adding compound C-3-5 20 g (72.96 mmol), 2,3-dichloropyrimidine 9.8 g (80.25 mmol), Pd(PPh₃)₄ 2.28 g (2.18 mmol), and 2 M Na₂CO₃ 80 mL to a mixture solvent of toluene 150 mL, and ethanol 50 mL, the mixture was stirred under reflux for 5 hours. Then, the mixture was cooled to room temperature, and distilled water was added to the mixture. Then, the mixture was extracted with EA, dried with magnesium sulfate, distilled under reduced pressure, and recrystallized with EA and methanol to obtain compound C-3-6 11 g (43.97%).

Preparation of Compound C-3

After dissolving compound C-3-3 5.2 g (12.83 mmol), and compound C-3-6 4 g (11.66 mmol) in DMF 150 mL, NaH 0.7 g (17.50 mmol, 60% in mineral oil) was added to the mixture. After stirring the mixture for 12 hours at room temperature, methanol and distilled water was added to the mixture. Then, the produced solid was filtered under reduced pressure, and separated with a column to obtain compound C-3 15 g (59.98%).

### EXAMPLE 5

### Preparation of Compound C-13

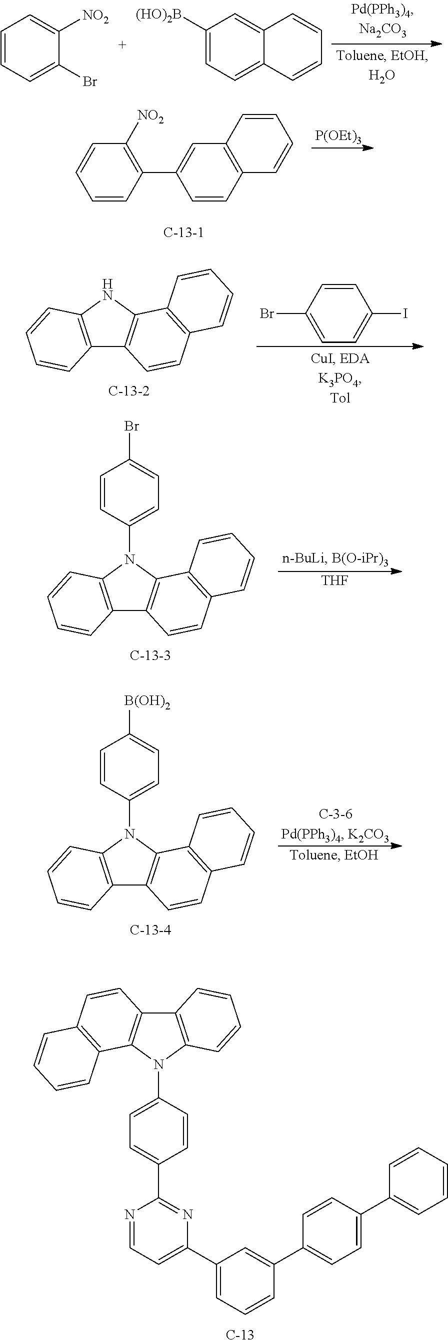

Compounds C-13-1 to C-13-4 were prepared using the same synthetic methods of compounds C-62-1 to C-62-4 of Example 8, and the preparation method of C-3-6 is shown in Example 4.

Preparation of Compound C-13

After mixing compound C-3-6 9.8 g (28 mmol), compound C-13-4 8 g (24 mmol), Pd(PPh₃)₄ 1.37 g (1 mmol), K₂CO₃ 9.83 g (70 mmol), toluene 120 mL, EtOH 30 mL, and H₂O 36 mL in a 500 mL round bottom flask, the mixture was stirred at 120° C. for 12 hours. After completing the reaction, the mixture was recrystallized with DMF to obtain compound C-13 4.5 g (26%).

### EXAMPLE 6

### Preparation of Compound C-32

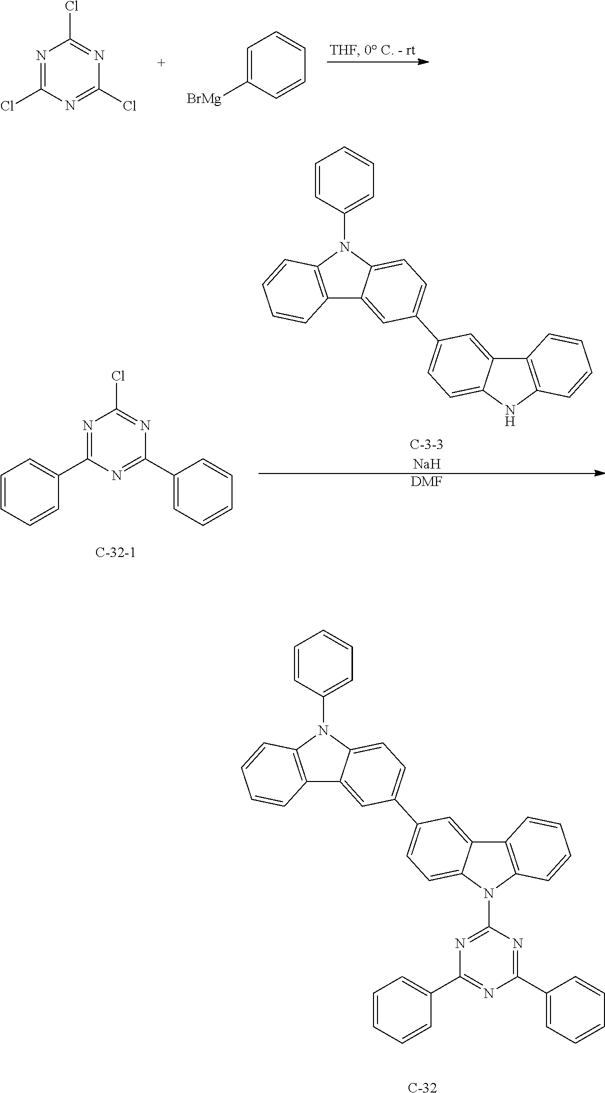

Preparation of Compound C-32-1

After dissolving cyanuric chloride 53 g (287 mmol) in THF 530 mL, and cooling the mixture to 0° C., phenylmagnesium bromide (3.0 M) 240 mL was slowly added to the mixture, and the mixture was stirred for 3 hours. Then, the mixture was slowly heated to room temperature, and stirred for 9 hours. After completing the stirring, an aqueous solution of ammonium chloride was added to the mixture, and quenched, then extracted with distilled water and EA, and the organic layer was concentrated. After completing the concentration, the obtained product was separated with a column (CHCl₃/Hex) to obtain compound C-32-1 62 g (80%).

Preparation of Compound C-32

After adding compound C-3-3 10 g (22.4 mmol), and NaH (60% dispersed in mineral oil) 1.3 g (33.6 mmol) to DMF 350 mL, the mixture was stirred for 1 hour under nitrogen atmosphere. Then, a mixture of compound C-32-1 5 g (18.6 mmol), and DMF 80 mL was added to the mixture, and was stirred at 90° C. for 9 hours. After completing the stirring, purified water was slowly added to the mixture to complete the reaction. Then, the mixture was cooled to room temperature, and filtered to obtain a solid product. The obtained mixture was separated with a column (MC/Hex) to obtain compound C-32 6.5 g (54%).

### EXAMPLE 7

### Preparation of Compound C-35

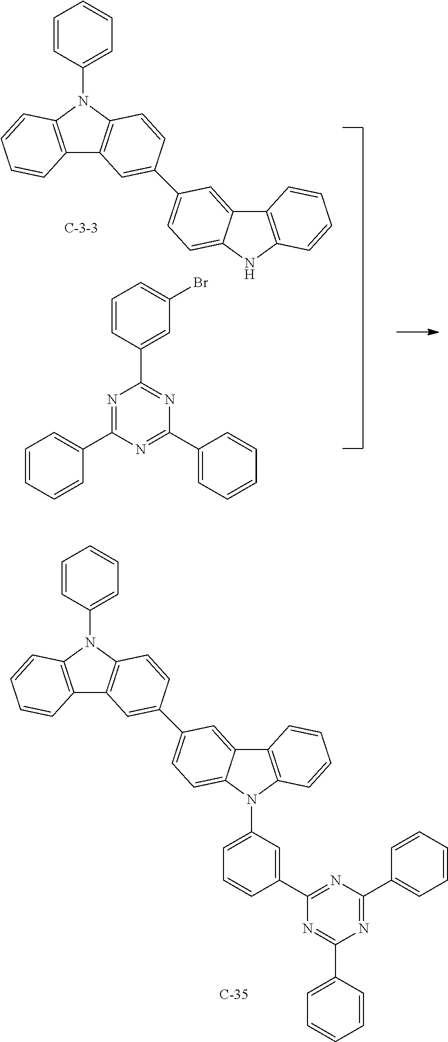

The preparation method of C-3-3 is shown in Example 4.

Preparation of Compound C-35

After mixing compound C-3-3 36.2 g (93.2 mmol), 2-(3-bromophenyl)-4,6-diphenyl-1,3,5-triazine 40 g (97.9 mmol), Pd(OAc)₂ 1.25 g (5.59 mmol), S-phos 4.6 g (11.18 mmol), NaOt-bu 26.8 g (279.7 mmol), and o-xylene 450 mL, the mixture was stirred under reflux. After 6 hours, the mixture cooled to room temperature, the produced solid was filtered under reduced pressure, and separated with a column to obtain compound C-35 34.8 g (52.1%).

### EXAMPLE 8

### Preparation of Compound C-62

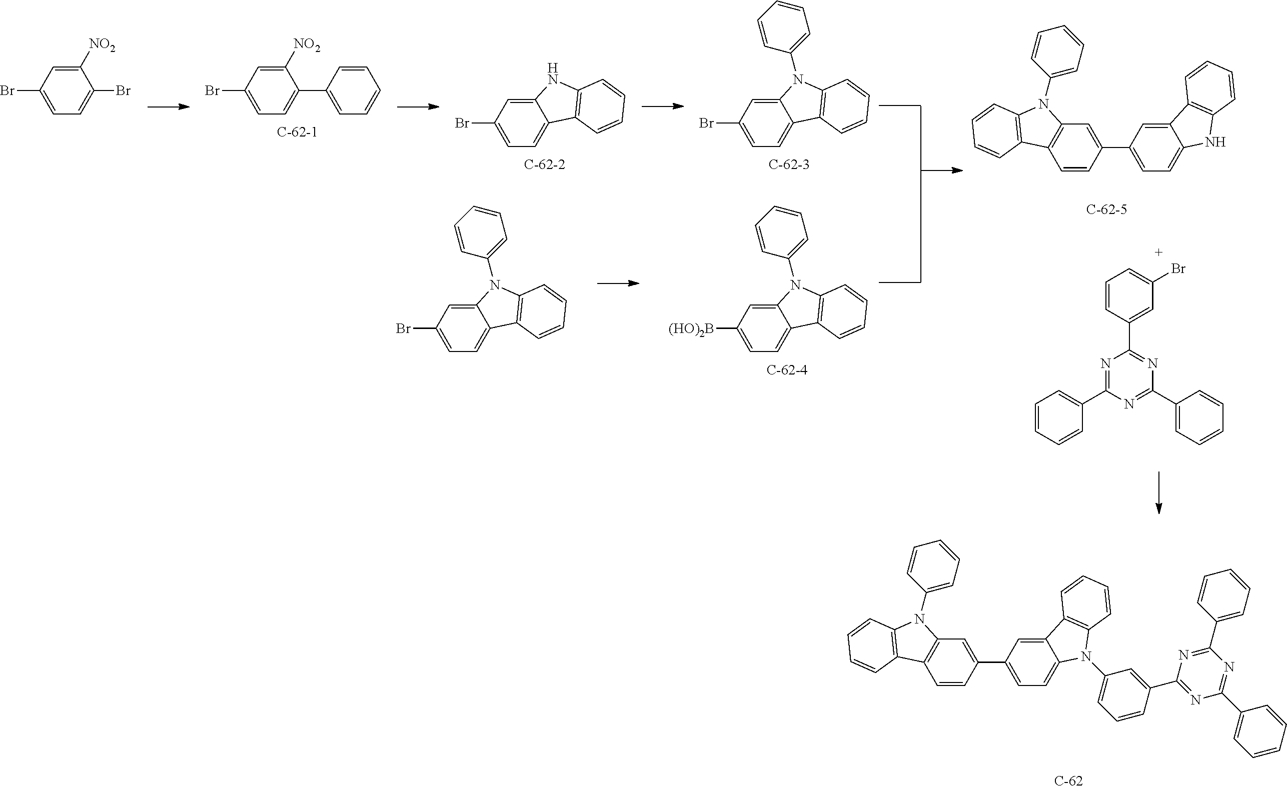

Preparation of Compound C-62-1

After adding 1,4-dibromo-2-nitrobenzene 50 g (177.99 mmol), phenyl boronic acid 19.7 g (161.81 mmol), Na₂CO₃ 51 g (485.43 mmol), and Pd(PPh₃)₄ 9.4 g (8.1 mmol) to a mixture solvent of toluene 900 mL, EtOH 240 mL, and purified water 240 mL, the mixture was stirred under reflux for one day. After completing the reaction, the mixture was cooled to room temperature, and extracted with distilled water, and EA. Then, the organic layer was distilled under reduced pressure, and separated with a column using MC/Hex to obtain compound C-62-1 42 g (92%).

Preparation of Compound C-62-2

After dissolving compound C-62-1 42 g (150 mmol) in a mixture solvent of P(OEt)₃ 450 mL, and 1,2-dichlorobenzene 300 mL, the mixture was stirred at 150° C. for one day. After completing the reaction, the mixture was concentrated under reduced pressure, extracted with EA, and the organic layer was concentrated. Then, the obtained product was separated with a column using MC/Hex to obtain compound C-62-2 18 g (48%).

Preparation of Compound C-62-3

After mixing compound C-62-2 17 g (69.07 mmol), iodobenzene 15.4 mL (138.15 mmol), CuI 10.5 g (55.26 mmol), ethylenediamine (EDA) 6.9 mL (103.6 mmol), Cs₂CO₃ 56.26 g (172.6 mmol), and toluene 350 mL, the mixture was stirred under reflux. After 4 hours, the mixture was cooled to room temperature, and filtered under reduced pressure. The remaining solution was filtered under reduced pressure, and separated with a column to obtain compound C-62-3 20 g (89%).

Preparation of Compound C-62-4

After dissolving compound C-62-3 25 g (77.59 mmol) in THF 400 mL, n-buLi 37.2 mL (93.10 mmol) was slowly added to the mixture at −78° C. After 40 minutes, triisopropyl borate 26.8 g (116.3 mmol) was added to the mixture. After heating the mixture slowly to room temperature, the mixture was stirred for 12 hours. Then, distilled water was added to the mixture, and the mixture was extracted with EA, dried with magnesium sulfate, and distilled under reduced pressure. Then, EA/Hex was added to the mixture, and the mixture was filtered under reduced pressure to obtain compound C-62-4 14 g (62.8%).

Preparation of Compound C-62-5

The same synthetic method of C-3-3 was used to obtain compound C-62-5 4 g (34%).

Preparation of Compound C-62

The same synthetic method of C-35 was used to obtain compound C-62 4 g (28.5%).

### EXAMPLE 9

### Preparation of Compound C-101

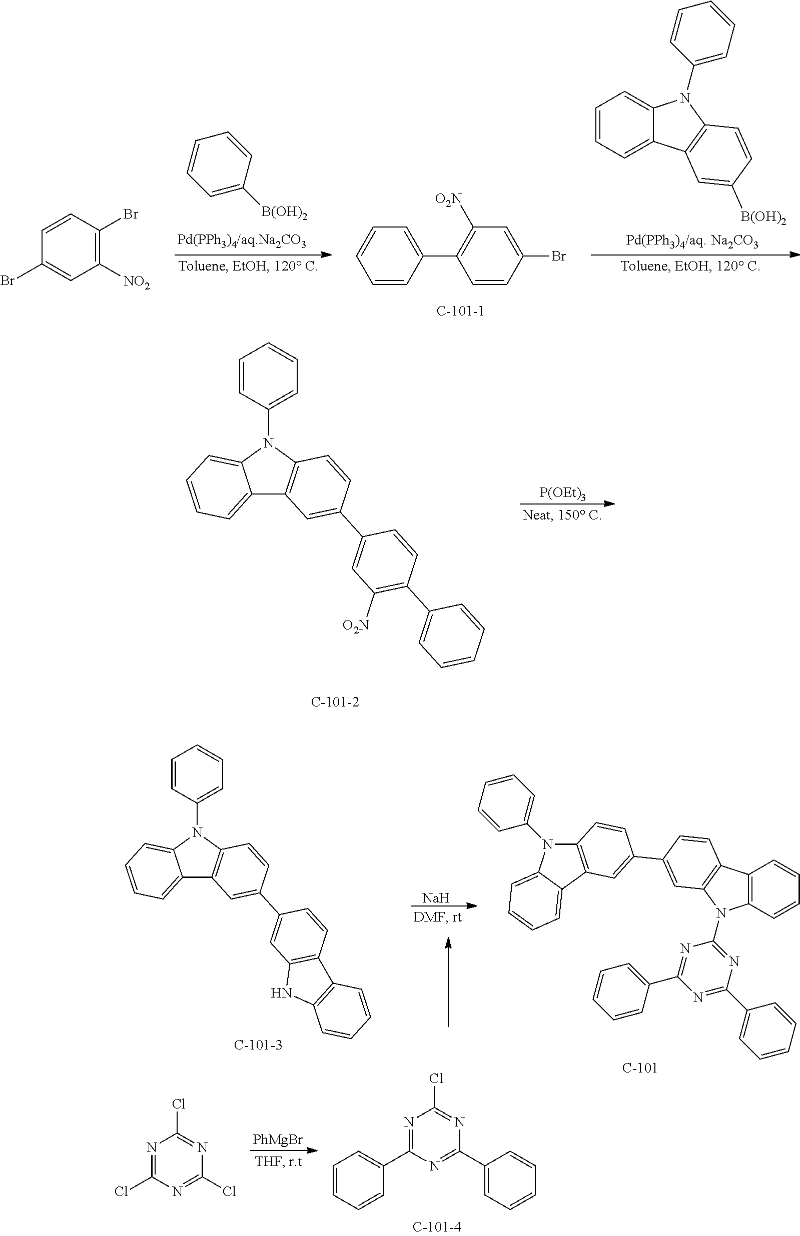

Preparation of compound C-101-1

After dissolving 1,4-dibromo-2-nitrobenzene 20 g (71.20 mmol), phenyl boronic acid 10.4 g (85.44 mmol), and Na₂CO₃ 18.9 g (178.00 mmol) in a mixture solvent of toluene 400 mL, ethanol 100 mL, and distilled water 100 mL, tetrakistriphenylphosphine palladium 2.5 g (2.14 mmol) was added to the mixture. Then, the mixture was stirred at 120° C. for 5 hours. Then, the reactant was cooled to room temperature, extracted with ethylacetate 400 mL, and the obtained organic layer was washed with distilled water 200 mL. The organic solvent was removed under reduced pressure. The obtained solid was washed with methanol, filtered, and dried. Then, the obtained product was separated using silica gel chromatography, and recrystallization to obtain compound C-101-1 13 g (66%).

Preparation of Compound C-101-2

After dissolving compound C-101-1 13 g (46.75 mmol), (9-phenyl-pH-carbazol-3-yl)boronic acid 16.1 g (56.09 mmol), and Na₂CO₃ 12.4 g (116.78 mmol) in a mixture solvent of toluene 240 mL, ethanol 60 mL, and distilled water 60 mL, tetrakistriphenylphosphine palladium 1.6 g (1.40 mmol) was added to the mixture. Then, the mixture was stirred at 120° C. for 5 hours. Then, the reactant was cooled to room temperature, extracted with ethylacetate 400 mL, and the obtained organic layer was washed with distilled water 200 mL. The organic solvent was removed under reduced pressure. The obtained solid was washed with methanol, filtered, and dried. Then, the obtained product was separated using silica gel chromatography, and recrystallization to obtain compound C-101-2 18 g (90%).

Preparation of Compound C-101-3

After dissolving compound C-101-2 18 g (40.86 mmol) in triethylphosphite 205 mL, the mixture was stirred at 150° C. under reflux. After 5 hours, the mixture was cooled to room temperature, and distilled under reduced pressure. Then, the obtained product was separated using silica gel chromatography, and recrystallization to obtain compound C-101-3 12 g (72%).

Preparation of Compound C-101-4

After dissolving 2,4,6-trichloro-1,3,5-triazine 36 g (195 mmol) in THF 360 mL, the mixture was cooled to 0° C., and PhMgBr 160 mL was slowly added. Then, the mixture was slowly heated to room temperature, and stirred for 12 hours. Then, after adding distilled water to the mixture to complete the reaction, the organic layer was extracted with EA. Then, the organic layer was distilled under reduced pressure, separated using silica gel chromatography, and recrystallization to obtain compound C-101-4 30 g (57%).

Preparation of Compound C-101

After dissolving compound C-101-3 7 g (17.14 mmol) in DMF 100 mL, NaH 1 g (25.71 mmol) was slowly added to the mixture. After stirring the mixture for 30 minutes, compound C-101-4 5.1 g (18.85 mmol) was added to the mixture, and stirred for 4 hours. The mixture was slowly added to MeOH 400 mL, and stirred for 30 minutes. The obtained solid was separated using silica gel chromatography, and recrystallization to obtain compound C-101 9.5 g (86%).

The detailed data of the compounds prepared in Example 4 to 9 (compounds C-3, C-13, C-32, C-35, C-62, and C-101), and the compounds that can be prepared using similar methods as in the above Examples (compounds C-17, C-33, C-40, C-42, and C-99) are shown in table 2 below.

TABLE 2

| | | PL Spectrum | | MS/EIMS | |
|---|---|---|---|---|---|
| Compound | Yield (%) | (nm) | MP (° C.) | Found | Calculated |
| C-3 | 59.98 | 478 | 206 | 714.85 | 714.28 |
| C-13 | 26.5 | 418 | 241 | 599.72 | 599.24 |
| C-17 | 48 | 463 | 145 | 714.85 | 714.28 |
| C-32 | 54 | 512 | 237 | 639.75 | 639.24 |
| C-33 | 49 | 407 | 140 | 637.77 | 637.25 |
| C-35 | 52.1 | 451 | 283 | 715.84 | 715.27 |
| C-40 | 24 | 485 | 285 | 580.70 | 580.17 |
| C-42 | 43 | 459 | 300 | 656.80 | 656.20 |
| C-62 | 28.5 | 466 | 250 | 715.84 | 715.27 |
| C-99 | 57 | 461 | 230 | 715.84 | 715.27 |
| C-101 | 86 | 481 | 280 | 639.75 | 639.24 |

### Device Example 1

### Production of an OLED Device Using the Organic Electroluminescent Compound According to the Present Invention

An OLED device was produced using the light emitting material according to the present invention. A transparent electrode indium tin oxide (ITO) thin film (15 Ω/sq) on a glass substrate for an organic light-emitting diode (OLED) device (Samsung Corning, Republic of Korea) was subjected to an ultrasonic washing with trichloroethylene, acetone, ethanol and distilled water, sequentially, and then was stored in isopropanol. Then, the ITO substrate was mounted on a substrate holder of a vacuum vapor depositing apparatus. N¹,N^{1′}-([1,1′-biphenyl]-4,4′-diyl)bis(N1-(naphthalen-1-yl)-N⁴,N⁴-diphenylbenzen-1,4-diamine) was introduced into a cell of said vacuum vapor depositing apparatus, and then the pressure in the chamber of said apparatus was controlled to 10⁻⁶ torr. Thereafter, an electric current was applied to the cell to evaporate the above introduced material, thereby forming a hole injection layer having a thickness of 60 nm on the ITO substrate. Then, N,N′-di(4-biphenyl)-N,N′-di(4-biphenyl)-4,4′-diaminophenyl was introduced into another cell of said vacuum vapor depositing apparatus, and was evaporated by applying an electric current to the cell, thereby forming a hole transport layer having a thickness of 20 nm on the hole injection layer. Thereafter, compound C-35 was introduced into one cell of the vacuum vapor depositing apparatus, as a host material, and compound D-28 was introduced into another cell as a dopant. The two materials were evaporated at different rates and were deposited in a doping amount of 15 wt % based on the total amount of the host and dopant to form a light-emitting layer having a thickness of 30 nm on the hole transport layer. Then, 2-(4-(9,10-di(naphthalen-2-yl)anthracen-2-yl)phenyl)-1-phenyl-1H-benzo[d]imidazole was introduced into one cell and lithium quinolate was introduced into another cell. The two materials were evaporated at the same rate and were deposited in a doping amount of 50 wt % each to form an electron transport layer having a thickness of 30 nm on the light-emitting layer. Then, after depositing lithium quinolate as an electron injection layer having a thickness of 2 nm on the electron transport layer, an Al cathode having a thickness of 150 nm was deposited by another vacuum vapor deposition apparatus on the electron injection layer. Thus, an OLED device was produced. All the materials used for producing the OLED device were purified by vacuum sublimation at 10⁻⁶ torr prior to use.

The produced OLED device showed a green emission having a luminance of 1620 cd/m² and a current density of 3.70 mA/cm² at a driving voltage of 2.9 V.

### Device Example 2

### Production of an OLED Device Using the Organic Electroluminescent Compound According to the Present Invention

An OLED device was produced in the same manner as in Device Example 1, except for using compound C-3 as a host, and using compound D-9 as a dopant of the light emitting material.

The produced OLED device showed a green emission having a luminance of 2450 cd/m² and a current density of 5.53 mA/cm² at a driving voltage of 3.5 V.

### Device Example 3

### Production of an OLED Device Using the Organic Electroluminescent Compound According to the Present Invention

An OLED device was produced in the same manner as in Device Example 1, except for using compound C-32 as a host, and using compound D-28 as a dopant of the light emitting material.

The produced OLED device showed a green emission having a luminance of 5740 cd/m² and a current density of 12.31 mA/cm² at a driving voltage of 3.5 V.

### Device Example 4

### Production of an OLED Device Using the Organic Electroluminescent Compound According to the Present Invention

An OLED device was produced in the same manner as in Device Example 1, except for using compound C-13 as a host, and using compound D-9 as a dopant of the light emitting material.

The produced OLED device showed a green emission having a luminance of 1530 cd/m² and a current density of 3.20 mA/cm² at a driving voltage of 3.1 V.

### Device Example 5

### Production of an OLED Device Using the Organic Electroluminescent Compound According to the Present Invention

An OLED device was produced in the same manner as in Device Example 1, except for using compound C-99 as a host, and using compound D-9 as a dopant of the light emitting material.

The produced OLED device showed a green emission having a luminance of 1890 cd/m² and a current density of 4.63 mA/cm² at a driving voltage of 3.1 V.

### Device Example 6

### Production of an OLED Device Using the Organic Electroluminescent Compound According to the Present Invention

An OLED device was produced in the same manner as in Device Example 1, except for using compound C-101 as a host, and using compound D-28 as a dopant of the light emitting material.

The produced OLED device showed a green emission having a luminance of 3370 cd/m² and a current density of 7.94 mA/cm² at a driving voltage of 3.3 V.

### Comparative Example 1

### Production of an OLED Device Using Conventional Light Emitting Material

An OLED device was produced in the same manner as in Device Example 1, except for using 4,4′-N,N′-dicarbazol-biphenyl as a host, compound Ir(ppy)₃ as a dopant to form a light-emitting layer having a thickness of 30 nm on the hole transport layer; and depositing aluminum(III)bis(2-methyl-8-quinolinato)4-phenylphenolate to form a hole blocking layer having a thickness of 10 nm.

The produced OLED device showed a green emission having a luminance of 3000 cd/m² and a current density of 9.8 mA/cm² at a driving voltage of 7.5 V.

As shown above, the organic EL device of the present invention contains a specific combination of a dopant and a host compound, and provides improved luminous efficiency at a lower driving voltage than the device using conventional luminous materials. This is because the energy gap is controlled by introducing alkyl and aryl groups to a Ir(ppy)₃ structure which is a conventional dopant compound. By this method, the energy gap of the host compound of the present invention is better combined with the dopant compound of the present invention than that of the conventional host compound, and finally the organic EL device of the present invention provides excellent luminous efficiency.

1. A combination of one or more dopant compounds represented by the following formula 1, and one or more host compounds represented by the following formula 2: 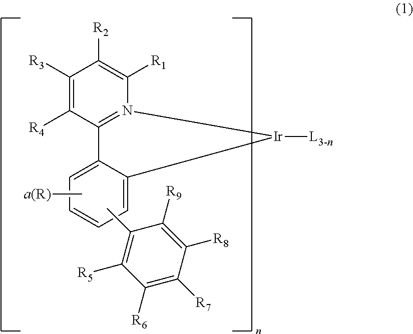
wherein
L is an organic ligand;
R₁ to R₉ each independently represent hydrogen, deuterium, a halogen, a substituted or unsubstituted (C1-C30)alkyl, a substituted or unsubstituted (C3-C30)cycloalkyl, a substituted or unsubstituted (C1-C30)alkoxy, a substituted or unsubstituted (C6-C30)aryl, or a substituted or unsubstituted 3- to 30-membered heteroaryl;
R represents hydrogen, a halogen, a substituted or unsubstituted (C1-C30)alkyl, or a substituted or unsubstituted (C3-C30)cycloalkyl;
a represents an integer of 1 to 3; where a is an integer of 2 or more, each of R may be same or different; and
n represents an integer of 1 to 3;
H-(Cz-L₁)_{b}-L₂-M (2)
wherein
Cz is selected from the following structures: 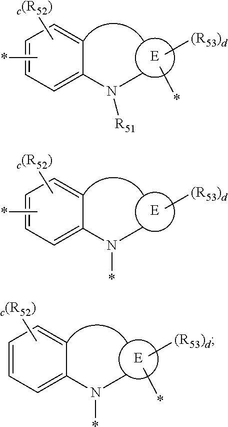
ring E represents a substituted or unsubstituted (C6-C30)cycloalkyl, a substituted or unsubstituted (C6-C30)aryl, or a substituted or unsubstituted 3- to 30-membered heteroaryl;
R₅₁ to R₅₃ each independently represent hydrogen, deuterium, a halogen, a substituted or unsubstituted (C1-C30)alkyl, a substituted or unsubstituted (C6-C30)aryl, a substituted or unsubstituted 3- to 30-membered heteroaryl, a substituted or unsubstituted 5- to 7-membered heterocycloalkyl, a substituted or unsubstituted (C6-C30)aryl fused with at least one substituted or unsubstituted (C3-C30)alicyclic ring, a 5- to 7-membered heterocycloalkyl fused with at least one substituted or unsubstituted (C6-C30)aromatic ring, a substituted or unsubstituted (C3-C30)cycloalkyl, a (C3-C30)cycloalkyl fused with at least one substituted or unsubstituted (C6-C30)aromatic ring, or a substituted or unsubstituted (C6-C30)aryl(C1-C30)alkyl;
L₁ and L₂ each independently represent a single bond, a substituted or unsubstituted (C6-C30)arylene, a substituted or unsubstituted 3- to 30-membered heteroarylene, or a substituted or unsubstituted (C6-C30)cycloalkylene;
M represents a substituted or unsubstituted (C6-C30)aryl, or a substituted or unsubstituted 3- to 30-membered heteroaryl;
b represents 1 or 2; where b is 2, each of Cz, and each of L₁ from each (Cz-L₁) may be same or different;
c and d each independently represent an integer of 0 to 4; where c or d is an integer of 2 or more, each of R₅₂, and each of R₅₃ may be same or different.

2. The combination according to claim 1, wherein the compound represented by formula 1 is represented by formula 3 or 4: 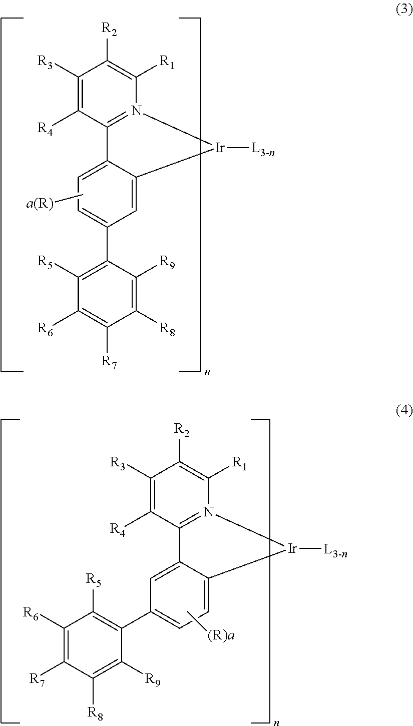
wherein R, R₁ to R₉, L, n, and a are as defined in claim 1.

3. The combination according to claim 1, wherein in formula 1, L is selected from the following structures: 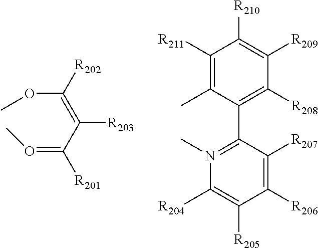
wherein R₂₀₁ to R₂₁₁ each independently represent hydrogen, deuterium, a halogen, a substituted or unsubstituted (C1-C30)alkyl, or a substituted or unsubstituted (C3-C30)cycloalkyl.

4. The combination according to claim 1, wherein in formula 2, Cz is selected from the following structures: 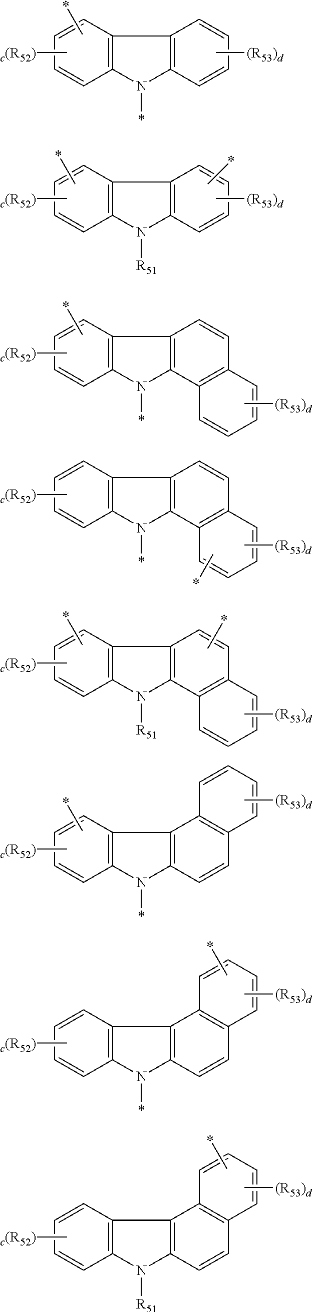
wherein R₅₁, R₅₂, R₅₃, c, and d are as defined in claim 1.

5. The combination according to claim 1, wherein the compound represented by formula 2 is represented by formula 5: 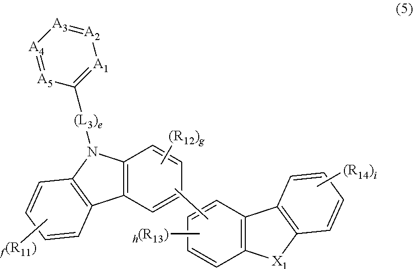
wherein
A₁ to A₅ each independently represent CR₂₃ or N;
X₁ represents —C(R₁₈)(R₁₉)—, —N(R₂₀)—, —S—, —O—, or —Si(R₂₁)(R₂₂)—;
L₃ represents a single bond, a substituted or unsubstituted (C6-C30)arylene, a substituted or unsubstituted 3- to 30-membered heteroarylene, or a substituted or unsubstituted (C6-C30)cycloalkylene;
R₁₁ to R₁₄, and R₁₈ to R₂₂ each independently represent hydrogen, deuterium, a halogen, a substituted or unsubstituted (C1-C30)alkyl, a substituted or unsubstituted (C6-C30)aryl, a substituted or unsubstituted 3- to 30-membered heteroaryl, a substituted or unsubstituted (C3-C30)cycloalkyl, a substituted or unsubstituted 5- to 7-membered heterocycloalkyl, a substituted or unsubstituted (C6-C30)aryl(C1-C30)alkyl, —NR₂₄R₂₅, —SiR₂₆R₂₇R₂₈, —SR₂₉, —OR₃₀, a cyano, a nitro, or a hydroxyl;
R₂₄ to R₃₀ each independently represent a substituted or unsubstituted (C1-C30)alkyl, a substituted or unsubstituted (C6-C30)aryl, or a substituted or unsubstituted 3- to 30-membered heteroaryl; or are linked to an adjacent substituent(s) to form a mono- or polycyclic, 5- to 30-membered alicyclic or aromatic ring;
R₂₃ represents hydrogen, deuterium, a halogen, a substituted or unsubstituted (C1-C30)alkyl, a substituted or unsubstituted (C6-C30)aryl, a substituted or unsubstituted (C6-C30)aryl fused with at least one substituted or unsubstituted (C3-C30)alicyclic ring, a substituted or unsubstituted 3- to 30-membered heteroaryl, a substituted or unsubstituted 5- to 7-membered heterocycloalkyl, a 5- to 7-membered heterocycloalkyl fused with at least one substituted or unsubstituted (C6-C30)aromatic ring, a substituted or unsubstituted (C3-C30)cycloalkyl, or a (C3-C30)cycloalkyl fused with at least one substituted or unsubstituted (C6-C30)aromatic ring; or are linked to an adjacent substituent(s) to form a mono- or polycyclic, 5- to 30-membered alicyclic or aromatic ring whose carbon atom(s) may be replaced with at least one hetero atom selected from the group consisting of nitrogen, oxygen and sulfur;
f to i each independently represent an integer of 0 to 4; where at least one of f to i is an integer of 2 or more, each of R₁₁ to R₁₄ may be same or different;
e represents 1 or 2; where e is 2, each of L₃ may be same or different.

6. The combination according to claim 5, wherein the compound represented by formula 5 is selected from formulae 6 to 8: 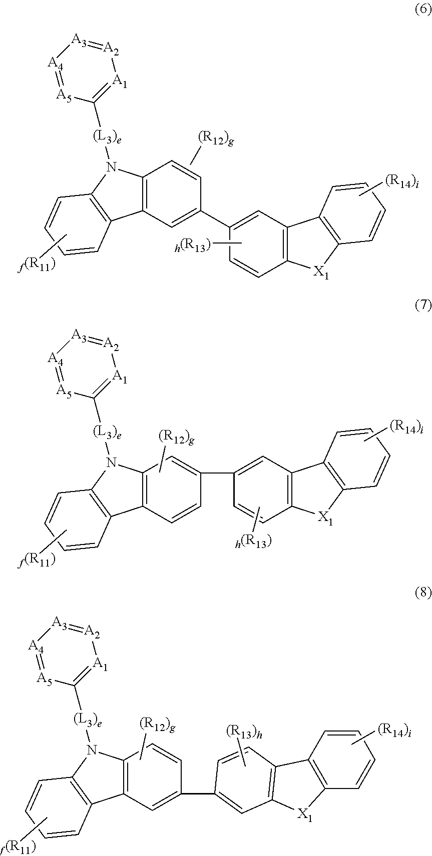
wherein A₁ to A₅, X₁, L₃, R₁₁ to R₁₄, and e to i are as defined in claim 5.

7. The combination according to claim 1, wherein the compound represented by formula 1 is selected from the group consisting of:

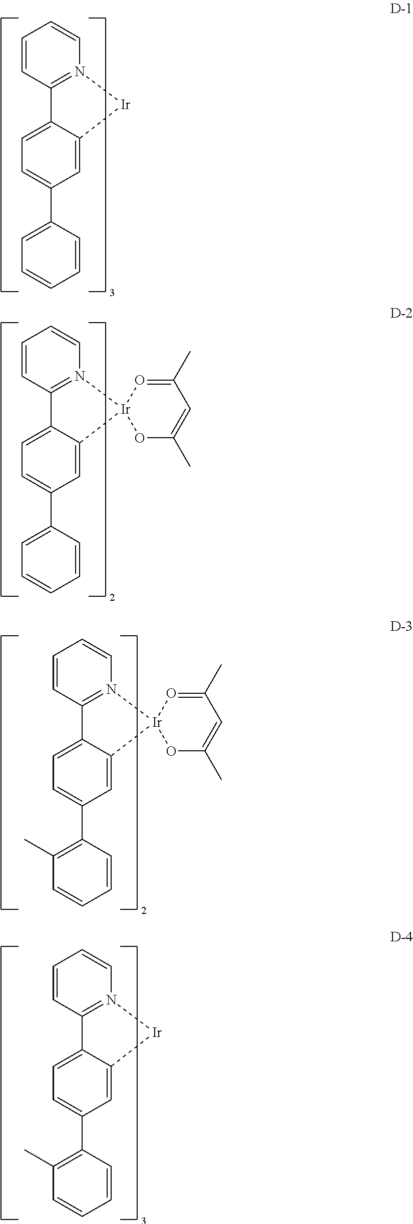

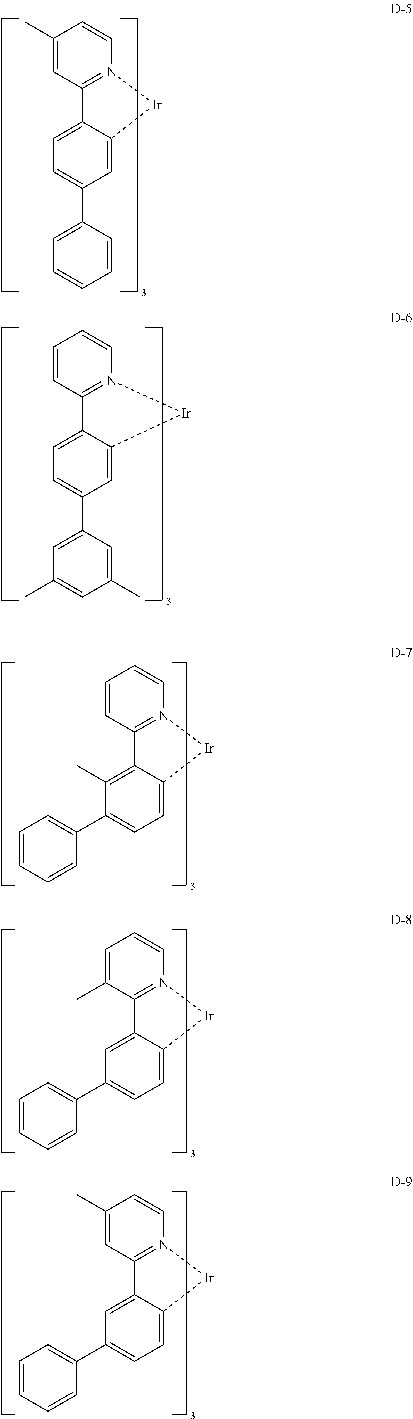

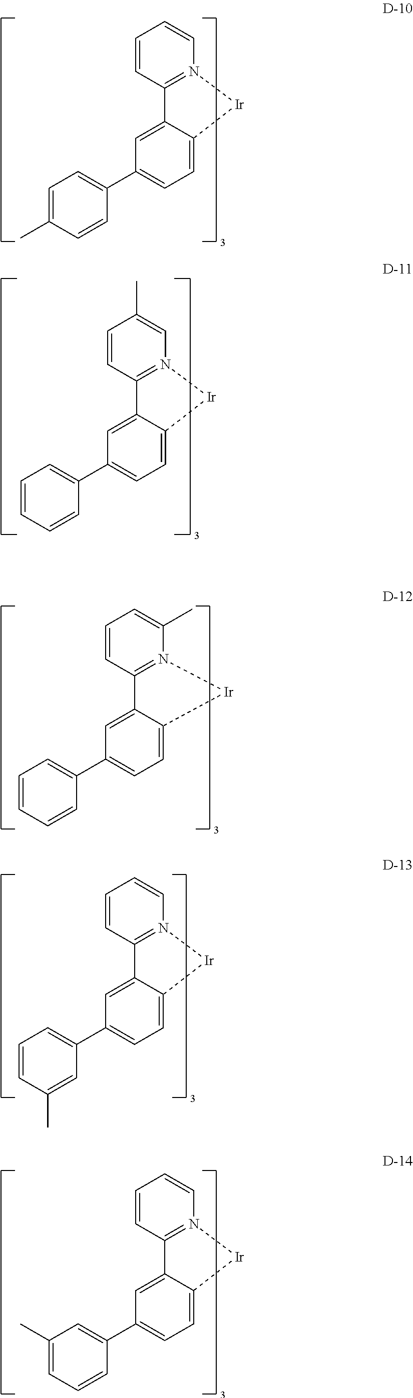

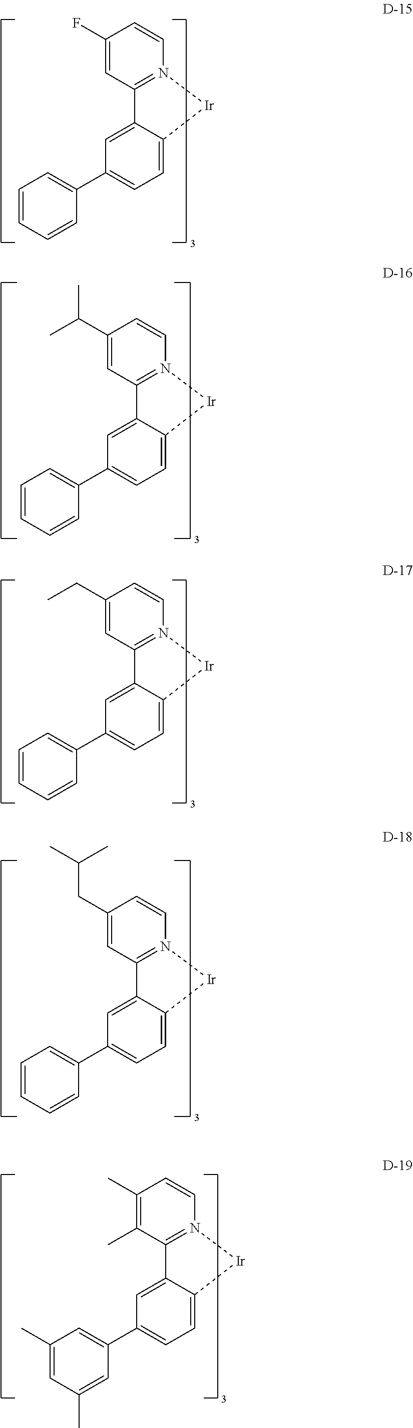

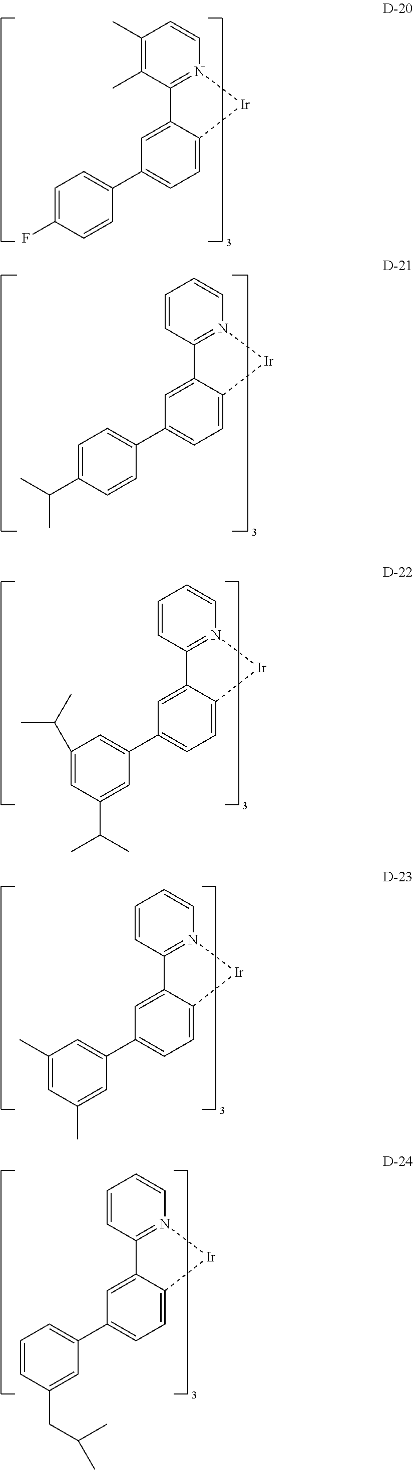

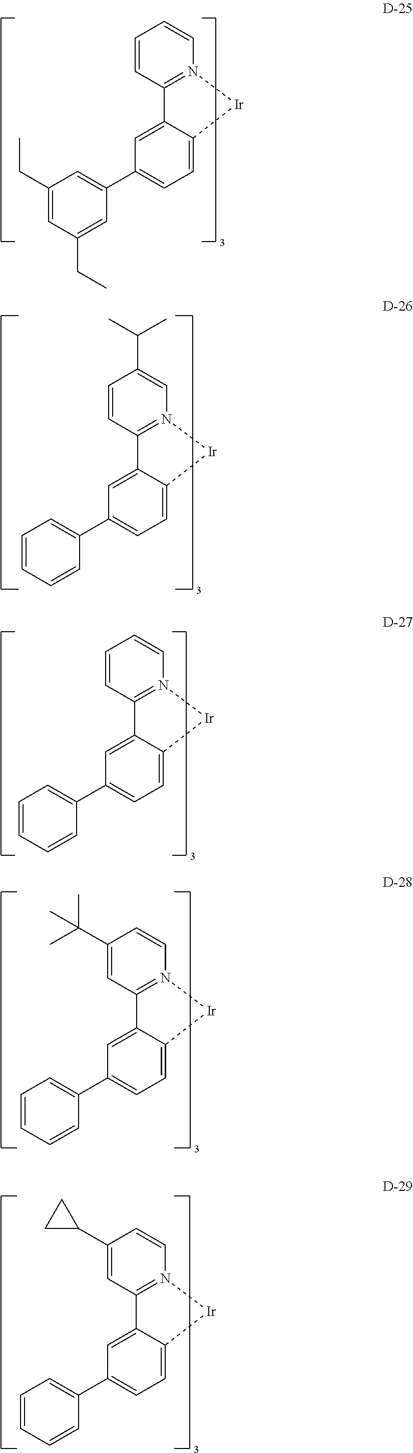

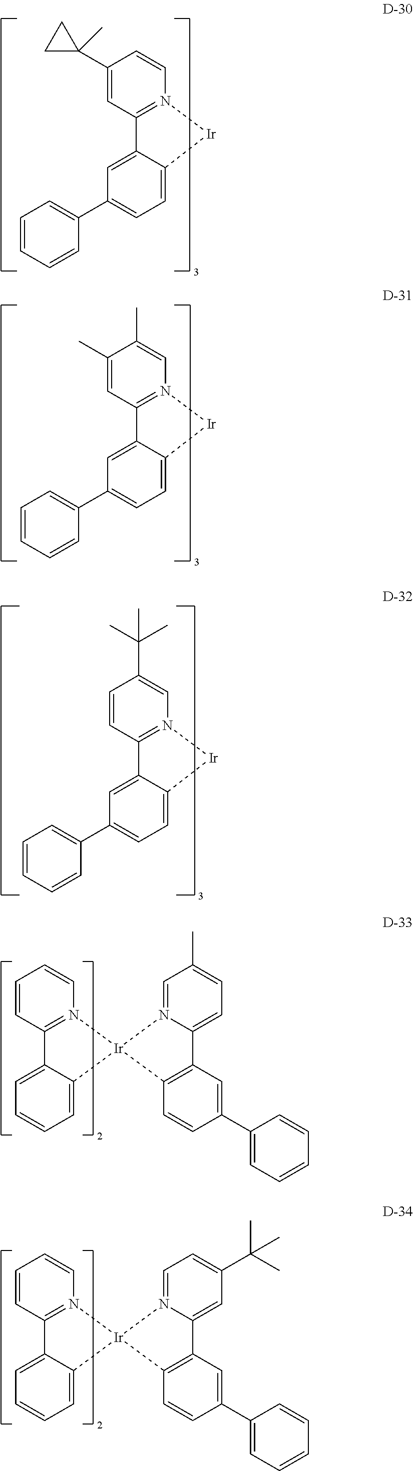

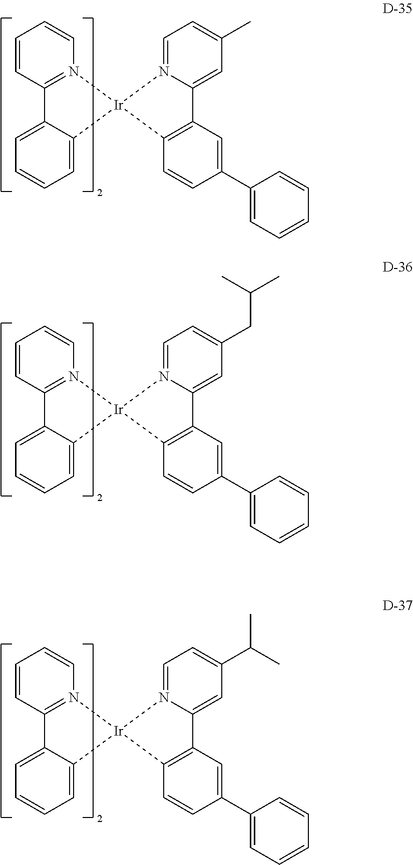

8. The combination according to claim 1, wherein the compound represented by formula 2 is selected from the group consisting of:

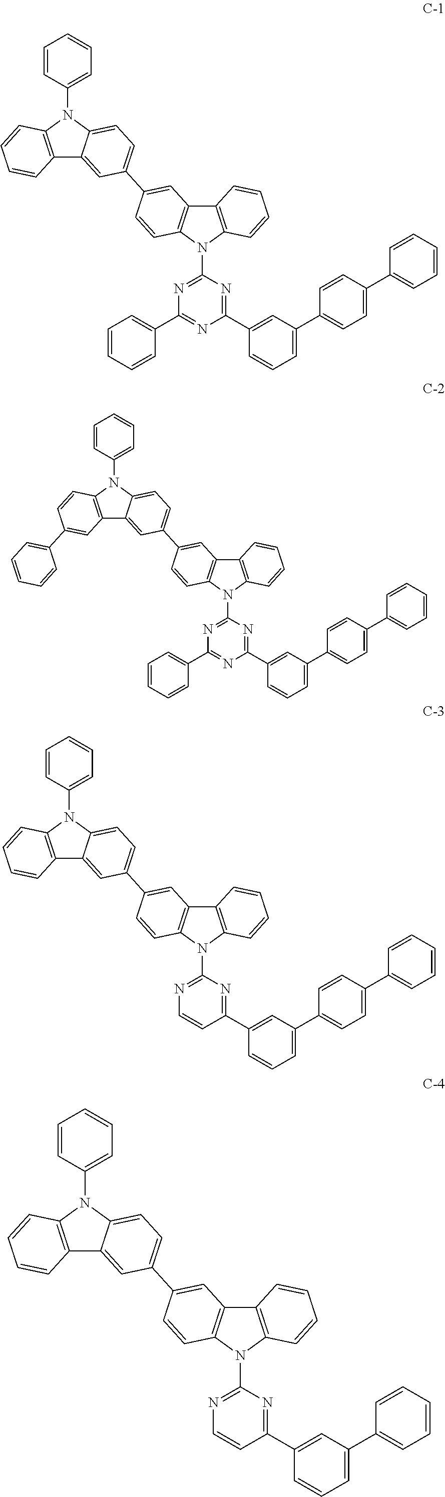 [SMILES: c1ccc(-c2ccc(-c3cccc(-c4nc(-c5ccccc5)nc(-n5c6ccccc6c6cc(-c7ccc8c(c7)c7ccccc7n8-c7ccccc7)ccc65)n4)c3)cc2)cc1 ; c1ccc(-c2ccc(-c3cccc(-c4nc(-c5ccccc5)nc(-n5c6ccccc6c6cc(-c7ccc8c(c7)c7cc(-c9ccccc9)ccc7n8-c7ccccc7)ccc65)n4)c3)cc2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1 ; c1ccc(-c2cccc(-c3ccnc(-n4c5ccccc5c5cc(-c6ccc7c(c6)c6ccccc6n7-c6ccccc6)ccc54)n3)c2)cc1]

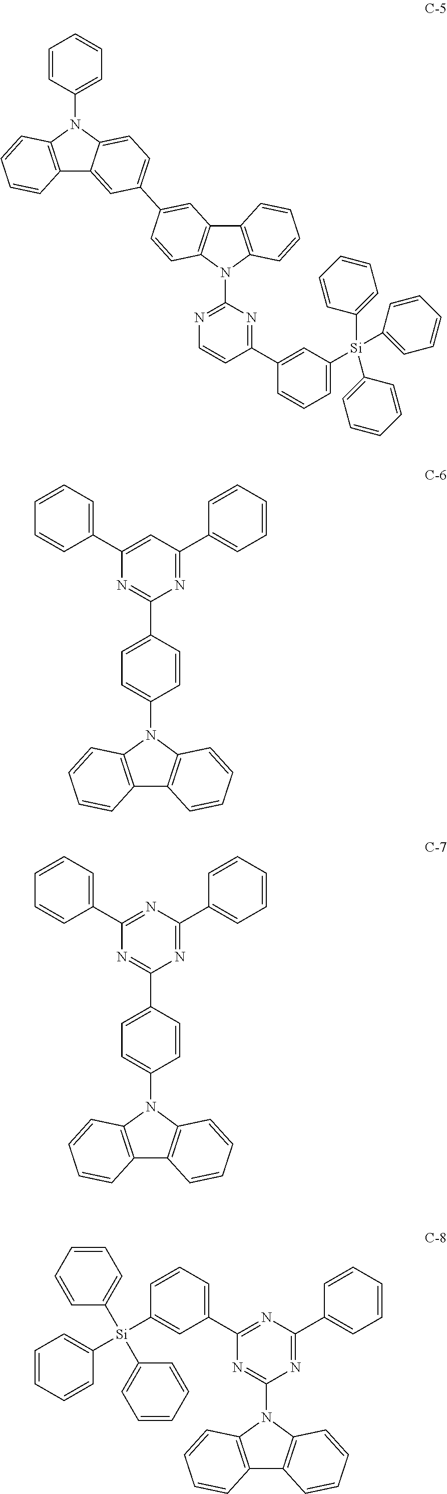 [SMILES: c1ccc(-n2c3ccccc3c3cc(-c4ccc5c(c4)c4ccccc4n5-c4nccc(-c5cccc([Si](c6ccccc6)(c6ccccc6)c6ccccc6)c5)n4)ccc32)cc1 ; c1ccc(-c2cc(-c3ccccc3)nc(-c3ccc(-n4c5ccccc5c5ccccc54)cc3)n2)cc1 ; c1ccc(-c2nc(-c3ccccc3)nc(-c3ccc(-n4c5ccccc5c5ccccc54)cc3)n2)cc1 ; c1ccc(-c2nc(-c3cccc([Si](c4ccccc4)(c4ccccc4)c4ccccc4)c3)nc(-n3c4ccccc4c4ccccc43)n2)cc1]

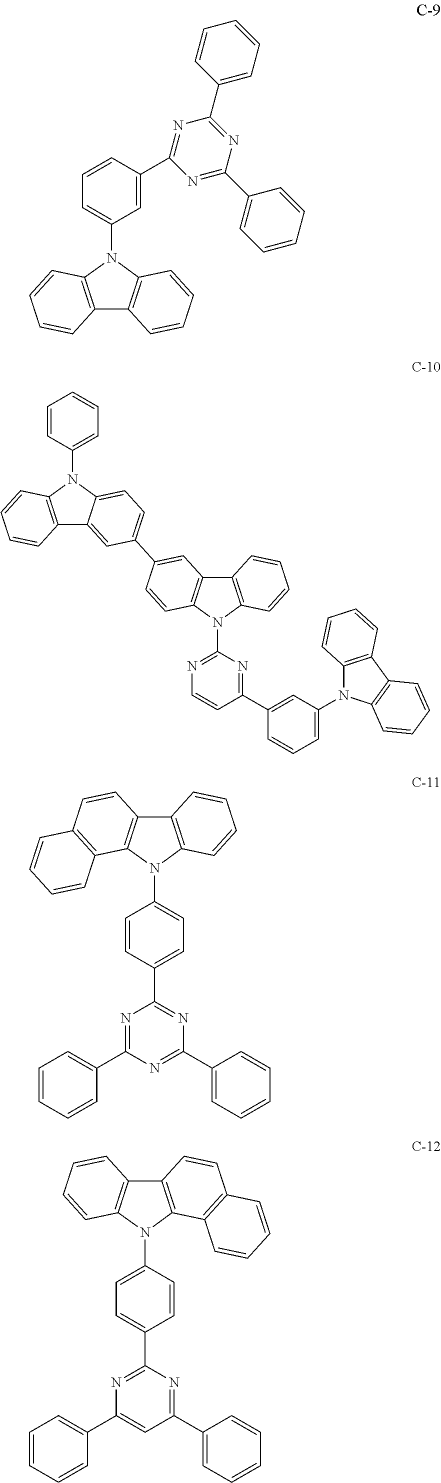

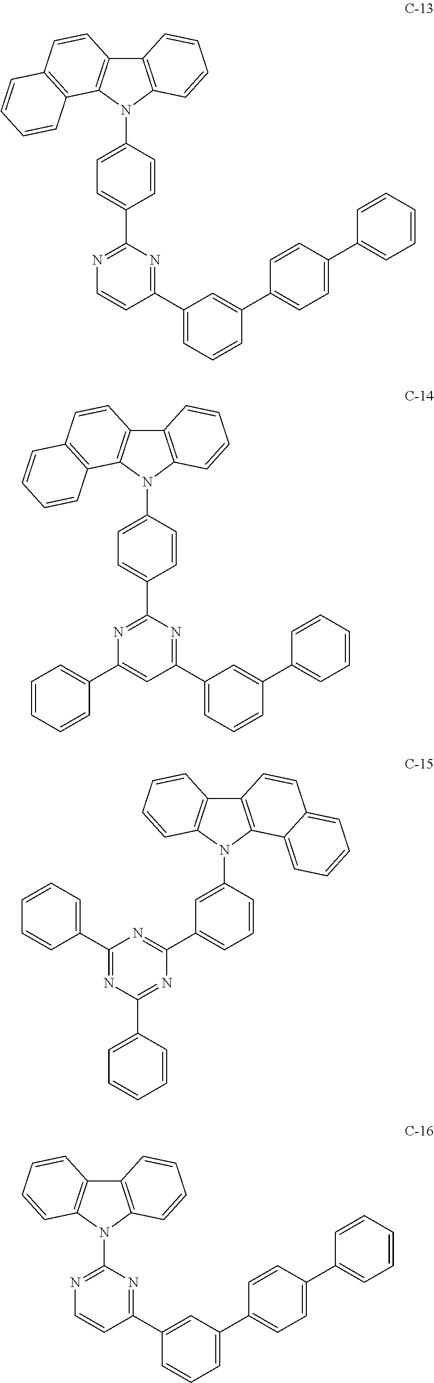 [SMILES: c1ccc(-c2ccc(-c3cccc(-c4ccnc(-c5ccc(-n6c7ccccc7c7ccc8ccccc8c76)cc5)n4)c3)cc2)cc1 ; c1ccc(-c2cccc(-c3cc(-c4ccccc4)nc(-c4ccc(-n5c6ccccc6c6ccc7ccccc7c65)cc4)n3)c2)cc1 ; c1ccc(-c2nc(-c3ccccc3)nc(-c3cccc(-n4c5ccccc5c5ccc6ccccc6c54)c3)n2)cc1 ; c1ccc(-c2ccc(-c3cccc(-c4ccnc(-n5c6ccccc6c6ccccc65)n4)c3)cc2)cc1]

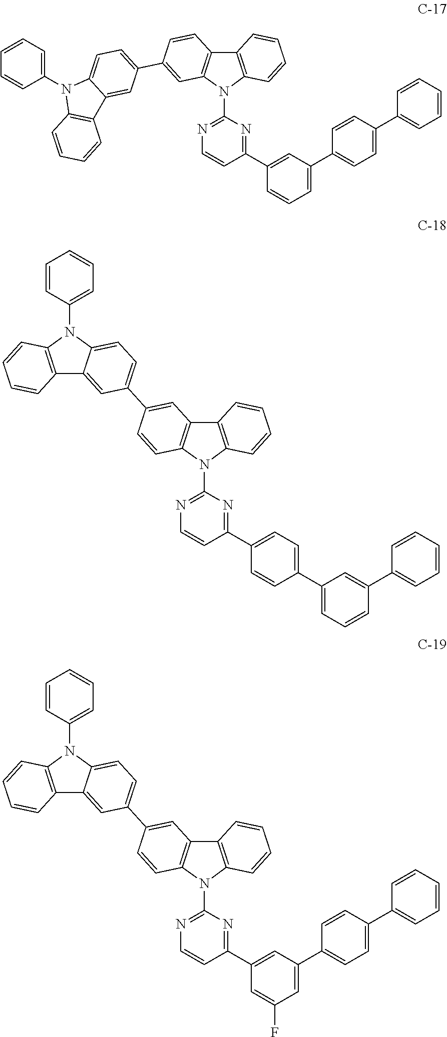 [SMILES: c1ccc(-c2ccc(-c3cccc(-c4ccnc(-n5c6ccccc6c6ccc(-c7ccc8c(c7)c7ccccc7n8-c7ccccc7)cc65)n4)c3)cc2)cc1 ; c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1 ; Fc1cc(-c2ccc(-c3ccccc3)cc2)cc(-c2ccnc(-n3c4ccccc4c4cc(-c5ccc6c(c5)c5ccccc5n6-c5ccccc5)ccc43)n2)c1]

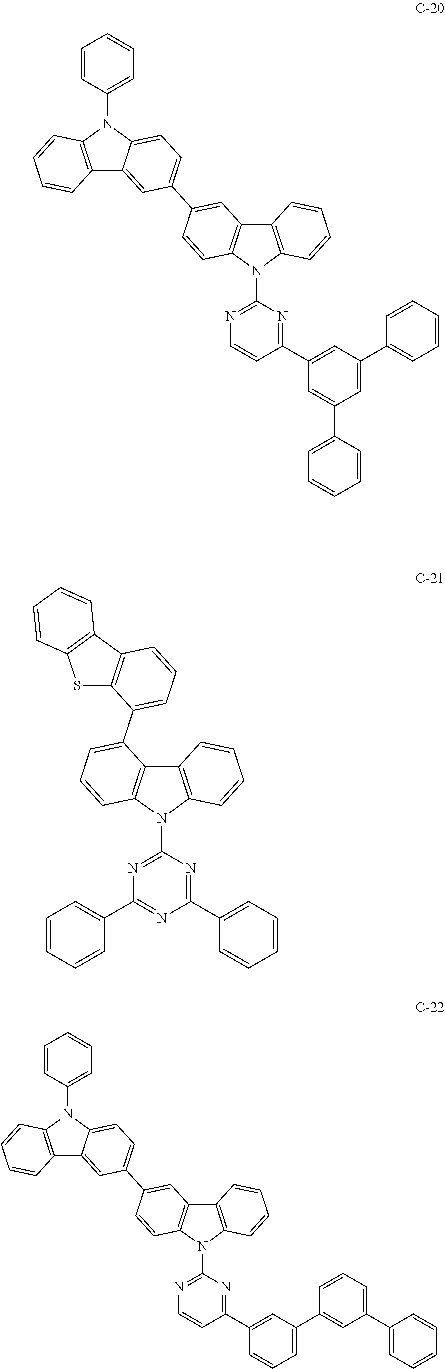 [SMILES: c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1 ; c1ccc(-c2nc(-c3ccccc3)nc(-n3c4ccccc4c4c(-c5cccc6c5sc5ccccc56)cccc43)n2)cc1 ; c1ccc(-c2cccc(-c3cccc(-c4ccnc(-n5c6ccccc6c6cc(-c7ccc8c(c7)c7ccccc7n8-c7ccccc7)ccc65)n4)c3)c2)cc1]

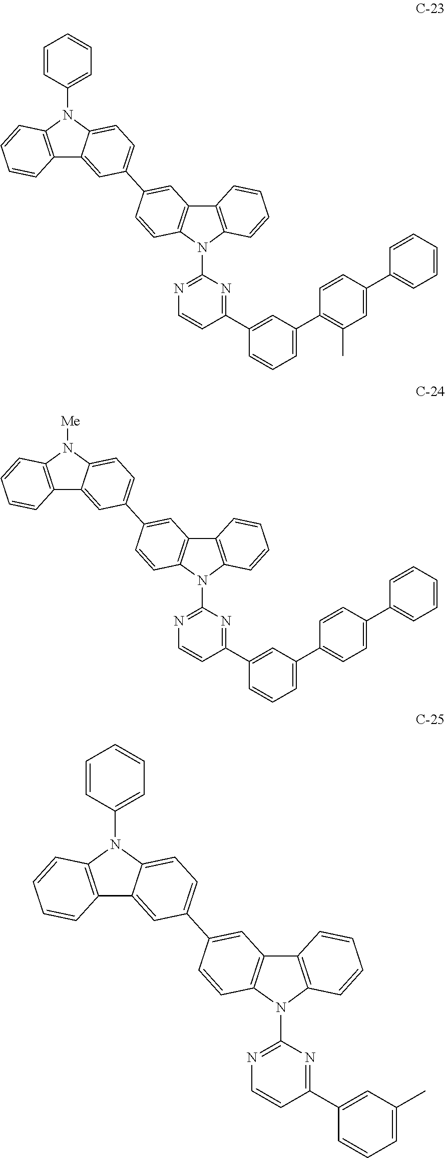 [SMILES: Cc1cc(-c2ccccc2)ccc1-c1cccc(-c2ccnc(-n3c4ccccc4c4cc(-c5ccc6c(c5)c5ccccc5n6-c5ccccc5)ccc43)n2)c1 ; Cn1c2ccccc2c2cc(-c3ccc4c(c3)c3ccccc3n4-c3nccc(-c4cccc(-c5ccc(-c6ccccc6)cc5)c4)n3)ccc21 ; Cc1cccc(-c2ccnc(-n3c4ccccc4c4cc(-c5ccc6c(c5)c5ccccc5n6-c5ccccc5)ccc43)n2)c1]

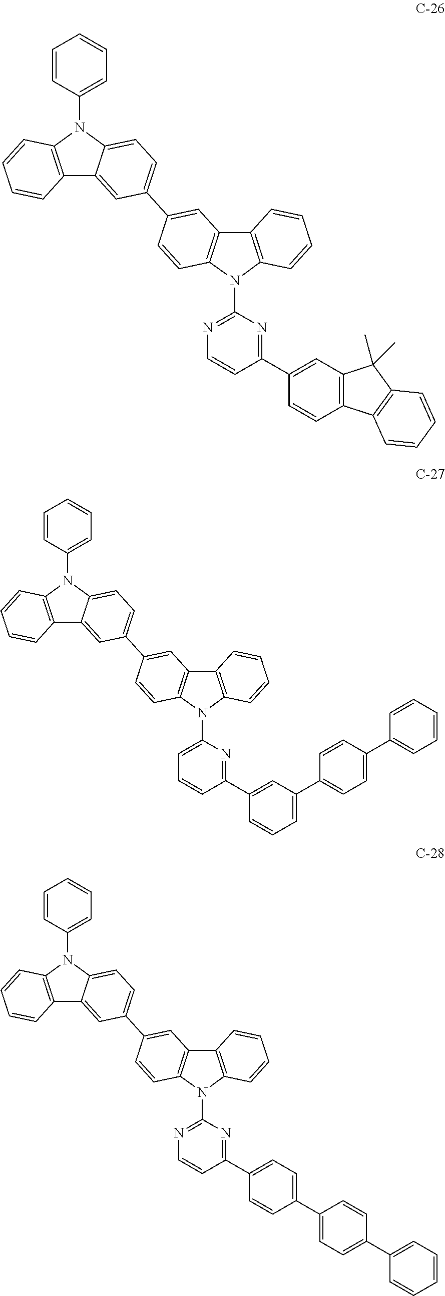 [SMILES: CC1(C)c2ccccc2-c2ccc(-c3ccnc(-n4c5ccccc5c5cc(-c6ccc7c(c6)c6ccccc6n7-c6ccccc6)ccc54)n3)cc21 ; c1ccc(-c2ccc(-c3cccc(-c4cccc(-n5c6ccccc6c6cc(-c7ccc8c(c7)c7ccccc7n8-c7ccccc7)ccc65)n4)c3)cc2)cc1 ; c1ccc(-c2ccc(-c3ccc(-c4ccnc(-n5c6ccccc6c6cc(-c7ccc8c(c7)c7ccccc7n8-c7ccccc7)ccc65)n4)cc3)cc2)cc1]

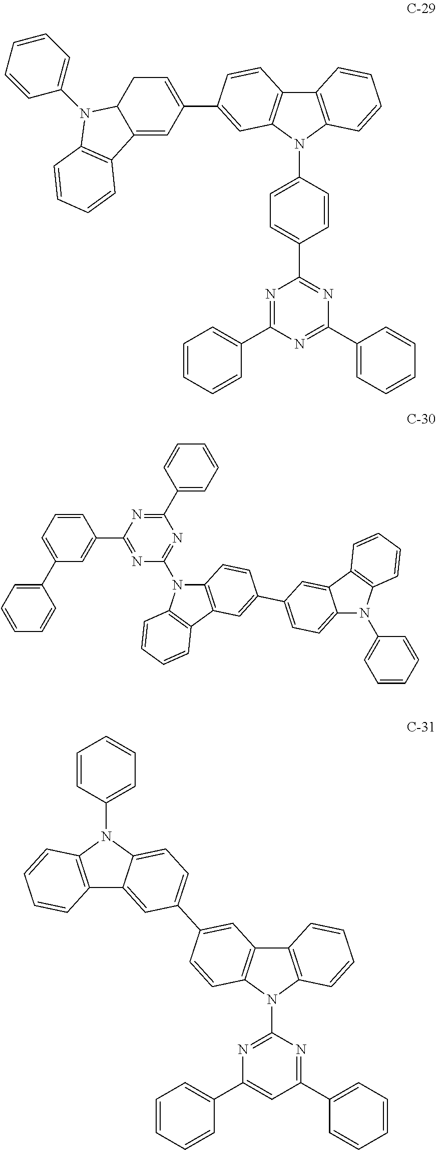 [SMILES: C1=C(c2ccc3c4ccccc4n(-c4ccc(-c5nc(-c6ccccc6)nc(-c6ccccc6)n5)cc4)c3c2)C=C2c3ccccc3N(c3ccccc3)C2C1 ; c1ccc(-c2cccc(-c3nc(-c4ccccc4)nc(-n4c5ccccc5c5cc(-c6ccc7c(c6)c6ccccc6n7-c6ccccc6)ccc54)n3)c2)cc1 ; c1ccc(-c2cc(-c3ccccc3)nc(-n3c4ccccc4c4cc(-c5ccc6c(c5)c5ccccc5n6-c5ccccc5)ccc43)n2)cc1]

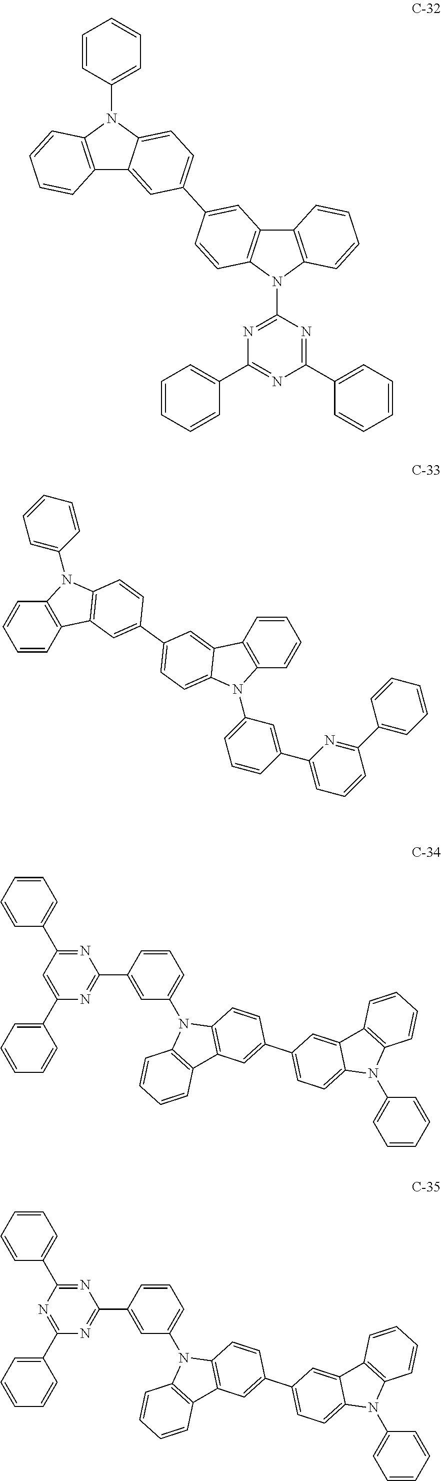 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-c3cccc(-n4c5ccccc5c5cc(-c6ccc7c(c6)c6ccccc6n7-c6ccccc6)ccc54)c3)n2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

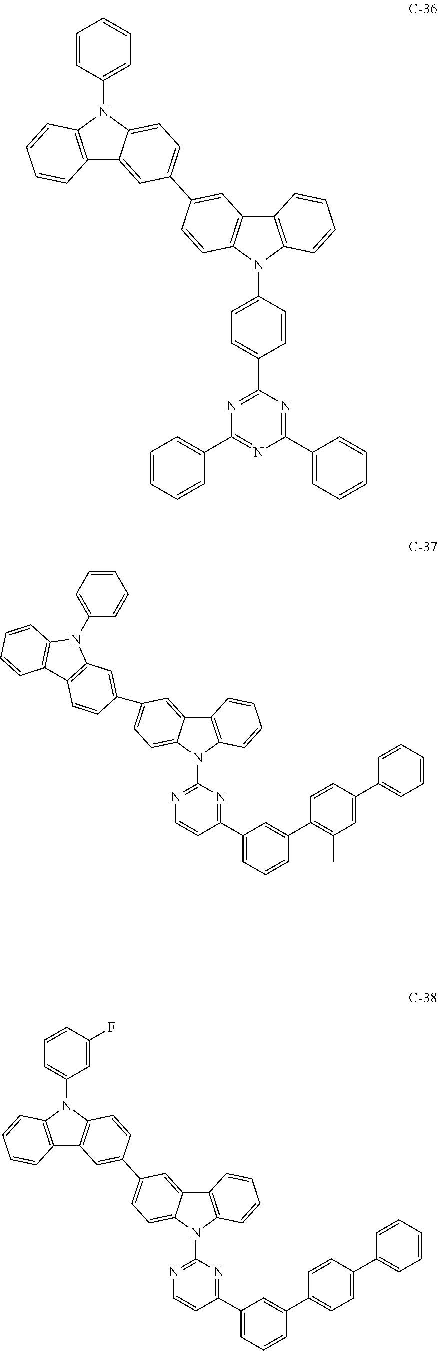 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; Cc1cc(-c2ccccc2)ccc1-c1cccc(-c2ccnc(-n3c4ccccc4c4cc(-c5ccc6c7ccccc7n(-c7ccccc7)c6c5)ccc43)n2)c1 ; Fc1cccc(-n2c3ccccc3c3cc(-c4ccc5c(c4)c4ccccc4n5-c4nccc(-c5cccc(-c6ccc(-c7ccccc7)cc6)c5)n4)ccc32)c1]

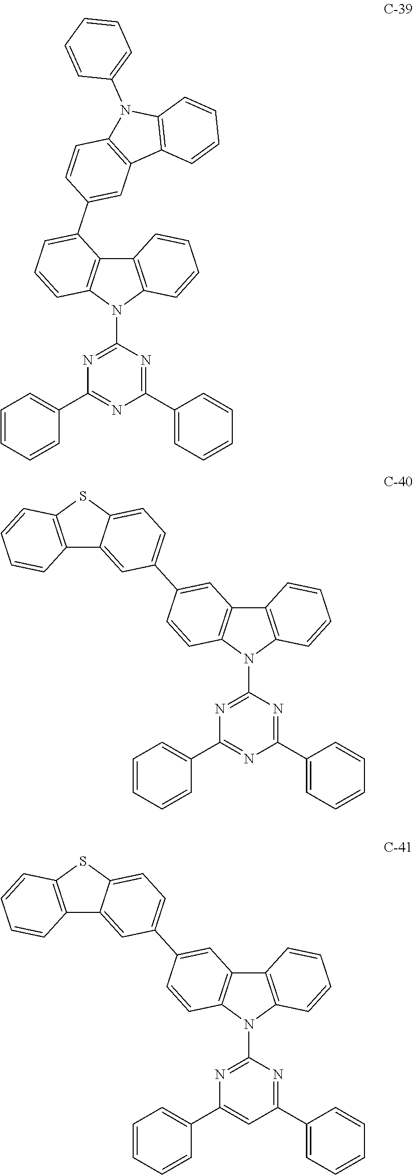 [SMILES: c1ccc(-c2nc(-c3ccccc3)nc(-n3c4ccccc4c4c(-c5ccc6c(c5)c5ccccc5n6-c5ccccc5)cccc43)n2)cc1 ; c1ccc(-c2nc(-c3ccccc3)nc(-n3c4ccccc4c4cc(-c5ccc6sc7ccccc7c6c5)ccc43)n2)cc1 ; c1ccc(-c2cc(-c3ccccc3)nc(-n3c4ccccc4c4cc(-c5ccc6sc7ccccc7c6c5)ccc43)n2)cc1]

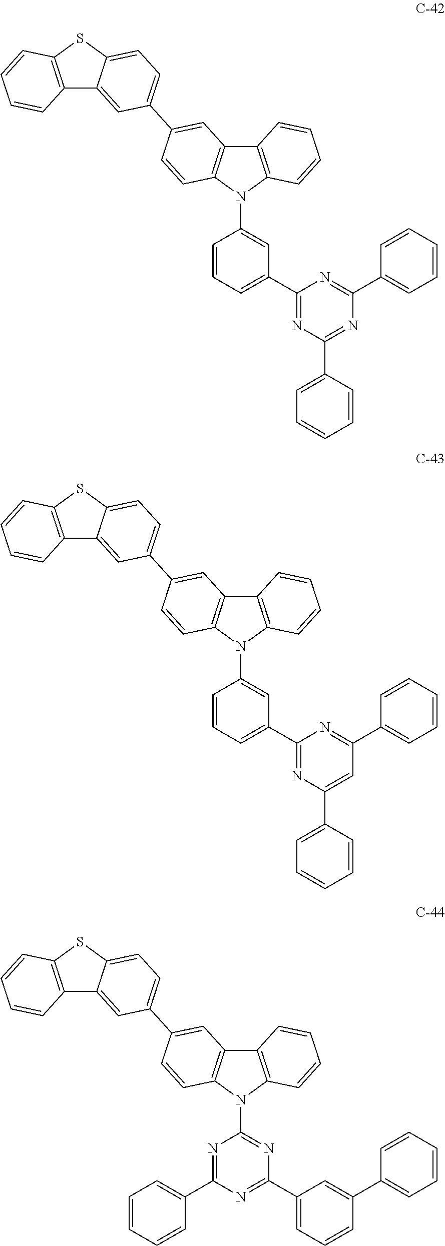 [SMILES: c1ccc(-c2nc(-c3ccccc3)nc(-c3cccc(-n4c5ccccc5c5cc(-c6ccc7sc8ccccc8c7c6)ccc54)c3)n2)cc1 ; c1ccc(-c2cc(-c3ccccc3)nc(-c3cccc(-n4c5ccccc5c5cc(-c6ccc7sc8ccccc8c7c6)ccc54)c3)n2)cc1 ; c1ccc(-c2cccc(-c3nc(-c4ccccc4)nc(-n4c5ccccc5c5cc(-c6ccc7sc8ccccc8c7c6)ccc54)n3)c2)cc1]

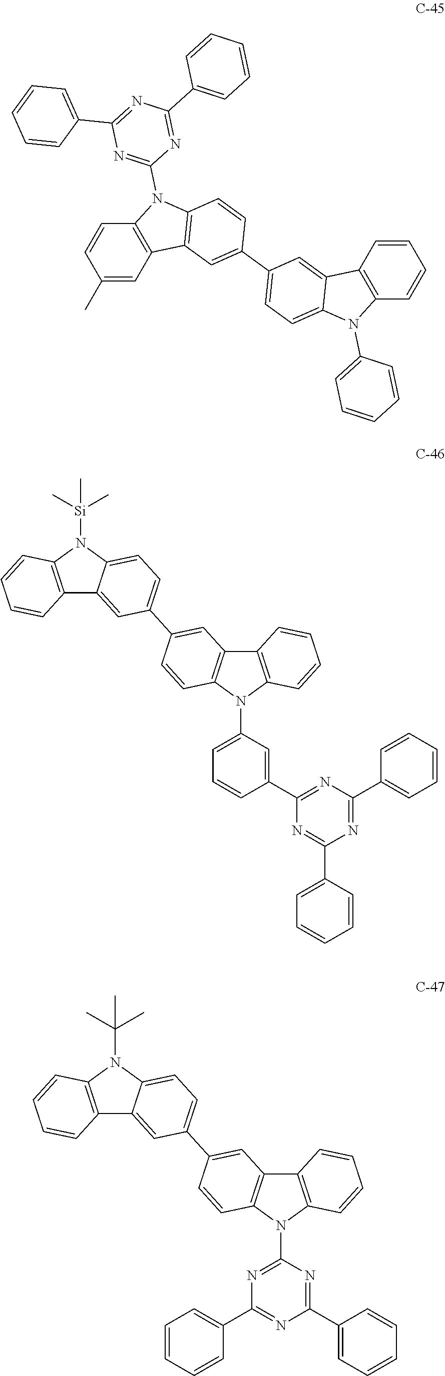 [SMILES: Cc1ccc2c(c1)c1cc(-c3ccc4c(c3)c3ccccc3n4-c3ccccc3)ccc1n2-c1nc(-c2ccccc2)nc(-c2ccccc2)n1 ; C[Si](C)(C)n1c2ccccc2c2cc(-c3ccc4c(c3)c3ccccc3n4-c3cccc(-c4nc(-c5ccccc5)nc(-c5ccccc5)n4)c3)ccc21 ; CC(C)(C)n1c2ccccc2c2cc(-c3ccc4c(c3)c3ccccc3n4-c3nc(-c4ccccc4)nc(-c4ccccc4)n3)ccc21]

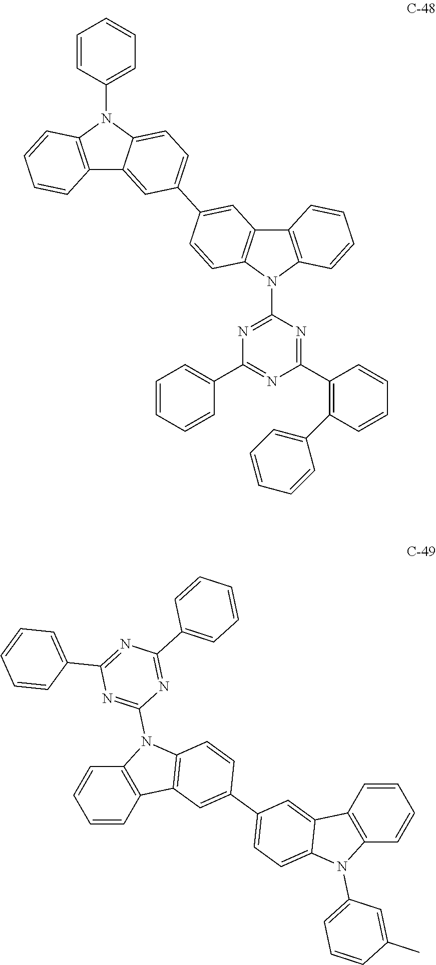 [SMILES: c1ccc(-c2nc(-c3ccccc3-c3ccccc3)nc(-n3c4ccccc4c4cc(-c5ccc6c(c5)c5ccccc5n6-c5ccccc5)ccc43)n2)cc1 ; Cc1cccc(-n2c3ccccc3c3cc(-c4ccc5c(c4)c4ccccc4n5-c4nc(-c5ccccc5)nc(-c5ccccc5)n4)ccc32)c1]

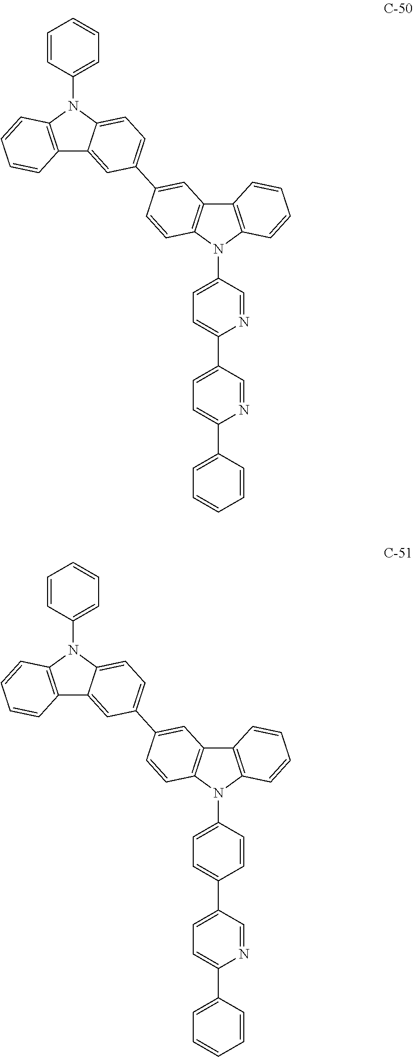 [SMILES: c1ccc(-c2ccc(-c3ccc(-n4c5ccccc5c5cc(-c6ccc7c(c6)c6ccccc6n7-c6ccccc6)ccc54)cn3)cn2)cc1 ; c1ccc(-c2ccc(-c3ccc(-n4c5ccccc5c5cc(-c6ccc7c(c6)c6ccccc6n7-c6ccccc6)ccc54)cc3)cn2)cc1]

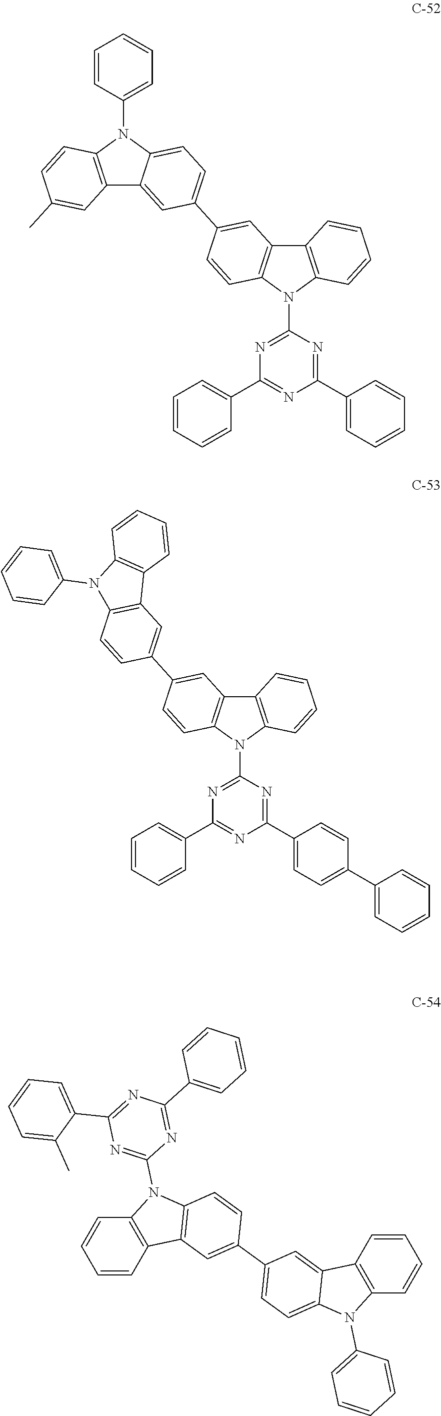 [SMILES: Cc1ccc2c(c1)c1cc(-c3ccc4c(c3)c3ccccc3n4-c3nc(-c4ccccc4)nc(-c4ccccc4)n3)ccc1n2-c1ccccc1 ; c1ccc(-c2ccc(-c3nc(-c4ccccc4)nc(-n4c5ccccc5c5cc(-c6ccc7c(c6)c6ccccc6n7-c6ccccc6)ccc54)n3)cc2)cc1 ; Cc1ccccc1-c1nc(-c2ccccc2)nc(-n2c3ccccc3c3cc(-c4ccc5c(c4)c4ccccc4n5-c4ccccc4)ccc32)n1]

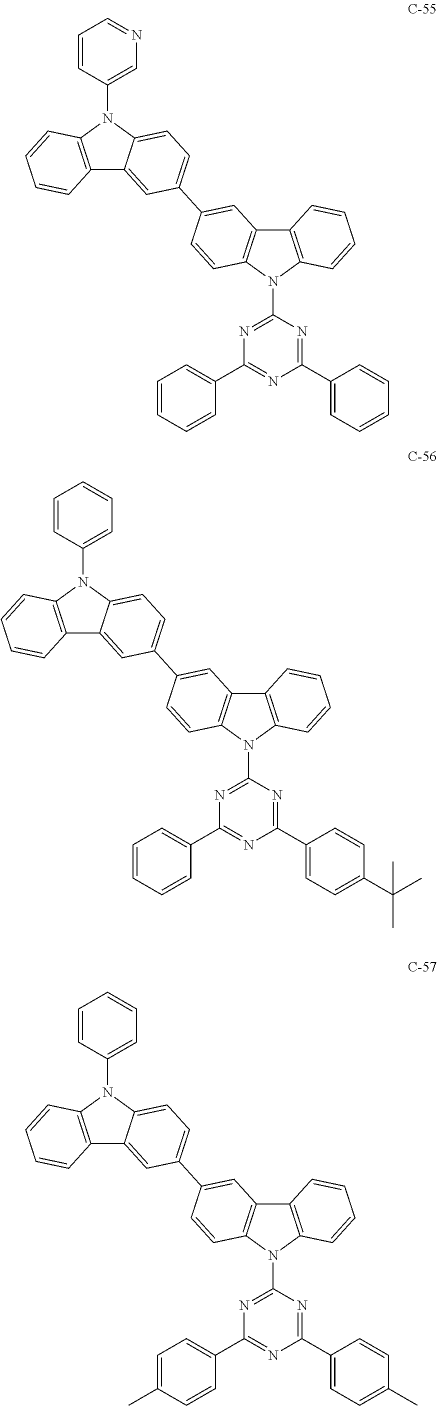 [SMILES: c1ccc(-c2nc(-c3ccccc3)nc(-n3c4ccccc4c4cc(-c5ccc6c(c5)c5ccccc5n6-c5cccnc5)ccc43)n2)cc1 ; CC(C)(C)c1ccc(-c2nc(-c3ccccc3)nc(-n3c4ccccc4c4cc(-c5ccc6c(c5)c5ccccc5n6-c5ccccc5)ccc43)n2)cc1 ; Cc1ccc(-c2nc(-c3ccc(C)cc3)nc(-n3c4ccccc4c4cc(-c5ccc6c(c5)c5ccccc5n6-c5ccccc5)ccc43)n2)cc1]

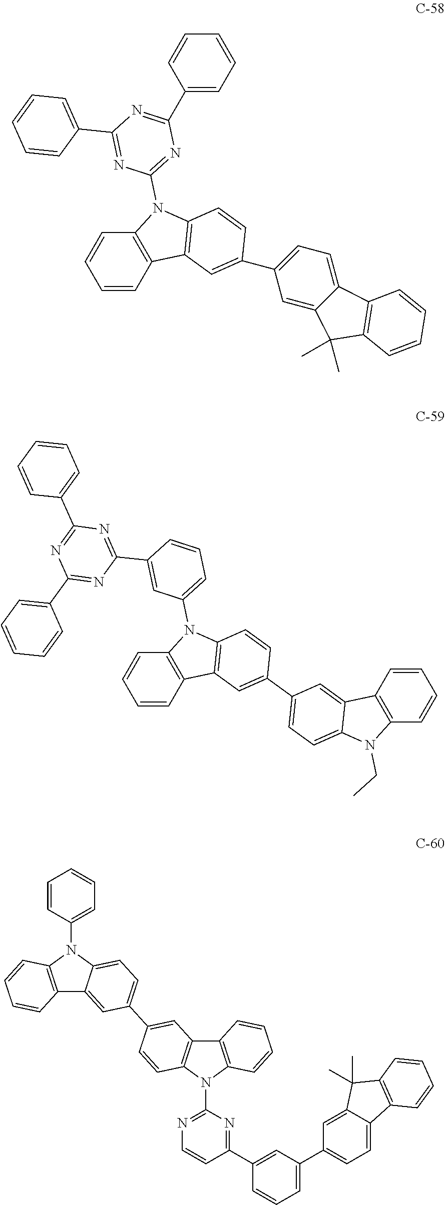 [SMILES: CC1(C)c2ccccc2-c2ccc(-c3ccc4c(c3)c3ccccc3n4-c3nc(-c4ccccc4)nc(-c4ccccc4)n3)cc21 ; CCn1c2ccccc2c2cc(-c3ccc4c(c3)c3ccccc3n4-c3cccc(-c4nc(-c5ccccc5)nc(-c5ccccc5)n4)c3)ccc21 ; CC1(C)c2ccccc2-c2ccc(-c3cccc(-c4ccnc(-n5c6ccccc6c6cc(-c7ccc8c(c7)c7ccccc7n8-c7ccccc7)ccc65)n4)c3)cc21]

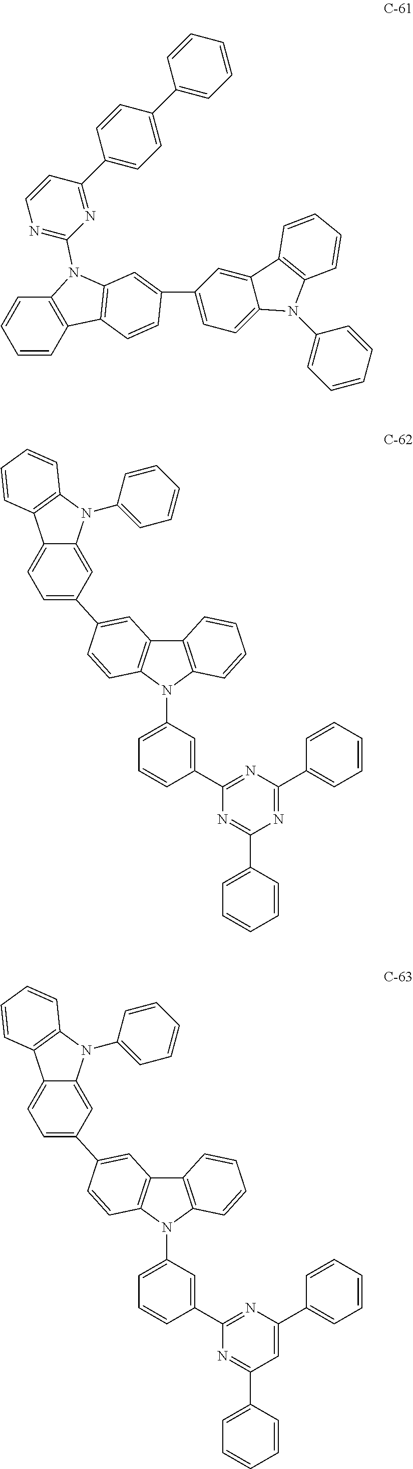 [SMILES: c1ccc(-c2ccc(-c3ccnc(-n4c5ccccc5c5ccc(-c6ccc7c(c6)c6ccccc6n7-c6ccccc6)cc54)n3)cc2)cc1 ; c1ccc(-c2nc(-c3ccccc3)nc(-c3cccc(-n4c5ccccc5c5cc(-c6ccc7c8ccccc8n(-c8ccccc8)c7c6)ccc54)c3)n2)cc1 ; c1ccc(-c2cc(-c3ccccc3)nc(-c3cccc(-n4c5ccccc5c5cc(-c6ccc7c8ccccc8n(-c8ccccc8)c7c6)ccc54)c3)n2)cc1]

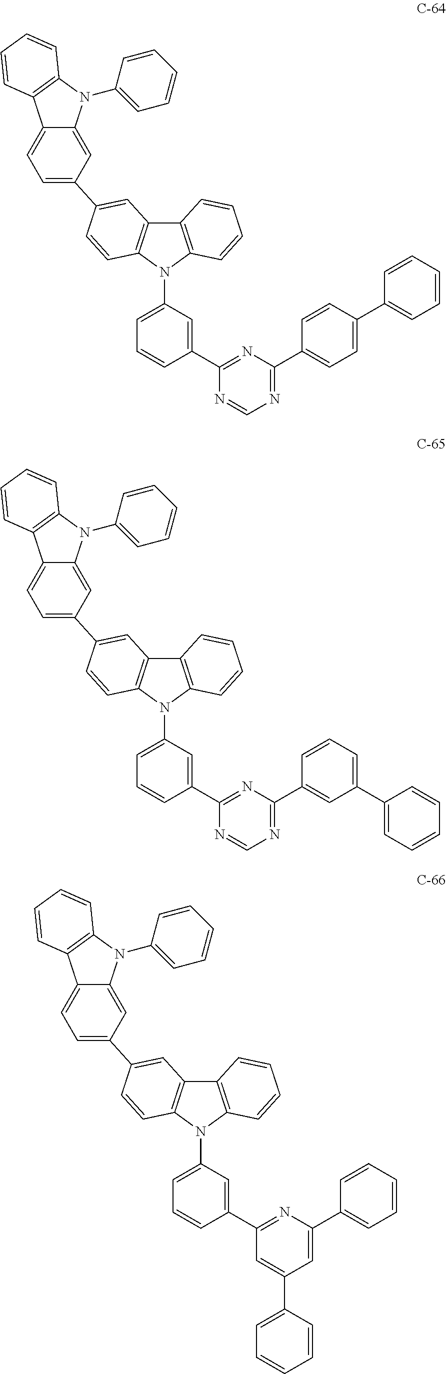 [SMILES: c1ccc(-c2ccc(-c3ncnc(-c4cccc(-n5c6ccccc6c6cc(-c7ccc8c9ccccc9n(-c9ccccc9)c8c7)ccc65)c4)n3)cc2)cc1 ; c1ccc(-c2cccc(-c3ncnc(-c4cccc(-n5c6ccccc6c6cc(-c7ccc8c9ccccc9n(-c9ccccc9)c8c7)ccc65)c4)n3)c2)cc1 ; c1ccc(-c2cc(-c3ccccc3)nc(-c3cccc(-n4c5ccccc5c5cc(-c6ccc7c8ccccc8n(-c8ccccc8)c7c6)ccc54)c3)c2)cc1]

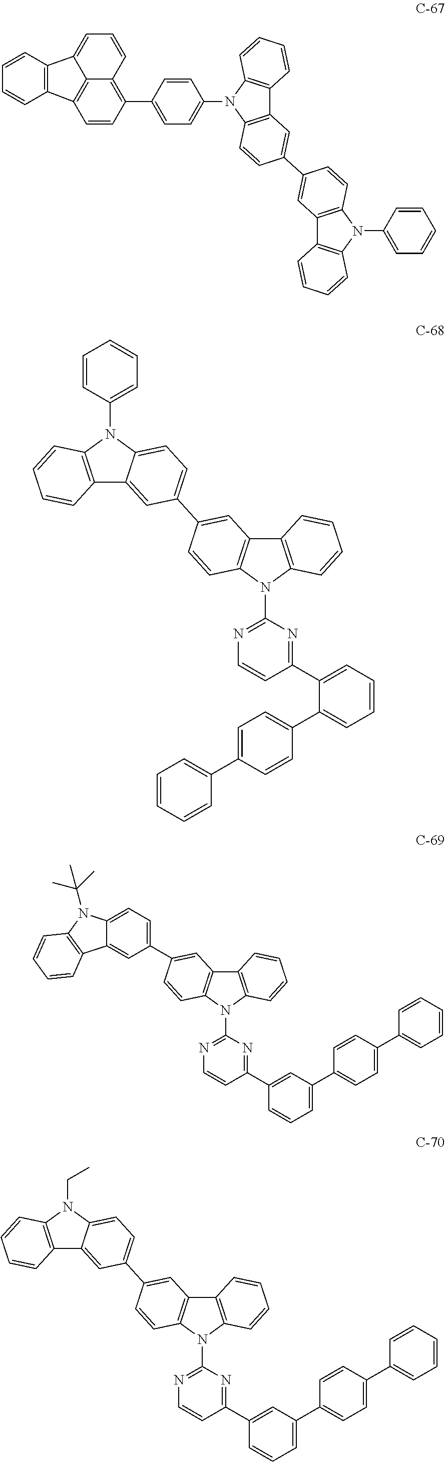 [SMILES: c1ccc(-n2c3ccccc3c3cc(-c4ccc5c(c4)c4ccccc4n5-c4ccc(-c5ccc6c7c(cccc57)-c5ccccc5-6)cc4)ccc32)cc1 ; c1ccc(-c2ccc(-c3ccccc3-c3ccnc(-n4c5ccccc5c5cc(-c6ccc7c(c6)c6ccccc6n7-c6ccccc6)ccc54)n3)cc2)cc1 ; CC(C)(C)n1c2ccccc2c2cc(-c3ccc4c(c3)c3ccccc3n4-c3nccc(-c4cccc(-c5ccc(-c6ccccc6)cc5)c4)n3)ccc21 ; CCn1c2ccccc2c2cc(-c3ccc4c(c3)c3ccccc3n4-c3nccc(-c4cccc(-c5ccc(-c6ccccc6)cc5)c4)n3)ccc21]

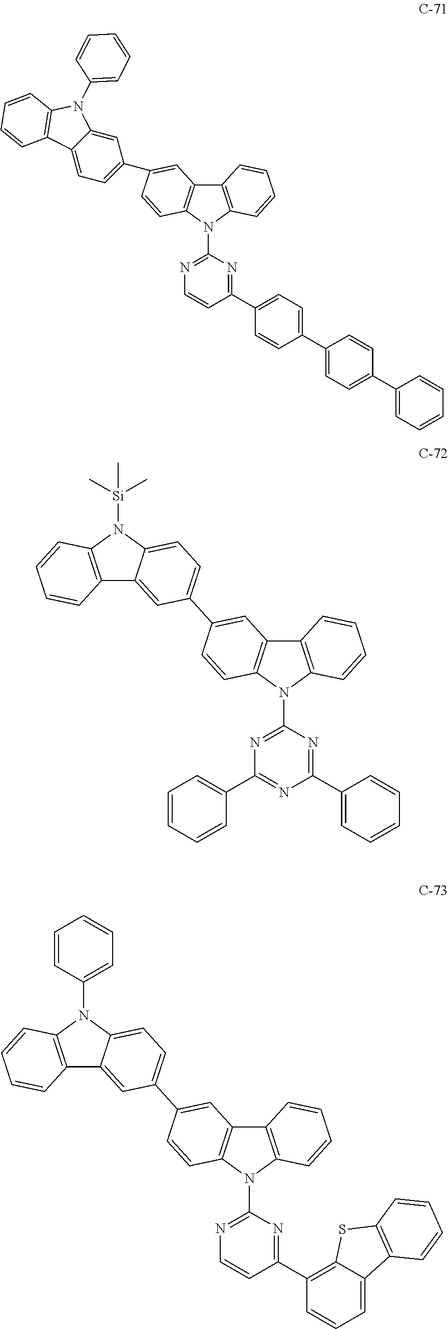 [SMILES: c1ccc(-c2ccc(-c3ccc(-c4ccnc(-n5c6ccccc6c6cc(-c7ccc8c9ccccc9n(-c9ccccc9)c8c7)ccc65)n4)cc3)cc2)cc1 ; C[Si](C)(C)n1c2ccccc2c2cc(-c3ccc4c(c3)c3ccccc3n4-c3nc(-c4ccccc4)nc(-c4ccccc4)n3)ccc21 ; c1ccc(-n2c3ccccc3c3cc(-c4ccc5c(c4)c4ccccc4n5-c4nccc(-c5cccc6c5sc5ccccc56)n4)ccc32)cc1]

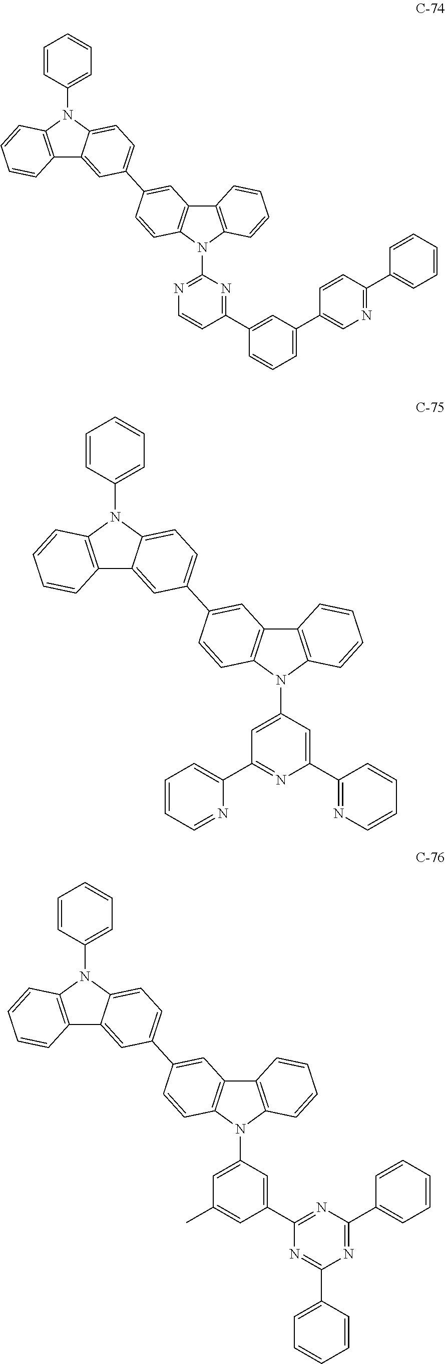 [SMILES: c1ccc(-c2ccc(-c3cccc(-c4ccnc(-n5c6ccccc6c6cc(-c7ccc8c(c7)c7ccccc7n8-c7ccccc7)ccc65)n4)c3)cn2)cc1 ; c1ccc(-n2c3ccccc3c3cc(-c4ccc5c(c4)c4ccccc4n5-c4cc(-c5ccccn5)nc(-c5ccccn5)c4)ccc32)cc1 ; Cc1cc(-c2nc(-c3ccccc3)nc(-c3ccccc3)n2)cc(-n2c3ccccc3c3cc(-c4ccc5c(c4)c4ccccc4n5-c4ccccc4)ccc32)c1]

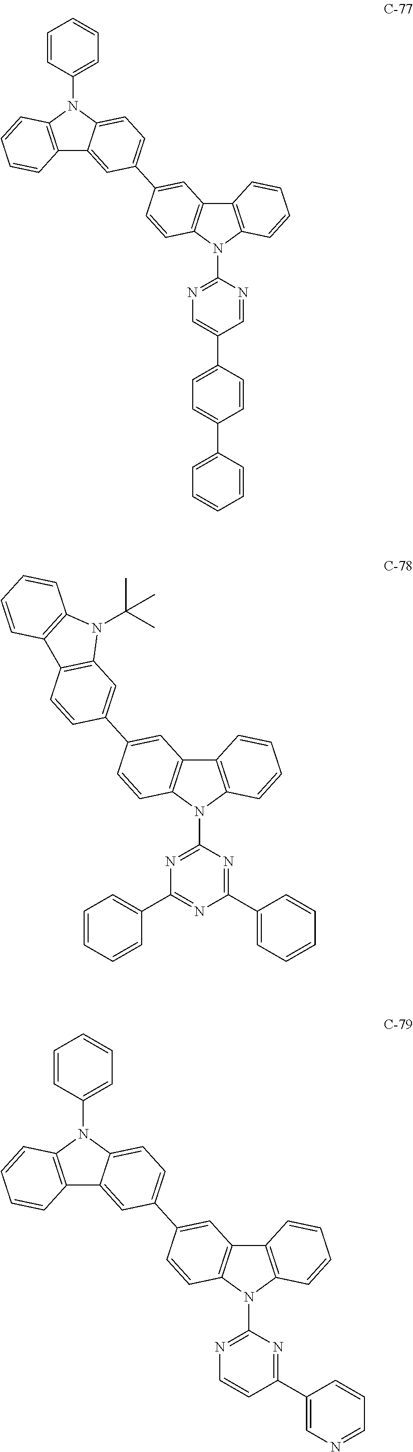 [SMILES: c1ccc(-c2ccc(-c3cnc(-n4c5ccccc5c5cc(-c6ccc7c(c6)c6ccccc6n7-c6ccccc6)ccc54)nc3)cc2)cc1 ; CC(C)(C)n1c2ccccc2c2ccc(-c3ccc4c(c3)c3ccccc3n4-c3nc(-c4ccccc4)nc(-c4ccccc4)n3)cc21 ; c1ccc(-n2c3ccccc3c3cc(-c4ccc5c(c4)c4ccccc4n5-c4nccc(-c5cccnc5)n4)ccc32)cc1]

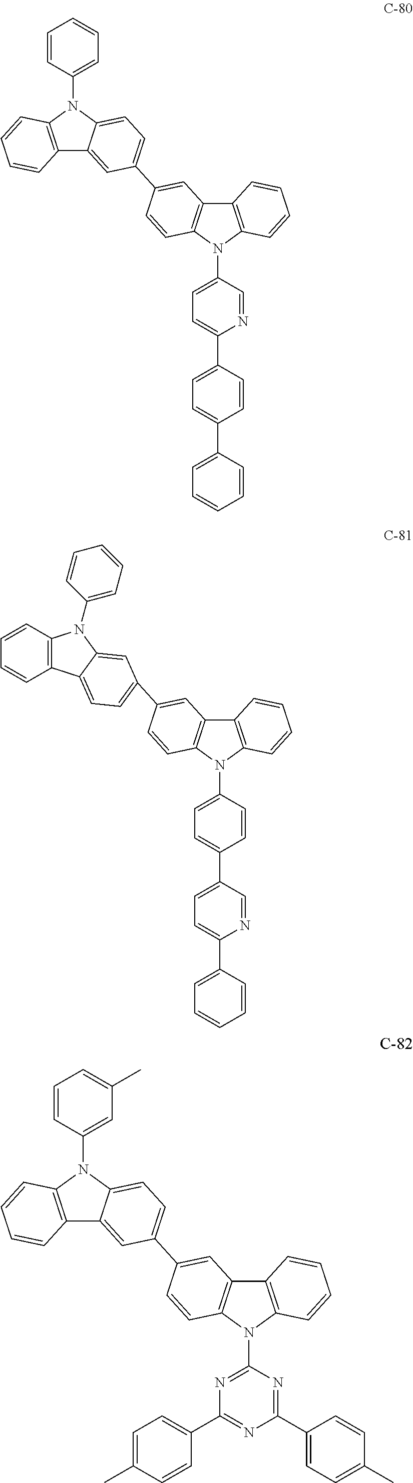 [SMILES: c1ccc(-c2ccc(-c3ccc(-n4c5ccccc5c5cc(-c6ccc7c(c6)c6ccccc6n7-c6ccccc6)ccc54)cn3)cc2)cc1 ; c1ccc(-c2ccc(-c3ccc(-n4c5ccccc5c5cc(-c6ccc7c8ccccc8n(-c8ccccc8)c7c6)ccc54)cc3)cn2)cc1 ; Cc1ccc(-c2nc(-c3ccc(C)cc3)nc(-n3c4ccccc4c4cc(-c5ccc6c(c5)c5ccccc5n6-c5cccc(C)c5)ccc43)n2)cc1]

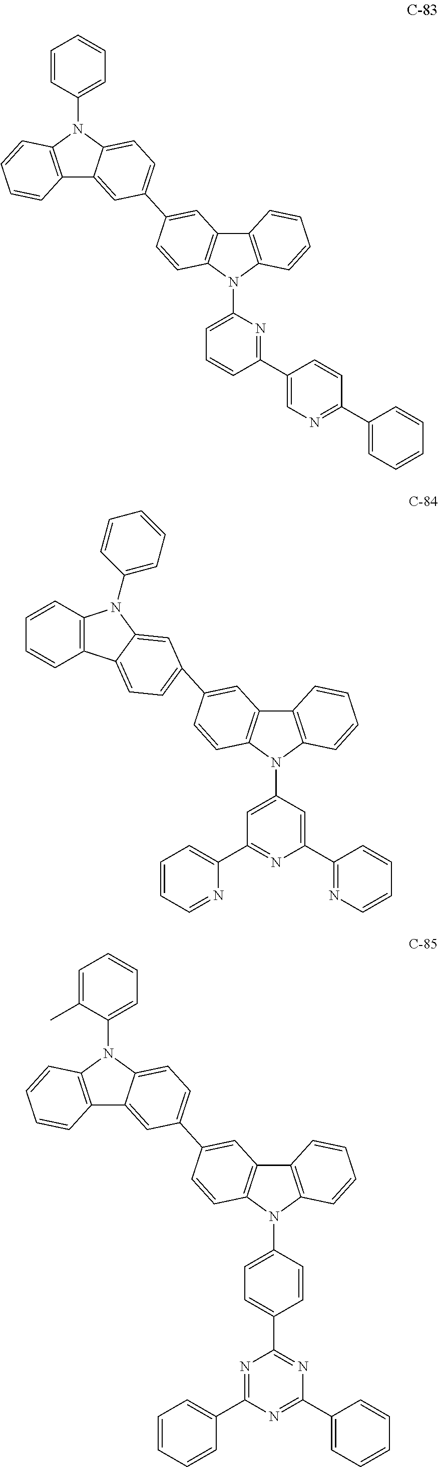 [SMILES: c1ccc(-c2ccc(-c3cccc(-n4c5ccccc5c5cc(-c6ccc7c(c6)c6ccccc6n7-c6ccccc6)ccc54)n3)cn2)cc1 ; c1ccc(-n2c3ccccc3c3ccc(-c4ccc5c(c4)c4ccccc4n5-c4cc(-c5ccccn5)nc(-c5ccccn5)c4)cc32)cc1 ; Cc1ccccc1-n1c2ccccc2c2cc(-c3ccc4c(c3)c3ccccc3n4-c3ccc(-c4nc(-c5ccccc5)nc(-c5ccccc5)n4)cc3)ccc21]

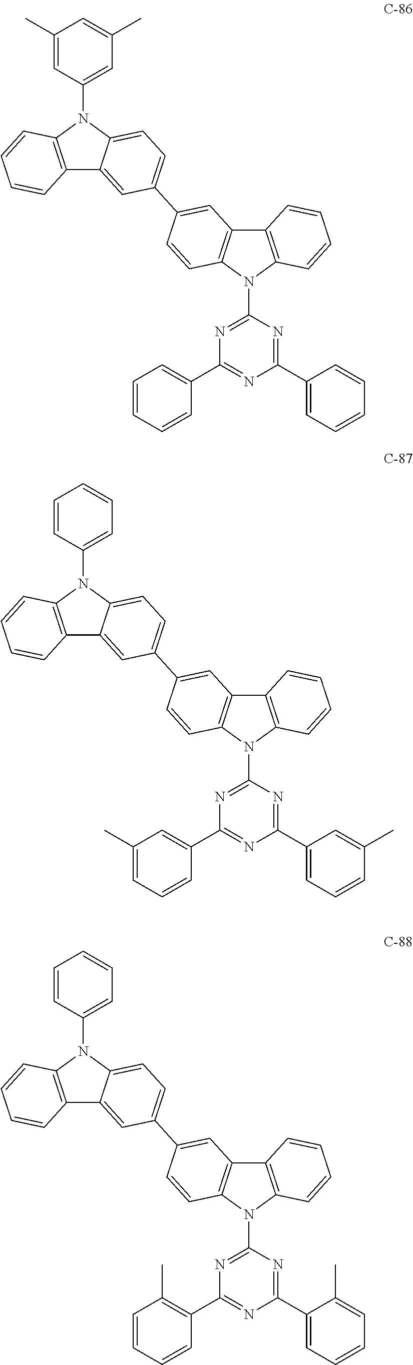 [SMILES: Cc1cc(C)cc(-n2c3ccccc3c3cc(-c4ccc5c(c4)c4ccccc4n5-c4nc(-c5ccccc5)nc(-c5ccccc5)n4)ccc32)c1 ; Cc1cccc(-c2nc(-c3cccc(C)c3)nc(-n3c4ccccc4c4cc(-c5ccc6c(c5)c5ccccc5n6-c5ccccc5)ccc43)n2)c1 ; Cc1ccccc1-c1nc(-c2ccccc2C)nc(-n2c3ccccc3c3cc(-c4ccc5c(c4)c4ccccc4n5-c4ccccc4)ccc32)n1]

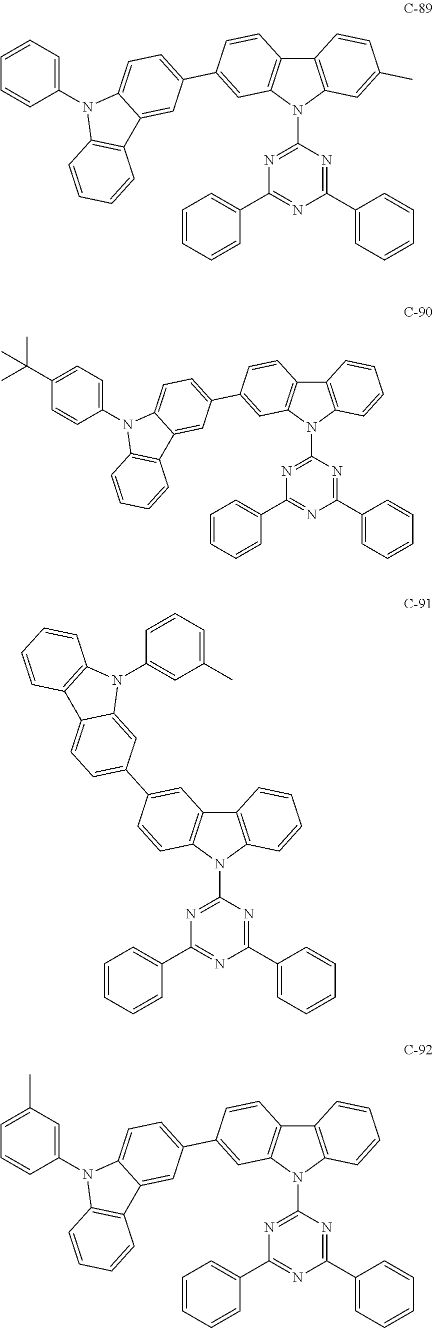 [SMILES: Cc1ccc2c3ccc(-c4ccc5c(c4)c4ccccc4n5-c4ccccc4)cc3n(-c3nc(-c4ccccc4)nc(-c4ccccc4)n3)c2c1 ; CC(C)(C)c1ccc(-n2c3ccccc3c3cc(-c4ccc5c6ccccc6n(-c6nc(-c7ccccc7)nc(-c7ccccc7)n6)c5c4)ccc32)cc1 ; Cc1cccc(-n2c3ccccc3c3ccc(-c4ccc5c(c4)c4ccccc4n5-c4nc(-c5ccccc5)nc(-c5ccccc5)n4)cc32)c1 ; Cc1cccc(-n2c3ccccc3c3cc(-c4ccc5c6ccccc6n(-c6nc(-c7ccccc7)nc(-c7ccccc7)n6)c5c4)ccc32)c1]

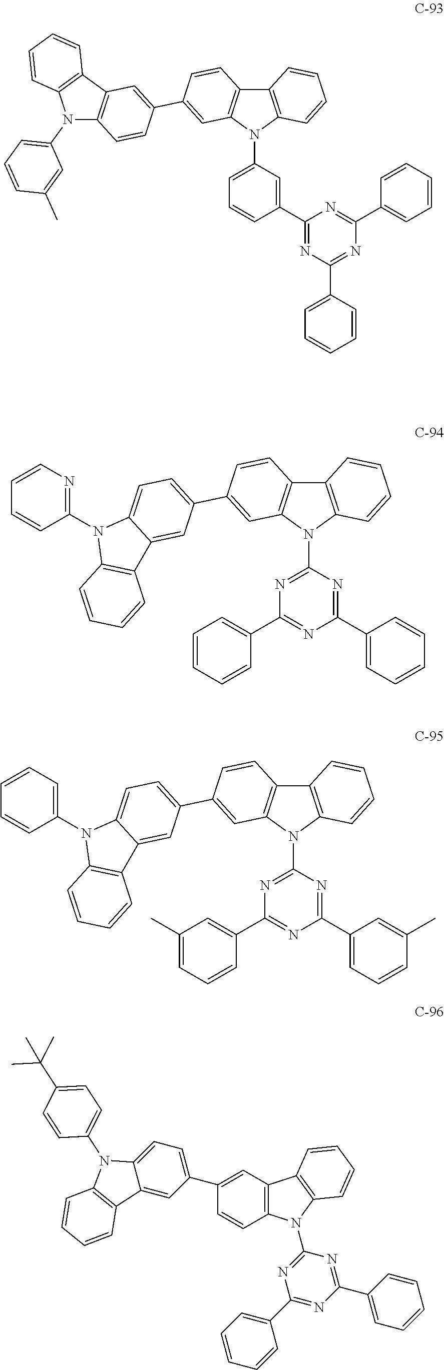

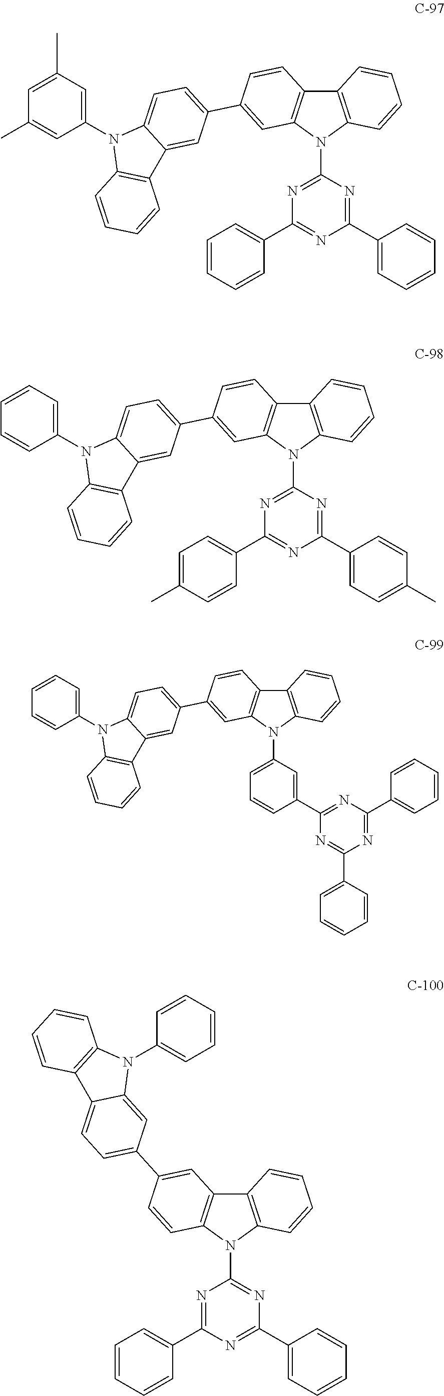 [SMILES: Cc1cc(C)cc(-n2c3ccccc3c3cc(-c4ccc5c6ccccc6n(-c6nc(-c7ccccc7)nc(-c7ccccc7)n6)c5c4)ccc32)c1 ; Cc1ccc(-c2nc(-c3ccc(C)cc3)nc(-n3c4ccccc4c4ccc(-c5ccc6c(c5)c5ccccc5n6-c5ccccc5)cc43)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-c2nc(-c3ccccc3)nc(-n3c4ccccc4c4cc(-c5ccc6c7ccccc7n(-c7ccccc7)c6c5)ccc43)n2)cc1]

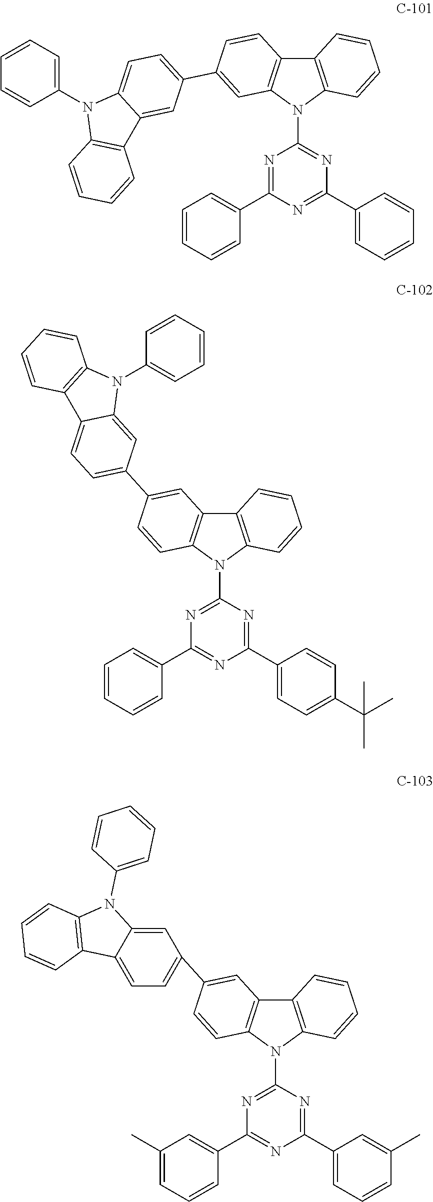 [SMILES: c1ccc(-c2nc(-c3ccccc3)nc(-n3c4ccccc4c4ccc(-c5ccc6c(c5)c5ccccc5n6-c5ccccc5)cc43)n2)cc1 ; CC(C)(C)c1ccc(-c2nc(-c3ccccc3)nc(-n3c4ccccc4c4cc(-c5ccc6c7ccccc7n(-c7ccccc7)c6c5)ccc43)n2)cc1 ; Cc1cccc(-c2nc(-c3cccc(C)c3)nc(-n3c4ccccc4c4cc(-c5ccc6c7ccccc7n(-c7ccccc7)c6c5)ccc43)n2)c1]

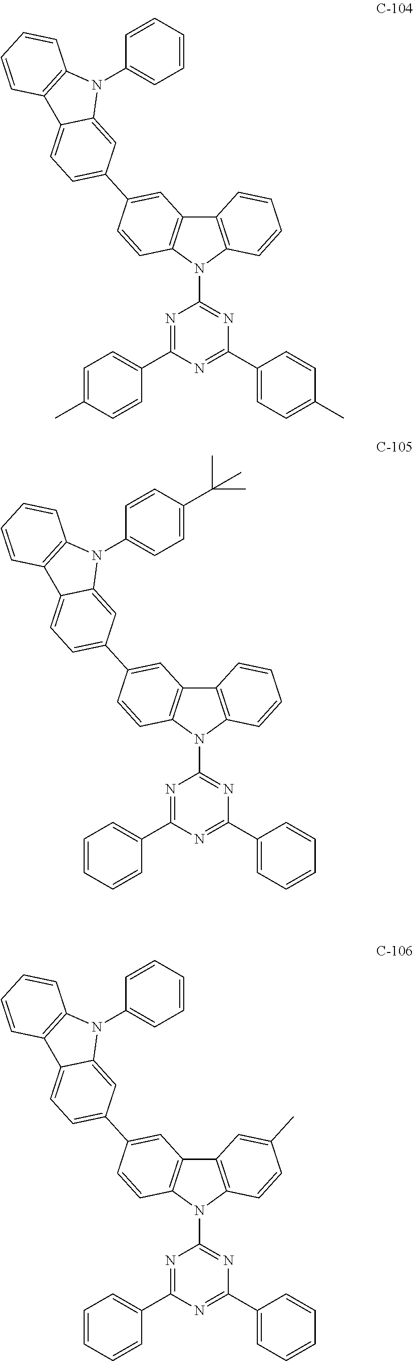 [SMILES: Cc1ccc(-c2nc(-c3ccc(C)cc3)nc(-n3c4ccccc4c4cc(-c5ccc6c7ccccc7n(-c7ccccc7)c6c5)ccc43)n2)cc1 ; CC(C)(C)c1ccc(-n2c3ccccc3c3ccc(-c4ccc5c(c4)c4ccccc4n5-c4nc(-c5ccccc5)nc(-c5ccccc5)n4)cc32)cc1 ; Cc1ccc2c(c1)c1cc(-c3ccc4c5ccccc5n(-c5ccccc5)c4c3)ccc1n2-c1nc(-c2ccccc2)nc(-c2ccccc2)n1]

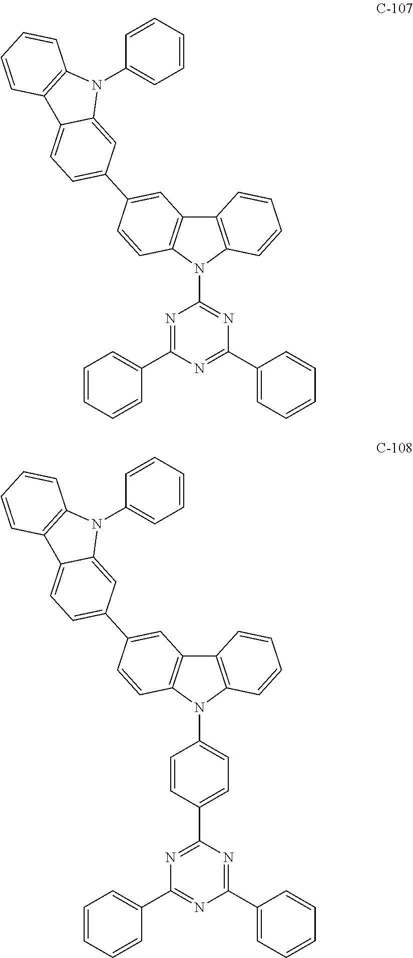 [SMILES: c1ccc(-c2nc(-c3ccccc3)nc(-n3c4ccccc4c4cc(-c5ccc6c7ccccc7n(-c7ccccc7)c6c5)ccc43)n2)cc1 ; c1ccc(-c2nc(-c3ccccc3)nc(-c3ccc(-n4c5ccccc5c5cc(-c6ccc7c8ccccc8n(-c8ccccc8)c7c6)ccc54)cc3)n2)cc1]

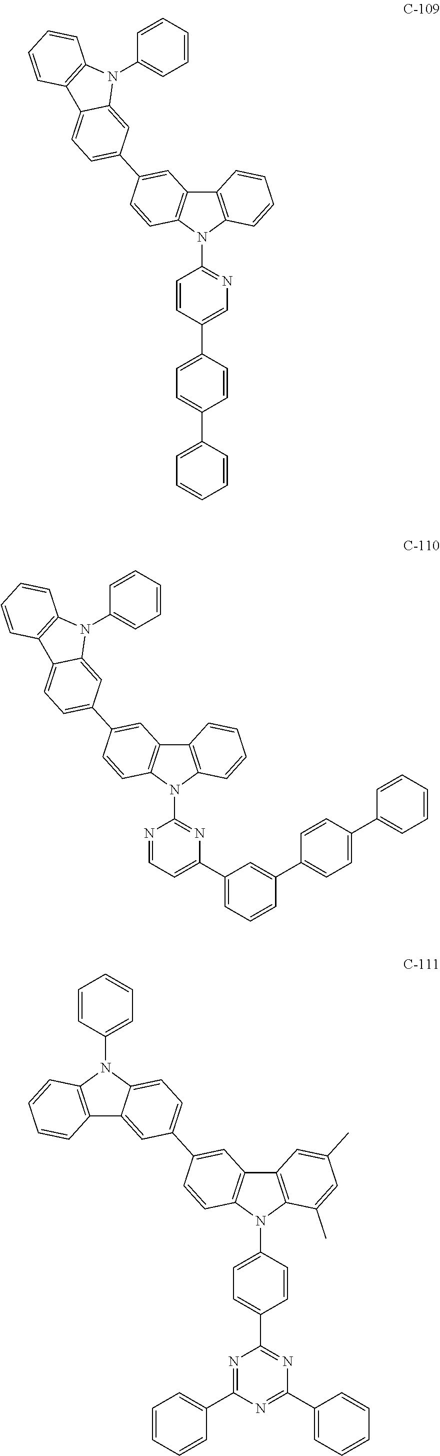 [SMILES: c1ccc(-c2ccc(-c3ccc(-n4c5ccccc5c5cc(-c6ccc7c8ccccc8n(-c8ccccc8)c7c6)ccc54)nc3)cc2)cc1 ; c1ccc(-c2ccc(-c3cccc(-c4ccnc(-n5c6ccccc6c6cc(-c7ccc8c9ccccc9n(-c9ccccc9)c8c7)ccc65)n4)c3)cc2)cc1 ; Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1]

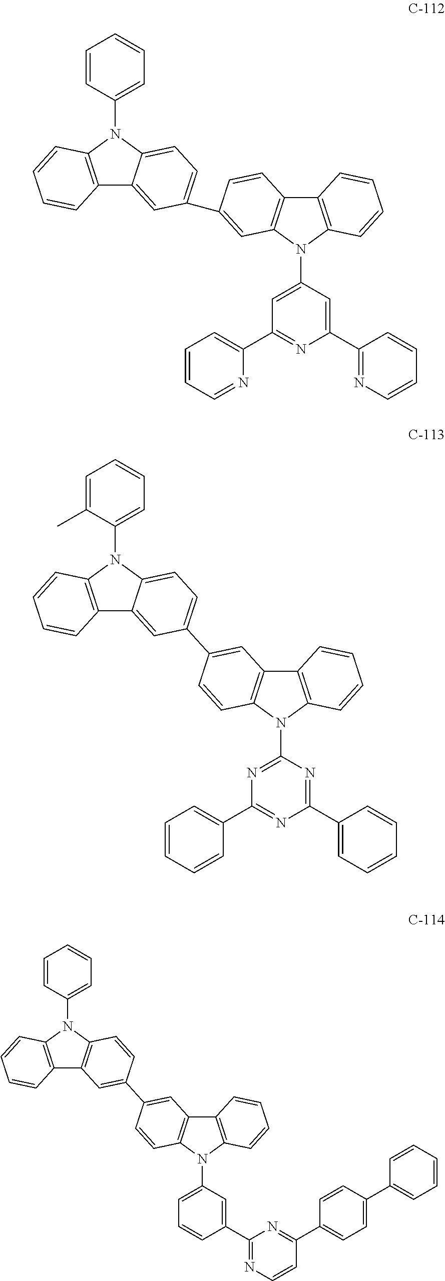 [SMILES: c1ccc(-n2c3ccccc3c3cc(-c4ccc5c6ccccc6n(-c6cc(-c7ccccn7)nc(-c7ccccn7)c6)c5c4)ccc32)cc1 ; Cc1ccccc1-n1c2ccccc2c2cc(-c3ccc4c(c3)c3ccccc3n4-c3nc(-c4ccccc4)nc(-c4ccccc4)n3)ccc21 ; c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1]

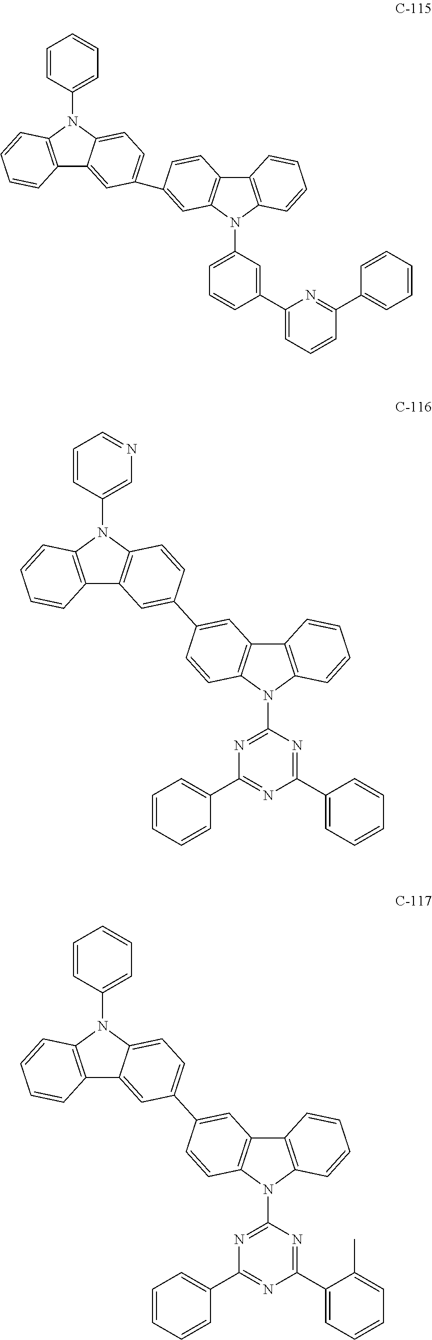 [SMILES: c1ccc(-c2cccc(-c3cccc(-n4c5ccccc5c5ccc(-c6ccc7c(c6)c6ccccc6n7-c6ccccc6)cc54)c3)n2)cc1 ; c1ccc(-c2nc(-c3ccccc3)nc(-n3c4ccccc4c4cc(-c5ccc6c(c5)c5ccccc5n6-c5cccnc5)ccc43)n2)cc1 ; Cc1ccccc1-c1nc(-c2ccccc2)nc(-n2c3ccccc3c3cc(-c4ccc5c(c4)c4ccccc4n5-c4ccccc4)ccc32)n1]

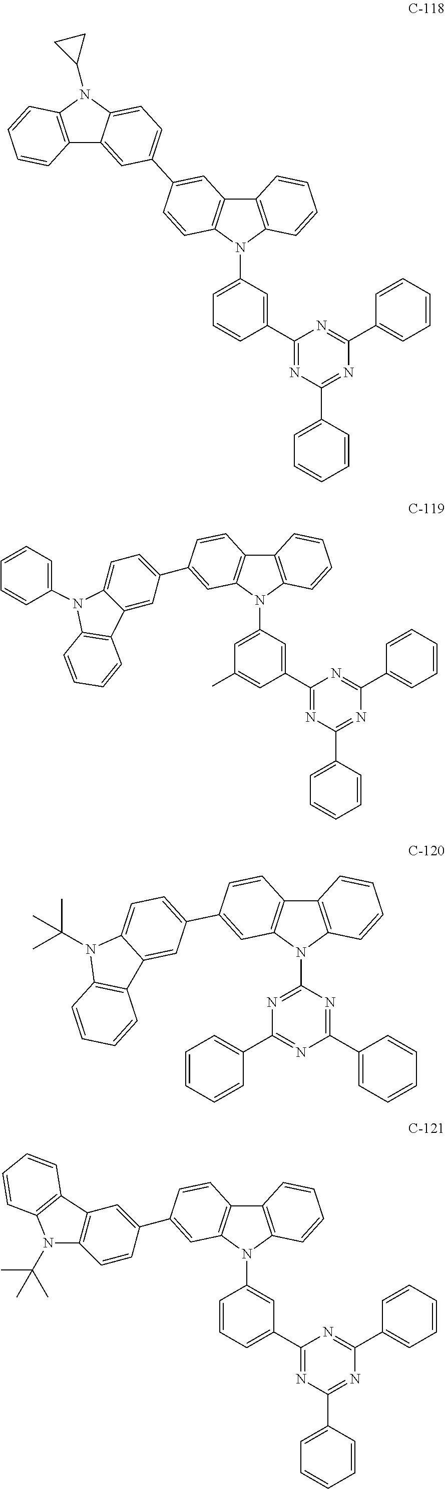 [SMILES: c1ccc(-c2nc(-c3ccccc3)nc(-c3cccc(-n4c5ccccc5c5cc(-c6ccc7c(c6)c6ccccc6n7C6CC6)ccc54)c3)n2)cc1 ; Cc1cc(-c2nc(-c3ccccc3)nc(-c3ccccc3)n2)cc(-n2c3ccccc3c3ccc(-c4ccc5c(c4)c4ccccc4n5-c4ccccc4)cc32)c1 ; CC(C)(C)n1c2ccccc2c2cc(-c3ccc4c5ccccc5n(-c5nc(-c6ccccc6)nc(-c6ccccc6)n5)c4c3)ccc21 ; CC(C)(C)n1c2ccccc2c2cc(-c3ccc4c5ccccc5n(-c5cccc(-c6nc(-c7ccccc7)nc(-c7ccccc7)n6)c5)c4c3)ccc21]

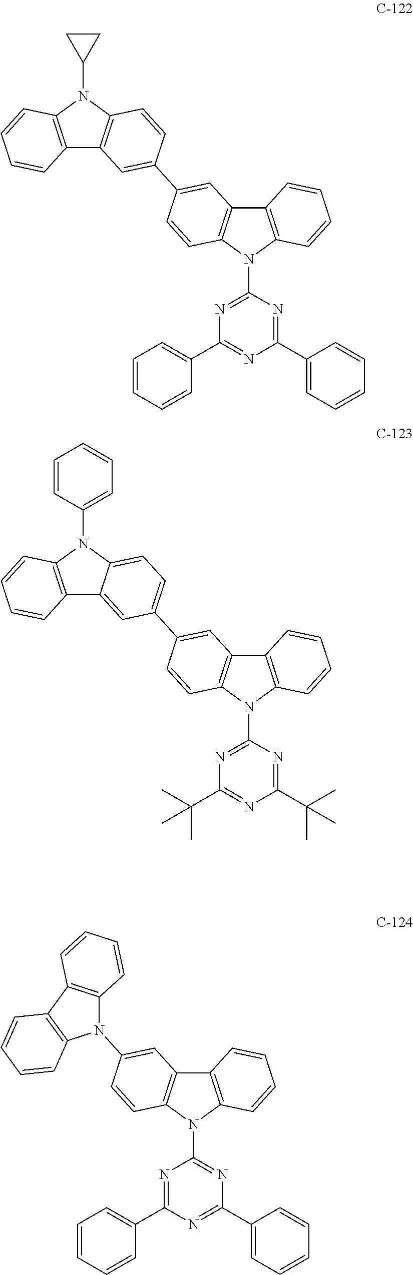 [SMILES: c1ccc(-c2nc(-c3ccccc3)nc(-n3c4ccccc4c4cc(-c5ccc6c(c5)c5ccccc5n6C5CC5)ccc43)n2)cc1 ; CC(C)(C)c1nc(-n2c3ccccc3c3cc(-c4ccc5c(c4)c4ccccc4n5-c4ccccc4)ccc32)nc(C(C)(C)C)n1 ; c1ccc(-c2nc(-c3ccccc3)nc(-n3c4ccccc4c4cc(-n5c6ccccc6c6ccccc65)ccc43)n2)cc1]

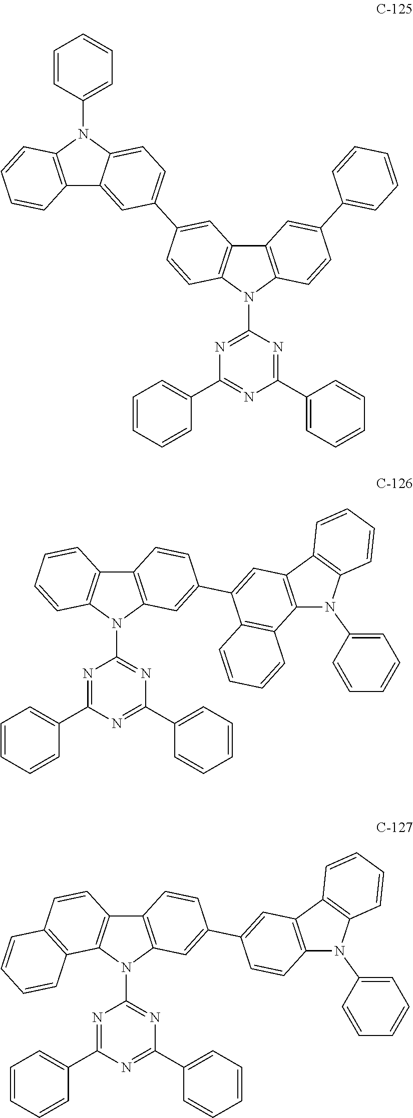 [SMILES: c1ccc(-c2ccc3c(c2)c2cc(-c4ccc5c(c4)c4ccccc4n5-c4ccccc4)ccc2n3-c2nc(-c3ccccc3)nc(-c3ccccc3)n2)cc1 ; c1ccc(-c2nc(-c3ccccc3)nc(-n3c4ccccc4c4ccc(-c5cc6c7ccccc7n(-c7ccccc7)c6c6ccccc56)cc43)n2)cc1 ; c1ccc(-c2nc(-c3ccccc3)nc(-n3c4cc(-c5ccc6c(c5)c5ccccc5n6-c5ccccc5)ccc4c4ccc5ccccc5c43)n2)cc1]

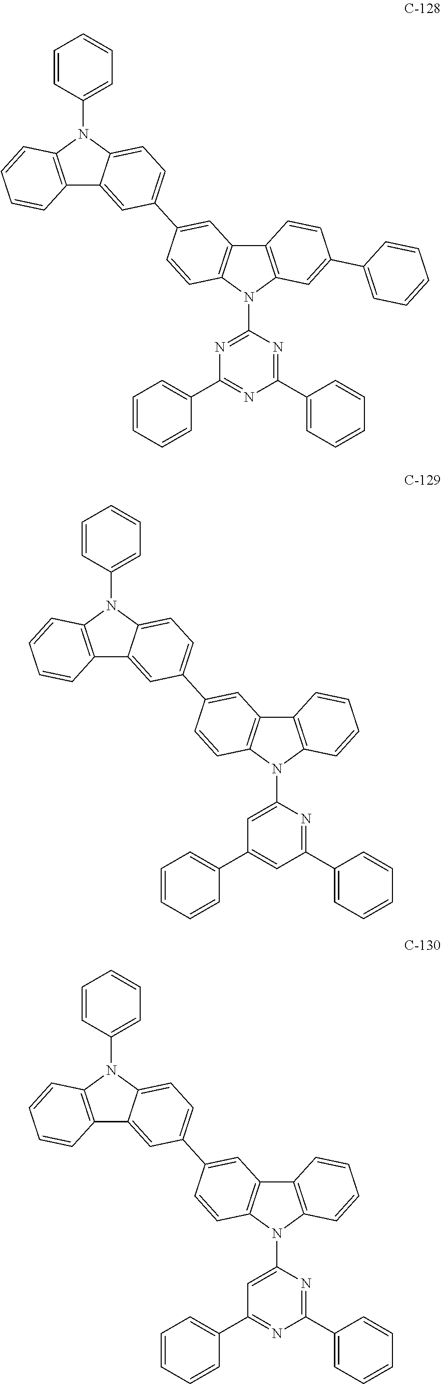 [SMILES: c1ccc(-c2ccc3c4cc(-c5ccc6c(c5)c5ccccc5n6-c5ccccc5)ccc4n(-c4nc(-c5ccccc5)nc(-c5ccccc5)n4)c3c2)cc1 ; c1ccc(-c2cc(-c3ccccc3)nc(-n3c4ccccc4c4cc(-c5ccc6c(c5)c5ccccc5n6-c5ccccc5)ccc43)c2)cc1 ; c1ccc(-c2cc(-n3c4ccccc4c4cc(-c5ccc6c(c5)c5ccccc5n6-c5ccccc5)ccc43)nc(-c3ccccc3)n2)cc1]

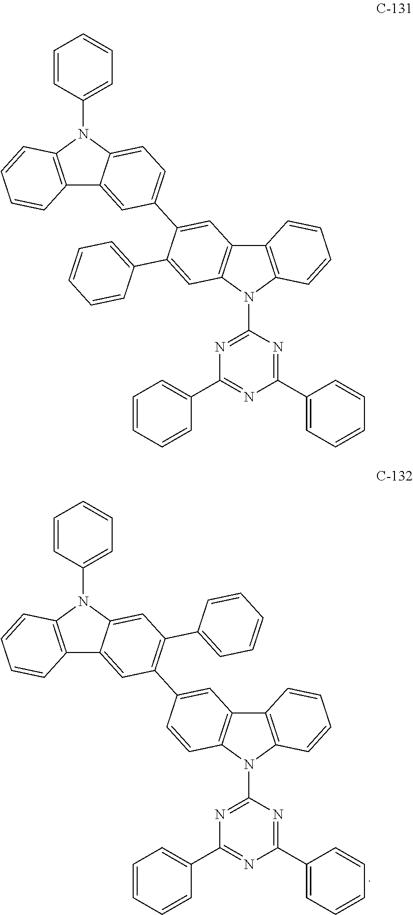 [SMILES: c1ccc(-c2nc(-c3ccccc3)nc(-n3c4ccccc4c4cc(-c5ccc6c(c5)c5ccccc5n6-c5ccccc5)c(-c5ccccc5)cc43)n2)cc1 ; c1ccc(-c2nc(-c3ccccc3)nc(-n3c4ccccc4c4cc(-c5cc6c7ccccc7n(-c7ccccc7)c6cc5-c5ccccc5)ccc43)n2)cc1]

9. An organic electroluminescent device comprising the combination according to any one of claims 1 to 8.
